(19) United States
(12) Patent Application Publication
(10) Pub. No.: US 2025/0311531 A1
(43) Pub. Date: Oct. 2, 2025

(54) QUANTUM DOT, OPTICAL MEMBER AND ELECTRONIC APPARATUS INCLUDING THE QUANTUM DOT, AND METHOD OF MANUFACTURING QUANTUM DOT

(71) Applicant: Samsung Display Co., Ltd., Yongin-si (KR)

(72) Inventors: Junehyuk Jung, Yongin-si (KR); Sungjae Kim, Yongin-si (KR); Youngsik Kim, Yongin-si (KR); Hongrae Kim, Yongin-si (KR); Bitna Yoon, Yongin-si (KR); Donghee Lee, Yongin-si (KR); Taekjoon Lee, Yongin-si (KR)

(73) Assignee: Samsung Display Co., Ltd., Yongin-si (KR)

(21) Appl. No.: 19/040,089

(22) Filed: Jan. 29, 2025

(30) Foreign Application Priority Data
Mar. 27, 2024 (KR) 10-2024-0041990

(51) Int. Cl. H10K 50/115; H10K 71/40

(52) U.S. Cl. CPC H10K 50/115; H10K 71/40

(57) ABSTRACT

Embodiments provide a quantum dot, an optical member including the quantum dot, an electronic apparatus including the quantum dot, and a method of manufacturing the quantum dot. The quantum dot includes: a core including copper (Cu), a Group III element, and a Group VI element; and a first shell covering the core. A full width at half maximum (FWHM) of an emission wavelength spectrum of the core is equal to or less than about 55 nm.

### CROSS-REFERENCE TO RELATED APPLICATION(S)

This application claims priority to and benefits of Korean Patent Application No. 10-2024-0041990 under 35 U.S.C. § 119, filed on Mar. 27, 2024, in the Korean Intellectual Property Office, the entire contents of which are incorporated herein by reference.

### BACKGROUND

### 1. Technical Field

Embodiments relate to a quantum dot, an optical member including the quantum dot, an electronic apparatus including the quantum dot, and a method of manufacturing the quantum dot.

### 2. Description of the Related Art

Quantum dots may be used as materials that perform various optical functions (for example, a light conversion function, a light emission function, and the like) in optical members and various electronic apparatuses. Quantum dots, which are semiconductor nanocrystals with a quantum confinement effect, may have different energy bandgaps by control of the size and composition of the nanocrystals, and thus may emit light of various emission wavelengths.

An optical member including quantum dots may have the form of a thin film, such as a thin film patterned for each subpixel. Such an optical member may be used as a color conversion member of a device that includes various light sources.

Quantum dots may be used for a variety of purposes in various electronic apparatuses. For example, quantum dots may be used as emitters. For example, quantum dots may be included in an emission layer of a light-emitting device that includes a pair of electrodes and the emission layer, and may serve as an emitter.

In order to implement high-quality optical members and electronic apparatuses, development is currently directed towards quantum dots that have excellent quantum yield (QY) and do not include cadmium, which is a toxic element.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments a novel quantum dot, an optical member including the quantum dot, an electronic apparatus including the quantum dot, and a method of manufacturing the quantum dot.

Additional aspects will be set forth in part in the description which follows and, in part, will be apparent from the description, or may be learned by practice of the embodiments of the disclosure.

According to embodiments, a quantum dot may include:
a core including copper (Cu), a Group III element, and a Group VI element; and
a first shell covering the core, wherein
a full width at half maximum (FWHM) of an emission wavelength spectrum of the core may be equal to or less than about 55 nm.

In an embodiment, a tail value of the emission wavelength spectrum of the core may be equal to or less than about 15 nm.

In an embodiment, the core may include an amount of Cu in a range of about 4 parts by weight to about 10 parts by weight, based on a total of 100 parts by weight of the core.

In an embodiment, the Group III element may be aluminum (Al), gallium (Ga), indium (In), thallium (TI), nihonium (Nh), or any combination thereof.

In an embodiment, the Group VI element may be oxygen (O), sulfur(S), selenium (Se), tellurium (Te), or any combination thereof.

In an embodiment, the core may include Cu, indium (In), gallium (Ga), and sulfur(S).

In an embodiment, based on a total of 100 parts by weight of the core, the core may include: an amount of Cu in a range of about 4 parts by weight to about 10 parts by weight; an amount In in a range of about 10 parts by weight to about 20 parts by weight; an amount Ga in a range of about 30 parts by weight to about 40 parts by weight; and an amount S in a range of about 40 parts by weight to about 50 parts by weight.

In an embodiment, the first shell may include a Group II-VI semiconductor compound, a Group III-VI semiconductor compound, a Group III-V semiconductor compound, or any combination thereof.

In an embodiment, the Group II-VI semiconductor compound may be CdS, CdSe, CdTe, ZnS, ZnSe, ZnTe, ZnO, ZnMg, HgS, HgSe, HgTe, MgSe, MgS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, CdZnSeS, CdZnSeTe, CdZnSTe, CdHgSeS, CdHgSeTe, CdHgSTe, HgZnSeS, HgZnSeTe, HgZnSTe, or any combination thereof.

In an embodiment, the Group III-VI semiconductor compound may be GaS, GaSe, Ga₂Se₃, GaTe, InS, InSe, In₂S₃, In₂Se₃, InTe, InGaS₃, InGaSe₃, or any combination thereof.

In an embodiment, the Group III-V semiconductor compound may be GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAS, AlPSb, InGaP, InNP, InAlP, InNAs, InNSb, InPAs, InPSb, GaAlNP, GaAlNAs, GaAlNSb, GaAlPAs, GaAlPSb, GalnNP, GaInNAs, GalnNSb, GaInPAs, GaInPSb, InAlNP, InAlNAs, InAlNSb, InAlPAs, InAlPSb, or any combination thereof.

In an embodiment, the quantum dot may emit red light having a maximum emission wavelength in a range of about 600 nm to about 700 nm.

In an embodiment, a quantum yield (QY) of the quantum dot may be more than 70% but not more than about 98%.

According to embodiments, an optical member may include the quantum dot.

According to embodiments, an electronic apparatus may include the quantum dot.

In an embodiment, the electronic apparatus may further include: a light source; and a color conversion member arranged in an optical path of light emitted from the light source, wherein
the color conversion member may include the quantum dot.

According to embodiments, a method of manufacturing a quantum dot may include:
manufacturing a core including copper (Cu), a Group III element, and a Group VI element; and
manufacturing a first shell covering the core, wherein
a full width at half maximum (FWHM) of an emission wavelength spectrum of the core may be equal to or less than about 55 nm.

In an embodiment, the manufacturing of the core may include manufacturing the core by using a composition for forming a core; and the composition may include a copper precursor, a Group III element-containing precursor, and a Group VI element-containing precursor.

In an embodiment, the manufacturing of the core may include heat-treating the composition for forming a core at a temperature more than 240° C. but not more than about 320° C.

In an embodiment, the manufacturing of the first shell may include manufacturing the first shell by using a composition for forming a first shell; and the composition may include a Group Il element-containing precursor and a Group VI element-containing precursor.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic cross-sectional view of a quantum dot according to an embodiment;

FIG. 2 is a schematic cross-sectional view of an electronic apparatus according to an embodiment;

FIG. 3 is a schematic cross-sectional view of a light-emitting device according to an embodiment;

FIG. 4 is a schematic perspective view of an electronic device including a quantum dot according to an embodiment;

FIG. 5 is a schematic perspective view of an exterior of a vehicle as an electronic device including a quantum dot according to an embodiment;

FIGS. 6A to 6C are each a schematic diagram of an interior of a vehicle according to embodiments; and

FIG. 7 is a graph of photoluminescence (PL) spectra of quantum dot cores according to the Examples and the Comparative Examples.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on”, “directly connected to”, or “directly coupled to” another element, there are no intervening elements present. For example, “directly on” may mean that two layers or two elements are disposed without an additional element such as an adhesion element therebetween.

In the specification, the expressions used in the singular such as “a”, “an”, and “the” are intended to include the plural forms as well, unless the context clearly indicates otherwise.

In the specification, the term “and/or” includes any and all combinations of one or more of the associated listed items. For example, “A and/or B” may be understood to mean “A, B, or A and B”. The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of”, modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises”, “comprising”, “includes”, “including”, “have”, “having”, “contains”, “containing”, and the like are intended to specify the presence of stated features, integers, steps, operations, elements, components, or combinations thereof in the disclosure, but do not preclude the presence or addition of one or more other features, integers, steps, operations, elements, components, or combinations thereof.

The term “Group I” as used herein may encompass a Group IA element and a Group IB element on the IUPAC periodic table; and a Group I element may include, for example, silver (Ag), copper (Cu), etc.

The term “Group II” as used herein may encompass a Group IIA element and a Group IIB element on the IUPAC periodic table; and a Group Il element may include, for example, magnesium (Mg), calcium (Ca), zinc (Zn), cadmium (Cd), mercury (Hg), etc.

The term “Group III” as used herein may encompass a Group IIIA element and a Group IIIB element on the IUPAC periodic table; and a Group III element may include, for example, aluminum (AI), gallium (Ga), indium (In), thallium (TI), nihonium (Nh), etc.

The term “Group VI” as used herein may encompass a Group VIA element and a Group VIB element on the IUPAC periodic table; and a Group VI element may include, for example, oxygen (O), sulfur(S), selenium (Se), tellurium (Te), etc.

The terms “quantum yield” (QY) and “luminescence efficiency” as used herein may be used with substantially a same meaning.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

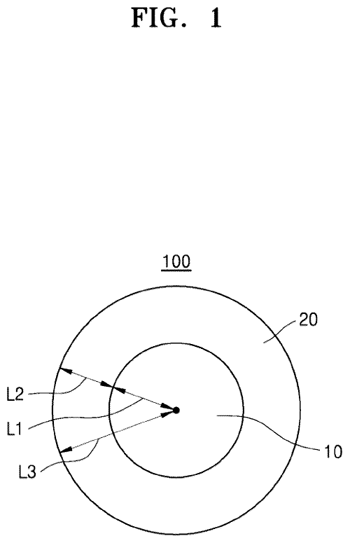

Hereinafter, a quantum dot 100 according to an embodiment and a method of manufacturing the same according to an embodiment will be described with reference to FIG. 1.

### [Description of FIG. 1]

FIG. 1 is a schematic cross-sectional view of a quantum dot 100 according to an embodiment. The quantum dot 100 may include a core 10 and a first shell 20.

### [Quantum Dot 100]

The quantum dot 100 of FIG. 1 may include:
a core 10 including copper (Cu), a Group III element, and a Group VI element; and
a first shell 20 covering the core, wherein
a full width at half maximum (FWHM) of an emission wavelength spectrum of the core may be equal to or less than about 55 nm.

According to an embodiment, the core 10 may include a Group I-III-VI semiconductor compound.

According to an embodiment, a full width at half maximum of an emission wavelength spectrum of the core 10 may be equal to or less than about 55 nm. For example, a FWHM of an emission wavelength spectrum of the core 10 may be at least about 1 nm but not more than about 55 nm, at least about 2 nm but not more than about 55 nm, at least about 3 nm but not more than about 55 nm, at least about 5 nm but not more than about 55 nm, at least about 10 nm but not more than about 55 nm, at least about 15 nm but not more than about 55 nm, at least about 20 nm but not more than about 55 nm, at least 25 nm but not more than about 55 nm, at least about 30 nm but not more than about 55 nm, at least about 40 nm but not more than about 55 nm, at least about 45 nm but not more than about 55 nm, at least about 46 nm but not more than about 55 nm, at least about 47 nm but not more than about 55 nm, at least about 48 nm but not more than about 55 nm, at least about 49 nm but not more than about 55 nm, at least about 50 nm but not more than about 55 nm, at least about 51 nm but not more than about 55 nm, at least about 52 nm but not more than about 55 nm, at least about 53 nm but not more than about 55 nm, at least about 54 nm but not more than about 55 nm, at least about 45 nm but not more than about 54 nm, at least about 46 nm but not more than about 54 nm, at least about 47 nm but not more than about 54 nm, at least about 48 nm but not more than about 54 nm, at least about 49 nm but not more than about 54 nm, at least about 50 nm but not more than about 54 nm, at least about 51 nm but not more than about 54 nm, at least about 52 nm but not more than about 54 nm, at least about 53 nm but not more than about 54 nm, at least about 45 nm but not more than about 53 nm, at least about 46 nm but not more than about 53 nm, at least about 47 nm but not more than about 53 nm, at least about 48 nm but not more than about 53 nm, at least about 49 nm but not more than about 53 nm, at least about 50 nm but not more than about 53 nm, at least about 51 nm but not more than about 53 nm, at least about 52 nm but not more than about 53 nm, at least about 45 nm but not more than about 52 nm, at least about 46 nm but not more than about 52 nm, at least about 47 nm but not more than about 52 nm, at least about 48 nm but not more than about 52 nm, at least about 49 nm but not more than about 52 nm, at least about 50 nm but not more than about 52 nm, at least about 51 nm but not more than about 52 nm, at least about 45 nm but not more than about 51 nm, at least about 46 nm but not more than about 51 nm, at least about 47 nm but not more than about 51 nm, at least about 48 nm but not more than about 51 nm, at least about 49 nm but not more than about 51 nm, at least about 50 nm but not more than about 51 nm, at least about 45 nm but not more than about 50 nm, at least about 46 nm but not more than about 50 nm, at least about 47 but not more than about 50 nm, at least about 48 nm but not more than about 50 nm, at least about 49 nm but not more than about 50 nm, at least about 45 nm but not more than about 49 nm, at least about 46 nm but not more than about 49 nm, at least about 47 nm but not more than about 49 nm, at least about 48 nm but not more than about 49 nm, at least about 45 nm but not more than about 48 nm, at least about 46 nm but not more than about 48 nm, at least about 47 nm but not more than about 48 nm, at least about 45 nm but not more than about 47 nm, at least about 46 nm but not more than about 47 nm, or at least about 45 nm but not more than about 46 nm. When a full width at half maximum of an emission wavelength spectrum of the core 10 of the quantum dot satisfies any of the above-mentioned ranges, color purity and color reproducibility may be excellent, a wide viewing angle may be improved, and quantum yield (QY) may be improved.

According to an embodiment, a tail value of an emission wavelength spectrum of the core 10 may be equal to or less than about 15 nm.

A tail value of the core 10 may be expressed as an absolute value of the [right wavelength width (R)-left wavelength width (L)] value at 1/10 of a peak value of a maximum emission wavelength of the core. For example, a tail value may be an absolute value of the [right half width-left half width] value at 1/10 of a peak value of a maximum emission wavelength.

The tail value may be a characteristic of quantum dots in addition to the full width at half maximum, and may be a numerical value representing particle uniformity and trap emission. As the tail value decreases, particle uniformity increases and the degree of trap emission decreases.

Since the tail area represented by the tail value may not contribute to a final light-emitting device efficiency later, even if each quantum dot has a same quantum yield, when the tail value is high, the area that does not contribute to a final light-emitting device efficiency increases, and thus efficiency and luminance of the device may decrease. Therefore, a low tail value may enable the provision of excellent quantum dots and accordingly an excellent device.

A tail value of an emission wavelength spectrum of the core 10 according to an embodiment may be equal to or less than about 15 nm. For example, a tail value of an emission wavelength spectrum of the core 10 may in a range of about 0 nm to about 15 nm, about 0.1 nm to about 15 nm, about 1 nm to about 15 nm, about 2 nm to about 15 nm, about 3 nm to about 15 nm, about 4 nm to about 15 nm, about 5 nm to about 15 nm, about 6 nm to about 15 nm, about 7 nm to about 15 nm, about 8 nm to about 15 nm, about 9 nm to about 15 nm, about 10 nm to about 15 nm, about 11 nm to about 15 nm, about 12 nm to about 15 nm, about 13 nm to about 15 nm, about 14 nm to about 15 nm, about 0 nm to about 14 nm, about 0.1 nm to about 14 nm, about 1 nm to about 14 nm, about 2 nm to about 14 nm, about 3 nm to about 14 nm, about 4 nm to about 14 nm, about 5 nm to about 14 nm, about 6 nm to about 14 nm, about 7 nm to about 14 nm, about 8 nm to about 14 nm, about 9 nm to about 14 nm, about 10 nm to about 14 nm, about 11 nm to about 14 nm, about 12 nm to about 14 nm, about 13 nm to about 14 nm, about 0 nm to about 13 nm, about 0.1 nm to about 13 nm, about 1 nm to about 13 nm, about 2 nm to about 13 nm, about 3 nm to about 13 nm, about 4 nm to about 13 nm, about 5 nm to about 13 nm, about 6 nm to about 13 nm, about 7 nm to about 13 nm, about 8 nm to about 13 nm, about 9 nm to about 13 nm, about 10 nm to 13 nm, about 11 nm to about 13 nm, about 12 nm to about 13 nm, about 0 nm to about 12 nm, about 0.1 nm to about 12 nm, about 1 nm to about 12 nm, about 2 nm to about 12 nm, about 3 nm to about 12 nm, about 4 nm to about 12 nm, about 5 nm to about 12 nm, about 6 nm to about 12 nm, about 7 nm to about 12 nm, about 8 nm to about 12 nm, about 9 nm to about 12 nm, about 10 nm to 12 nm, about 11 nm to about 12 nm, about 0 nm to about 11 nm, about 0.1 nm to about 11 nm, about 1 nm to about 11 nm, about 2 nm to about 11 nm, about 3 nm to about 11 nm, about 4 nm to about 11 nm, about 5 nm to about 11 nm, about 6 nm to about 11 nm, about 7 nm to about 11 nm, about 8 nm to about 11 nm, about 9 nm to about 11 nm, about 10 nm to about 11 nm, about 0 nm to about 10 nm, about 0.1 nm to about 10 nm, about 1 nm to about 10 nm, about 2 nm to about 10 nm, about 3 nm to about 10 nm, about 4 nm to about 10 nm, about 5 nm to about 10 nm, about 6 nm to about 10 nm, about 7 nm to about 10 nm, about 8 nm to about 10 nm, about 9 nm to about 10 nm, about 1 nm to about 9 nm, about 2 nm to about 7 nm, about 3 nm to about 5 nm, or about 4 nm to about 5 nm.

According to an embodiment, the core 10 may include an amount of copper (Cu) in a range of about 4 parts by weight to about 10 parts by weight, based on a total of 100 parts by weight of the core 10.

For example, based on a total of 100 parts by weight of the core 10, the core 10 may include an amount of copper (Cu) in a range of about 4 parts by weight to about 10 parts by weight, about 4 parts by weight to about 9 parts by weight, about 4 parts by weight to about 8 parts by weight, about 4 parts by weight to about 7 parts by weight, about 4 parts by weight to about 6 parts by weight, about 4 parts by weight to about 5 parts by weight, about 5 parts by weight to about 10 parts by weight, about 5 parts by weight to about 9 parts by weight, about 5 parts by weight to about 8 parts by weight, about 5 parts by weight to about 7 parts by weight, about 5 parts by weight to about 6 parts by weight, about 6 parts by weight to about 10 parts by weight, about 6 parts by weight to about 9 parts by weight, about 6 parts by weight to about 8 parts by weight, about 6 parts by weight to about 7 parts by weight, about 7 parts by weight to about 10 parts by weight, about 7 parts by weight to about 9 parts by weight, about 7 parts by weight to about 8 parts by weight, about 8 parts by weight to about 10 parts by weight, about 8 parts by weight to about 9 parts by weight, or about 9 parts by weight to about 10 parts by weight.

According to an embodiment, the core 10 may include an amount of the Group Ill element in a range of about 10 parts by weight to about 50 parts by weight, based on a total of 100 parts by weight of the core 10.

For example, when the core 10 includes two or more Group III elements, a total amount of the two or more Group III elements may be in a range of about 10 parts by weight to about 50 parts by weight, based on a total of 100 parts by weight of the core 10.

According to an embodiment, the core 10 may include an amount of the Group VI element in a range of about 40 parts by weight to about 60 parts by weight, based on a total of 100 parts by weight of the core 10.

For example, when the core 10 includes two or more Group VI elements, a total amount of the two or more Group VI elements may be in a range of about 40 parts by weight to about 60 parts by weight, based on a total of 100 parts by weight of the core 10.

According to an embodiment, the Group III element may be aluminum (Al), gallium (Ga), indium (In), thallium (TI), nihonium (Nh), or any combination thereof.

For example, the Group III element included in the core 10 may be: aluminum (AI), gallium (Ga), indium (In), or any combination thereof; gallium (Ga), indium (In), or any combination thereof; or gallium (Ga) and indium (In).

For example, in case that the Group III elements that are included in the core 10 are gallium (Ga) and indium (In), an amount of gallium may be in a range of about 30 parts by weight to about 40 parts by weight, based on a total of 100 parts by weight of the core 10, and an amount of indium may be in a range of about 10 parts by weight to about 20 parts by weight, based on a total of 100 parts by weight of the core 10.

According to an embodiment, the Group VI element may be oxygen (O), sulfur(S), selenium (Se), tellurium (Te), or any combination thereof.

For example, the Group VI element included in the core 10 may be sulfur(S), selenium (Se), or any combination thereof.

According to an embodiment, the core 10 may include copper (Cu), indium (In), gallium (Ga), and sulfur(S).

For example, the core 10 may be a copper indium gallium sulfur (CIGS) quantum dot core consisting of copper (Cu), indium (In), gallium (Ga), and sulfur(S).

According to an embodiment, based on a total of 100 parts by weight of the core 10, the core 10 may include: an amount of copper (Cu) in a range of about 4 parts by weight to about 10 parts by weight; an amount of indium (In) in a range of about 10 parts by weight to about 20 parts by weight; an amount of gallium (Ga) in a range of about 30 parts by weight to about 40 parts by weight; and an amount of sulfur(S) in a range of about 40 parts by weight to about 50 parts by weight.

According to an embodiment, the first shell 20 may include a Group II-VI semiconductor compound, a Group III-VI semiconductor compound, a Group III-V semiconductor compound, or any combination thereof.

According to an embodiment, the quantum dot 100 may further include a second shell (not shown) covering the first shell 20.

According to an embodiment, the second shell (not shown) may include a Group II-VI semiconductor compound, a Group III-VI semiconductor compound, a Group III-V semiconductor compound, or any combination thereof.

According to an embodiment, the Group II-VI semiconductor compound may be CdS, CdSe, CdTe, ZnS, ZnSe, ZnTe, ZnO, ZnMg, HgS, HgSe, HgTe, MgSe, MgS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, CdZnSeS, CdZnSeTe, CdZnSTe, CdHgSeS, CdHgSeTe, CdHgSTe, HgZnSeS, HgZnSeTe, HgZnSTe, or any combination thereof.

According to an embodiment, the Group III-VI semiconductor compound may be GaS, GaSe, Ga₂Se₃, GaTe, InS, InSe, In₂S₂, In₂Se₃, InTe, InGaS₃, InGaSe₃, or any combination thereof.

According to an embodiment, the Group III-V semiconductor compound may be GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAS, AlPSb, InGaP, InNP, InAlP, InNAs, InNSb, InPAs, InPSb, GaAlNP, GaAlNAs, GaAlNSb, GaAlPAs, GaAlPSb, GalnNP, GaInNAs, GalnNSb, GaInPAs, GaInPSb, InAlNP, InAlNAs, InAlNSb, InAlPAs, InAlPSb, or any combination thereof.

According to an embodiment, the quantum dot may further include an intershell layer (not shown) between the first shell 20 and the second shell (not shown), wherein the intershell layer may include a material identical to a material of the first shell and a material identical to a material of the second shell (not shown).

According to an embodiment, in the core 10, Cu may be present at a uniform concentration or at a non-uniform concentration.

According to an embodiment, in the core 10, the Group III element may be present at a uniform concentration or at a non-uniform concentration.

According to an embodiment, in the core 10, the Group VI element may be present at a uniform concentration or at a non-uniform concentration.

According to an embodiment, in the first shell 20, its constituent elements may be present at a uniform concentration or at a non-uniform concentration.

According to an embodiment, in the second shell (not shown), its constituent elements may be present at a uniform concentration or at a non-uniform concentration.

According to an embodiment, the concentration of elements included in the first shell 20 and the second shell (not shown) may form a concentration gradient depending on the distance from the core.

According to an embodiment, a radius L1 of the core 10 of the quantum dot 100 may be equal to or greater than about 4 nm. For example, the radius L1 of the core 10 may be in a range of about 4 nm to about 8 nm, about 4 nm to about 7.5 nm, about 4 nm to about 7 nm, or about 4 nm to about 6 nm.

According to an embodiment, a thickness L2 of the first shell 20 of the quantum dot 100 may be in a range of about 0.5 nm to about 3 nm. For example, the thickness L2 of the first shell 20 may be in a range of about 0.5 nm to about 3 nm, about 0.5 nm to about 2 nm, or about 0.5 nm to about 1 nm.

According to an embodiment, thickness of the second shell (not shown) of the quantum dot 100 may be in a range of about 0.5 to about 3. For example, the thickness of the second shell (not shown) may be in a range of about 0.5 nm to about 3 nm, about 1 nm to about 3 nm, or about 2 nm to about 3 nm.

According to an embodiment, a sum of the thickness L2 of the first shell 20 and the thickness of the second shell (not shown) may be in a range of about 1 nm to about 4 nm.

For example, a sum of the thicknesses of the first shell 20 and the second shell (not shown) may be in a range of about 1 nm to about 4 nm, or about 1 nm to about 3 nm.

The term “radius L1 of the core” may refer to a distance from the center of the quantum dot to an interface between the core 10 and the first shell 20.

The term “thickness L2 of the first shell” may refer to a distance from an interface between the core 10 and the first shell 20 to the surface of the first shell 20. For example, the “thickness L2 of the first shell” may correspond to a value obtained by subtracting the radius L1 of the core 10 from a distance L3 from the center of the quantum dot to the surface of the first shell 20.

According to an embodiment, a cation content of the first shell 20 may be in a range of about 10 parts by weight to about 50 parts by weight, based on a total of 100 parts by weight of the first shell 20.

According to an embodiment, the quantum dot 100 may be in the form of spherical, pyramidal, multi-arm, or cubic nanoparticles, nanotubes, nanowires, nanofibers, or nanoplate particles.

According to an embodiment, the quantum dot 100 may be spherical.

According to an embodiment, a maximum emission wavelength of a photoluminescence (PL) spectrum of the quantum dot 100 may be in a range of about 500 nm to about 700 nm. For example, a maximum emission wavelength of the PL spectrum of the quantum dot 100 may be in a range of about 600 nm to about 690 nm, about 610 nm to about 680 nm, or about 615 nm to about 670 nm.

According to an embodiment, the quantum dot 100 may emit blue light, green light, or red light. For example, the quantum dot 100 may emit red light.

According to an embodiment, the quantum dot 100 may emit red light having a maximum emission wavelength in a range of about 600 nm to about 700 nm.

According to an embodiment, a quantum yield (QY) of the quantum dot 100 may be more than 70% but not more than about 98%. For example, the QY of the quantum dot 100 may be at least about 75% but not more than about 97%, or at least about 85% but not more than about 95%.

According to an embodiment, the quantum dot 100 may have an FWHM of an emission wavelength spectrum equal to or less than about 60 nm. For example, the quantum dot 100 may have an FWHM of an emission wavelength spectrum equal to or less than about 58 nm. For example, the quantum dot 100 may have an FWHM of an emission wavelength spectrum equal to or less than about 55 nm. Within any of these ranges, color purity or color reproducibility may be improved. Light emitted through the quantum dot 100 may be emitted in all directions, so that a wide viewing angle may be improved.

In the specification, a “quantum dot” may be a crystal of a semiconductor compound, and may include any material capable of emitting light of various emission wavelengths according to a size of the crystal. The quantum dot 100 may emit light of various emission wavelengths by adjusting an elemental ratio in the quantum dot 100 compound.

A diameter of the quantum dot 100 may be, for example, in a range of about 1 nm to about 10 nm.

According to an embodiment, the quantum dot 100 may be manufactured by a method of manufacturing a quantum dot described hereinafter.

The quantum dot 100 may be synthesized by a wet chemical process, a metal organic chemical vapor deposition process, a molecular beam epitaxy process, or any process similar thereto.

The wet chemical process is a method that includes mixing a precursor material with an organic solvent and growing a quantum dot particle crystal. When the crystals grow, the organic solvent naturally serves as a dispersant that is coordinated on the surface of the quantum dot crystals and controls the growth of the crystals so that the growth of quantum dot particles may be controlled through a process which costs less and may be more readily performed than vapor deposition methods, such as metal organic chemical vapor deposition (MOCVD) or molecular beam epitaxy (MBE).

In addition to the Group II-VI semiconductor compound described above, the quantum dot 100 may further include: another Group II-VI semiconductor compound; a Group III-V semiconductor compound; a Group III-VI semiconductor compound; a Group I-III-VI semiconductor compound; a Group IV-VI semiconductor compound; a Group IV element or compound; or any combination thereof.

Examples of a Group II-VI semiconductor compound may include: a binary compound, such as CdS, CdSe, CdTe, ZnS, ZnSe, ZnTe, ZnO, HgS, HgSe, HgTe, MgSe, MgS, etc.; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, etc.; a quaternary compound, such as CdZnSeS, CdZnSeTe, CdZnSTe, CdHgSeS, CdHgSeTe, CdHgSTe, HgZnSeS, HgZnSeTe, HgZnSTe, etc.; and any combination thereof.

Examples of a Group III-V semiconductor compound may include: a binary compound, such as GaN, GaP, GaAs, GaSb, AlN, AlP, AlAs, AlSb, InN, InP, InAs, InSb, etc.; a ternary compound, such as GaNP, GaNAs, GaNSb, GaPAs, GaPSb, AlNP, AlNAs, AlNSb, AlPAS, AlPSb, InGaP, InNP, InAlP, InNAs, InNSb, InPAs, InPSb, GaAlNP, etc.; a quaternary compound, such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, etc.; and any combination thereof. In an embodiment, a Group III-V semiconductor compound may further include a Group Il element. Examples of a Group III-V semiconductor compound further including a Group II element may include InZnP, InGaZnP, InAlZnP, etc.

Examples of a Group III-VI semiconductor compound may include: a binary compound, such as GaS, GaSe, Ga₂Se₃, GaTe, InS, InSe, In₂S₃, In₂Se₃, InTe, etc.; a ternary compound, such as InGaSs, InGaSes, etc.; and any combination thereof.

Examples of a Group I-III-VI semiconductor compound may include: a ternary compound, such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, AgAlO₂, etc.; a quaternary compound, such as AgInGaS₂, AgInGaSe₂, etc.; and any combination thereof.

Examples of a Group IV-VI semiconductor compound may include: a binary compound, such as SnS, SnSe, SnTe, PbS, PbSe, PbTe, etc.; a ternary compound, such as SnSeS, SnSeTe, SnSTe, PbSeS, PbSeTe, PbSTe, SnPbS, SnPbSe, SnPbTe, etc.; a quaternary compound, such as SnPbSSe, SnPbSeTe, SnPbSTe, etc.; and any combination thereof.

Examples of a Group IV element or compound may include: a single element material, such as Si, Ge, etc.; a binary compound, such as SiC, SiGe, etc.; and any combination thereof.

Each element included in a compound, such as a binary compound, a ternary compound, or a quaternary compound, may be present in a particle at a uniform concentration or at a non-uniform concentration. The formulae of the quantum dot compounds as described above may refer to the types of elements included in each compound, and the ratios of elements in these compounds may vary. For example, AgInGaS₂ may refer to AgInₓGa₁₋ₓS₂ (where x is a real number between 0 and 1).

The first shell 20 of the quantum dot 100 may serve as a protective layer that prevents chemical degeneration of the core to maintain semiconductor characteristics, and/or may serve as a charging layer that imparts electrophoretic characteristics to the quantum dot 100. The first shell 20 may be single-layered or multi-layered. An interface between the core 10 and the first shell 20 may have a concentration gradient in which the concentration of an element that is present in the first shell 20 decreases toward the core 10.

The first shell 20 of the quantum dot 100 may further include a metal oxide, a metalloid oxide, a non-metal oxide, a semiconductor compound, or any combination thereof. Examples of a metal oxide, a metalloid oxide, or a non-metal oxide may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, etc.; a ternary compound, such as MgAl₂O₄, CoFe₂O₄, NiFe₂O₄, CoMn₂O₄, etc.; or any combination thereof.

Examples of a semiconductor compound may include; as described herein: a Group II-VI semiconductor compound; a Group III-V semiconductor compound; a Group III-VI semiconductor compound; a Group I-III-VI semiconductor compound; a Group IV-VI semiconductor compound; or any combination thereof. For example, the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, or any combination thereof.

Since an energy band gap may be adjusted by controlling a size of the quantum dot 100, light having various wavelength bands may be obtained from a quantum dot emission layer. Accordingly, by using quantum dots of different sizes, a light-emitting device that emits light of various wavelengths may be implemented. For example, the size of the quantum dots 100 or a ratio of elements in a quantum dot compound may be adjusted to emit red light, green light, and/or blue light. Through such adjustments, the quantum dots 100 may be configured to emit white light by a combination of light of various colors.

### [Method of Manufacturing Quantum Dot]

According to an embodiment, a method of manufacturing a quantum dot may include: manufacturing a core including copper (Cu), a Group III element, and a Group VI element; and manufacturing a first shell covering the core, wherein a full width at half maximum (FWHM) of an emission wavelength spectrum of the core may be equal to or less than about 55 nm.

With respect to the method of manufacturing a quantum dot according to embodiments, the quantum dot described herein may be a quantum dot as described above.

According to an embodiment, the manufacturing of the core may include manufacturing the core by using a composition for forming a core, wherein the composition includes a copper precursor, a Group III element-containing precursor, and a Group VI element-containing precursor.

According to an embodiment, the manufacturing of the core may include heat-treating the composition for forming a core at a temperature more than 240° C. but not more than about 320° C.

The composition for forming a core may include: a first composition for forming a core, which includes a copper precursor and a Group III element-containing precursor; a second composition for forming a core, which includes the first composition for forming a core and a Group VI element-containing precursor; and a third composition for forming a core, which includes the second composition for forming a core, a copper precursor, and a Group III element-containing precursor.

According to an embodiment, the manufacturing of the core may include:
subjecting the first composition for forming a core to undergo a reaction at a low temperature;
forming a second composition for forming a core by adding a Group VI element-containing precursor to the first composition for forming a core that has undergone a reaction;
heat-treating the second composition for forming a core at a temperature equal to or less than about 240° C.;
forming a third composition for forming a core by adding a copper precursor and a Group Ill element-containing precursor to the heat-treated second composition for forming a core; and
heat-treating the third composition for forming a core, wherein
the heat-treating of the third composition for forming a core may be performed at a temperature more than 240° C. but not more than about 320° C.

For example, the heat-treating of the third composition for forming a core may be performed at a temperature more than 240° C. but not more than about 320° C., at a temperature more than 240° C. but not more than about 310° C., at a temperature more than 240° C. but not more than about 300° C., at a temperature more than 240° C. but not more than about 290° C., at a temperature more than 240° C. but not more than about 280° C., at a temperature more than 240° C. but not more than about 270° C., at a temperature more than 240° C. but not more than about 260° C., at a temperature more than 240° C. but not more than about 250° C., at a temperature at least about 250° C. but not more than about 320° C., at a temperature at least about 250° C. but not more than about 310° C., at a temperature at least about 250° C. but not more than about 300° C., at a temperature at least about 250° C. but not more than about 290° C., at a temperature at least about 250° C. but not more than about 280° C., at a temperature at least about 250° C. but not more than about 270° C., at a temperature at least about 250° C. but not more than about 260° C., at a temperature at least about 260° C. but not more than about 320° C., at a temperature at least about 260° C. but not more than about 310° C., at a temperature at least about 260° C. but not more than about 300° C., at a temperature at least about 260° C. but not more than about 290° C., at a temperature at least about 260° C. but not more than about 280° C., at a temperature at least about 260° C. but not more than about 270° C., at a temperature at least about 270° C. but not more than about 320° C., at a temperature at least about 270° C. but not more than about 310° C., at a temperature at least about 270° C. but not more than about 300° C., at a temperature at least about 270° C. but not more than about 290° C., at a temperature at least about 270° C. but not more than about 280° C., at a temperature at least about 280° C. but not more than about 320° C., at a temperature at least about 280° C. but not more than about 310° C., at a temperature at least about 280° C. but not more than about 300° C., at a temperature at least about 280° C. but not more than about 290° C., at a temperature at least about 290° C. but not more than about 320° C., at a temperature at least about 290° C. but not more than about 310° C., at a temperature at least about 290° C. but not more than about 300° C., at a temperature at least about 300° C. but not more than about 320° C., at a temperature at least about 300° C. but not more than about 310° C., or at a temperature at least about 310° C. but not more than about 320° C.

By the method of manufacturing the quantum dot according to an embodiment including the heat-treating of the third composition for forming a core within any of the temperature ranges above, the core may be uniformly formed, the quantum dot may have ensured particle uniformity, and the composition of the quantum dot may be appropriately adjusted, thereby manufacturing a quantum dot having a narrow full width at half maximum and a low tail value.

According to an embodiment, the low temperature at which the first composition for forming a core undergoes a reaction may be equal to or less than about 150° C. For example, the low temperature at which the first composition for forming a core undergoes a reaction may be in a range of about 100° C. to about 150° C., in a range of about 110° C. to about 140° C., in a range of about 110° C. to about 130° C., or in a range of about 110° C. to about 125° C.

According to an embodiment, the manufacturing of the first shell may include manufacturing the first shell by using a composition for forming a first shell, wherein the composition may include a Group Il element-containing precursor and a Group VI element-containing precursor.

According to an embodiment, the manufacturing of the first shell may further include heat-treating the composition for forming a first shell at a temperature more than 240° C. but not more than about 320° C.

For example, the heat-treating of the composition for forming a first shell may be performed at a temperature more than 240° C. but not more than about 320° C., at a temperature more than 240° C. but not more than about 310° C., at a temperature more than 240° C. but not more than about 300° C., at a temperature more than 240° C. but not more than about 290° C., at a temperature more than 240° C. but not more than about 280° C., at a temperature more than 240° C. but not more than about 270° C., at a temperature more than 240° C. but not more than about 260° C., at a temperature more than 240° C. but not more than about 250° C., at a temperature at least about 250° C. but not more than about 320° C., at a temperature at least about 250° C. but not more than about 310° C., at a temperature at least about 250° C. but not more than about 300° C., at a temperature at least about 250° C. but not more than about 290° C., at a temperature at least about 250° C. but not more than about 280° C., at a temperature at least about 250° C. but not more than about 270° C., at a temperature at least about 250° C. but not more than about 260° C., at a temperature at least about 260° C. but not more than about 320° C., at a temperature at least about 260° C. but not more than about 310° C., at a temperature at least about 260° C. but not more than about 300° C., at a temperature at least about 260° C. but not more than about 290° C., at a temperature at least about 260° C. but not more than about 280° C., at a temperature at least about 260° C. but not more than about 270° C., at a temperature at least about 270° C. but not more than about 320° C., at a temperature at least about 270° C. but not more than about 310° C., at a temperature at least about 270° C. but not more than about 300° C., at a temperature at least about 270° C. but not more than about 290° C., at a temperature at least about 270° C. but not more than about 280° C., at a temperature at least about 280° C. but not more than about 320° C., at a temperature at least about 280° C. but not more than about 310° C., at a temperature at least about 280° C. but not more than about 300° C., at a temperature at least about 280° C. but not more than about 290° C., at a temperature at least about 290° C. but not more than about 320° C., at a temperature at least about 290° C. but not more than about 310° C., at a temperature at least about 290° C. but not more than about 300° C., at a temperature at least about 300° C. but not more than about 320° C., at a temperature at least about 300° C. but not more than about 310° C., or at a temperature at least about 310° C. but not more than about 320° C.

According to an embodiment, the method of manufacturing a quantum dot may further include, after manufacturing of the first shell, forming a second shell by using a composition for forming a second shell.

For example, the composition for forming a second shell may include a Group II element-containing precursor and a Group VI element-containing precursor.

According to an embodiment, a Group III element-containing precursor included in the first composition for forming a core, and a Group Ill element-containing precursor that is added when manufacturing the third composition for forming a core may be identical to or different from each other.

According to an embodiment, a Group VI element-containing precursor that is added when manufacturing the second composition for forming a core, and a Group VI element-containing precursor included in the composition for forming a first shell may be identical to or different from each other.

According to an embodiment, a Group Il element-containing precursor included in the composition for forming a first shell, and a Group II element-containing precursor included in the composition for forming a second shell may be identical to or different from each other.

According to an embodiment, a Group VI element-containing precursor included in the composition for forming a first shell, and a Group VI element-containing precursor included in the composition for forming a second shell may be identical to or different from each other.

According to an embodiment, the copper precursor may be copper or a copper compound.

For example, the copper precursor may be copper iodide, copper bromide, copper chloride, copper acetylacetonate, or any combination thereof.

According to an embodiment, the Group Il element-containing precursor may be: zinc or a zinc compound; cadmium or a cadmium compound; or mercury or a mercury compound.

For example, the Group II element-containing precursor may be zinc acetate, dimethyl zinc, diethyl zinc, zinc carboxylate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, cadmium oxide, dimethyl cadmium, diethyl cadmium, cadmium carbonate, cadmium acetate dihydrate, cadmium acetylacetonate, cadmium fluoride, cadmium chloride, cadmium iodide, cadmium bromide, cadmium perchlorate, cadmium phosphide, cadmium nitrate, cadmium sulfate, cadmium carboxylate, mercury iodide, mercury bromide, mercury fluoride, mercury cyanide, mercury nitrate, mercury perchlorate, mercury sulfate, mercury oxide, mercury carbonate, mercury carboxylate, or the like.

According to an embodiment, the Group III element-containing precursor may be: aluminum or an aluminum compound; gallium or a gallium compound; indium or an indium compound; or thallium or a thallium compound.

For example, the Group III element-containing precursor may be aluminum phosphate, aluminum acetylacetonate, aluminum chloride, aluminum fluoride, aluminum oxide, aluminum nitrate, aluminum sulfate, gallium acetylacetonate, gallium chloride, gallium fluoride, gallium oxide, gallium nitrate, gallium sulfate, indium acetate, indium chloride, indium oxide, indium nitrate, indium sulfate, indium carboxylate, or the like.

According to an embodiment, the Group VI element-containing precursor may be: sulfur or a sulfur compound; selenium or a selenium compound; or tellurium or a tellurium compound.

For example, the Group VI element-containing precursor may be sulfur, sulfur-containing oleylamine, phosphine sulfide, trialkylphosphine sulfide, trialkenylphosphine sulfide, alkylamino sulfide, alkenylamino sulfide, alkylthiol, selenium, trialkylphosphine selenide, trialkenylphosphine selenide, alkylamino selenide, alkenylamino selenide, trialkylphosphine telluride, trialkenylphosphine telluride, alkylamino telluride, alkenylamino telluride, or the like.

According to an embodiment, the Group III element-containing precursor when forming the core may be gallium chloride, indium chloride, or any combination thereof.

According to an embodiment, the Group VI element-containing precursor when forming the core may be sulfur-containing oleylamine.

According to an embodiment, the Group II element-containing precursor when forming the first shell may be zinc acetate (Zn(OA)₂), and the Group VI element-containing precursor when forming the first shell may be trioctylphosphine sulfide (TOP-S).

According to an embodiment, the composition for forming a core and the composition for forming a first shell may each further include a solvent.

According to an embodiment, the solvent may be an organic solvent. For example, the solvent may include 1-octadecene (ODE), trioctylamine (TOA), trioctylphosphine (TOP), oleylamine, or any combination thereof.

According to an embodiment, the manufacturing of the core may include heat-treating the composition for forming a core at a temperature more than 240° C. but not more than about 320° C. to cause a cation exchange reaction.

According to an embodiment, the method of manufacturing a quantum dot may further include treating the surface of the first shell or the second shell with an organic ligand or a metal halide.

According to an embodiment, the organic ligand may include C₄-C₃₀ fatty acids.

For example, the organic ligand may include palmitic acid, palmitoleic acid, stearic acid, oleic acid, trioctylphosphine, trioctylphosphine oxide, oleylamine, octylamine, trioctyl amine, hexadecylamine, octanethiol, dodecanethiol, hexylphosphonic acid, tetradecylphosphonic acid, octylphosphonic acid, or the like.

The method of manufacturing a quantum dot according to an embodiment may include manufacturing the core by using a composition for forming a core, and heat-treating the composition at a temperature more than 240° C. but not more than about 320° C., so that the core may have an appropriate composition ratio, so that the core may be evenly synthesized to thereby achieve a narrow full width at half maximum and a low tail value, and so that the shell on the core may be evenly formed, thereby improving chemical stability and PL characteristics.

Accordingly, the quantum dot according to an embodiment may achieve an excellent quantum yield (QY) based on a narrow full width at half maximum and a low tail value, thereby enabling the provision of a quantum dot with improved chemical stability and PL characteristics.

Therefore, high-quality optical members and electronic apparatuses may be provided by using the quantum dot.

### [Apparatus]

The quantum dots may be used in various electronic apparatuses. Accordingly, according to another embodiment, an electronic apparatus may include the quantum dots.

According to an embodiment, an electronic apparatus may include: a light source; and a color conversion member arranged in an optical path of light emitted from the light source, wherein the color conversion member may include the quantum dots.

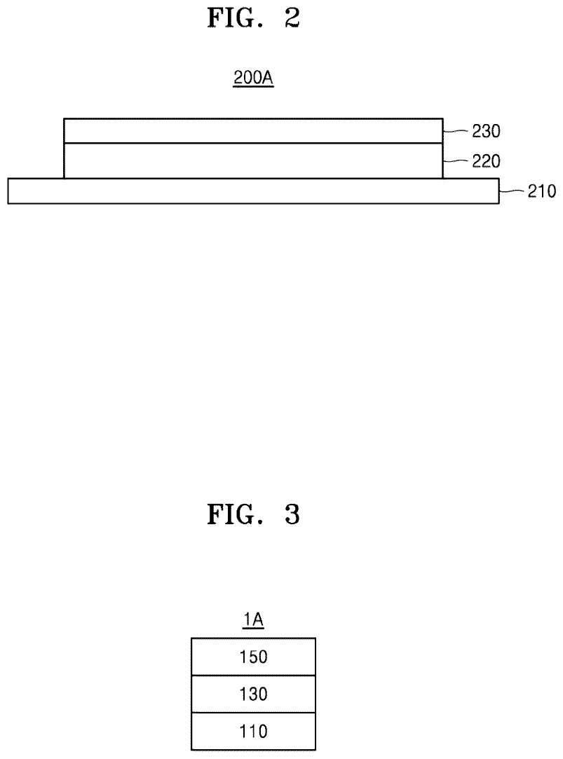

### [Description of FIG. 2]

FIG. 2 is a schematic cross-sectional view of an electronic apparatus 200A according to an embodiment. The electronic apparatus 200A of FIG. 2 may include: a substrate 210; a light source on the substrate 210; and a color conversion member 230 on the light source 220.

For example, the light source 220 may be a backlight unit (BLU) for use in liquid crystal displays (LCD), a fluorescent lamp, a light-emitting device, an organic light-emitting device, or a quantum-dot light-emitting device (QLED), or any combination thereof. The color conversion member 230 may be arranged in at least one traveling direction of light emitted from the light source 220.

At least one region of the color conversion member 230 of the electronic apparatus 200A may include the quantum dots, and the region may absorb light emitted from the light source to emit red light with a maximum emission wavelength in a range of about 600 nm to about 700 nm or to emit blue light with a maximum emission wavelength in a range of about 180 nm to about 430 nm.

In the specification, the expression that “the color conversion member 230 is arranged in at least one traveling direction of light emitted from the light source 220” does not exclude other elements from being further included between the color conversion member 230 and the light source 220.

For example, a polarizing plate, a liquid crystal layer, a light guide plate, a diffusion plate, a prism sheet, a microlens sheet, a luminance enhancing sheet, a reflective film, a color filter, or any combination thereof may be further included between the light source 220 and the color conversion member 230.

In embodiments, a polarizing plate, a liquid crystal layer, a light guide plate, a diffusion plate, a prism sheet, a microlens sheet, a luminance enhancing sheet, a reflective film, a color filter, or any combination thereof may be further included on the color conversion member 230.

The electronic apparatus 200A illustrated in FIG. 2 is an embodiment according to the disclosure, and may have any various shapes according to the related art, and thus, may further include various structures according to the related art.

According to another embodiment, the electronic apparatus may include a structure that includes a light source, a light guide plate, a color conversion member, a first polarizing plate, a liquid crystal layer, a color filter, and a second polarizing plate, which may be arranged in that order.

According to another embodiment, the electronic apparatus may include a structure that includes a light source, a light guide plate, a first polarizing plate, a liquid crystal layer, a second polarizing plate, and a color conversion member, which may be arranged in that order.

In the embodiments described above, the color filter may include a pigment or a dye. In the embodiments described above, one of the first polarizing plate and the second polarizing plate may be a vertical polarizing plate, and the other thereof may be a horizontal polarizing plate.

### [Light-Emitting Device]

In embodiments, the quantum dots as described herein may be used as an emitter. Therefore, according to another embodiment, a light-emitting device may include: a first electrode; a second electrode facing the first electrode; an interlayer between the first electrode and the second electrode that includes an emission layer; and the quantum dots. For example, the emission layer of the light-emitting device may include the quantum dots. The light-emitting device may further include a hole transport region between the first electrode and the emission layer, an electron transport region between the emission layer and the second electrode, or a combination thereof.

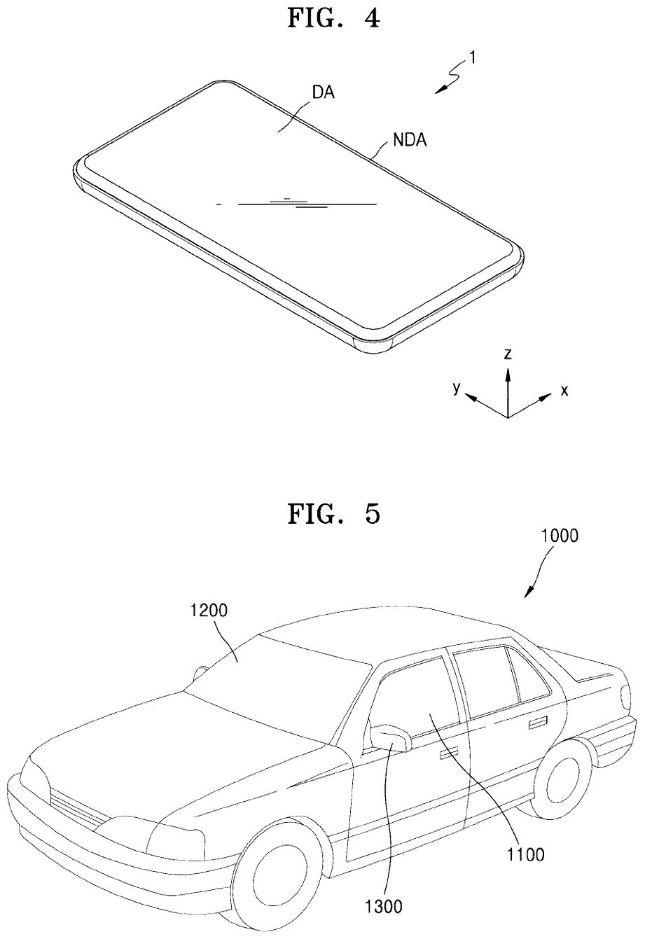

### [Description of FIG. 3]

FIG. 3 is a schematic cross-sectional view of a light-emitting device 1A according to an embodiment.

The light-emitting device 1A may include: a first electrode 110; a second electrode 150 facing the first electrode 110; an interlayer 130 between the first electrode 110 and the second electrode 150 and including an emission layer; and quantum dots. Hereinafter, each layer of the light-emitting device 1A will be described.

According to an embodiment,
the first electrode of the light-emitting device may be an anode,
the second electrode of the light-emitting device may be a cathode,
the interlayer may further include a hole transport region between the first electrode and the emission layer, and an electron transport region between the emission layer and the second electrode,
the hole transport region may include a hole injection layer, a hole transport layer, an emission auxiliary layer, an electron blocking layer, or any combination thereof, and
the electron transport region may include a buffer layer, a hole blocking layer, an electron control layer, an electron transport layer, an electron injection layer, or any combination thereof.

According to another embodiment, the quantum dots may be included between the first electrode and the second electrode of the light-emitting device. Therefore, the quantum dots may be included in the interlayer of the light-emitting device. For example, the emission layer of the interlayer may include the quantum dots.

According to another embodiment, the emission layer of the interlayer in the light-emitting device may include a dopant and a host, and the host may include the quantum dots. For example, the quantum dots may serve as a host. The emission layer may emit red light, green light, blue light, and/or white light. For example, the emission layer may emit red light. The red light may have, for example, a maximum emission wavelength in a range of about 600 nm to about 700 nm.

According to another embodiment, the emission layer of the interlayer in the light-emitting device may include a dopant and a host, the host may include the quantum dots, and the dopant may emit blue light or red light. For example, the dopant may include a transition metal and ligand(s) in the number of m, and m may be an integer from 1 to 6. The ligand(s) in the number of m may be identical to or different from each other, at least one of the ligand(s) in the number of m may be bonded to the transition metal via a carbon-transition metal bond, and the carbon-transition metal bond may be a coordinate bond. For example, at least one of the ligand(s) in the number of m may be a carbene ligand (for example, Ir(pmp)₃ or the like). The transition metal may be, for example, iridium, platinum, osmium, palladium, rhodium, gold, or the like. Further details on the emission layer and the dopant may be the same as described herein.

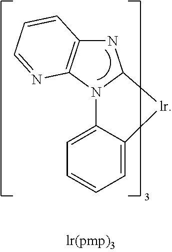

According to another embodiment, the light-emitting device may include a capping layer outside the first electrode or outside the second electrode.

For example, the light-emitting device may further include at least one of a first capping layer outside the first electrode and a second capping layer outside the second electrode, and the quantum dots may be included in at least one of the first capping layer and the second capping layer. Further details on the first capping layer and/or second capping layer may be the same as described herein.

According to an embodiment, the light-emitting device may include:
a first capping layer outside the first electrode and including the quantum dot;
a second capping layer outside the second electrode and including the quantum dot; or
the first capping layer and the second capping layer.

In the specification, the expression “(the interlayer and/or capping layer) includes quantum dot” may be interpreted as “(the interlayer and/or capping layer) may include the quantum dot or two or more different quantum dots.”

In the specification, the term “interlayer” may refer to a single layer and/or all layers between the first electrode and the second electrode of the light-emitting device.

According to another embodiment, an electronic apparatus may include the quantum dots and/or the light-emitting device as described herein. The electronic apparatus may further include a thin-film transistor. For example, the electronic apparatus may further include a thin-film transistor including a source electrode and a drain electrode, wherein the first electrode of the light-emitting device may be electrically connected to the source electrode or the drain electrode. In an embodiment, the electronic apparatus may further include a color filter, a color conversion layer, a touch screen layer, a polarizing layer, or any combination thereof. Further details on the electronic apparatus may be the same as described herein.

Hereinafter, the structure of the light-emitting device 1A according to an embodiment and a method of manufacturing the light-emitting device 1A will be described with reference to FIG. 3.

FIG. 1 is a schematic cross-sectional view of a light-emitting device 1A according to an embodiment. The light-emitting device 1A may include a first electrode 110, an interlayer 130, and a second electrode 150.

### [First Electrode 110]

In FIG. 3, a substrate may be further included under the first electrode 110 or on the second electrode 150. The substrate may be a glass substrate or a plastic substrate. In an embodiment, the substrate may be a flexible substrate, and may include plastics with excellent heat resistance and durability, such as polyimide, polyethylene terephthalate (PET), polycarbonate, polyethylene naphthalate, polyarylate (PAR), polyetherimide, or any combination thereof.

The first electrode 110 may be formed by, for example, depositing or sputtering a material for forming the first electrode 110 on the substrate. When the first electrode 110 is an anode, a material for forming the first electrode 110 may be a high-work function material that facilitates injection of holes.

The first electrode 110 may be a reflective electrode, a transflective electrode, or a transmissive electrode. When the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In an embodiment, when the first electrode 110 is a transflective electrode or a reflective electrode, a material for forming the first electrode 110 may include magnesium (Mg), silver (Ag), aluminum (AI), aluminum-lithium (Al—Li), calcium (Ca), magnesium-indium (Mg—In), magnesium-silver (Mg—Ag), or any combination thereof.

The first electrode 110 may have a structure consisting of a single layer or a structure including multiple layers. For example, the first electrode 110 may have a three-layered structure of ITO/Ag/ITO.

### [Interlayer 130]

The interlayer 130 may be arranged on the first electrode 110. The interlayer 130 may include an emission layer.

The interlayer 130 may further include a hole transport region between the first electrode 110 and the emission layer, and an electron transport region between the emission layer and the second electrode 150.

The interlayer 130 may further include, in addition to various organic materials, a metal-containing compound such as an organometallic compound, an inorganic material such as quantum dots, or the like.

In an embodiment, the interlayer 130 may include two or more emitting units stacked between the first electrode 110 and the second electrode 150, and at least one charge generation layer arranged between adjacent units among the two or more emitting units. When the interlayer 130 includes the two or more emitting units and the at least one charge generation layer, the light-emitting device 1A may be a tandem light-emitting device.

### [Hole Transport Region in Interlayer 130]

The hole transport region may have a structure consisting of a layer consisting of a single material, a structure consisting of a layer including different materials, or a structure including multiple layers including different materials.

The hole transport region may include a hole injection layer, a hole transport layer, an emission auxiliary layer, an electron blocking layer, or any combination thereof.

In embodiments, the hole transport region may have a multi-layered structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein the layers of each structure may be stacked from the first electrode 110 in its respective stated order, but the structure of the hole transport region is not limited thereto.

In embodiments, the hole transport region may include a compound represented by Formula 201, a compound represented by Formula 202, or any combination thereof:

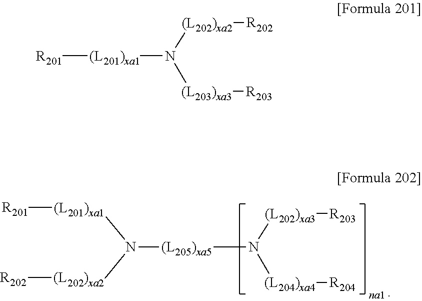

In Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group (for example, a carbazole group, etc.) unsubstituted or substituted with at least one R₁₀ₐ (for example, Compound HT16, etc.),
R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer from 1 to 4.

In an embodiment, the compound represented by Formula 201 and the compound represented by Formula 202 may each independently include at least one of groups represented by Formulae CY201 to CY217:

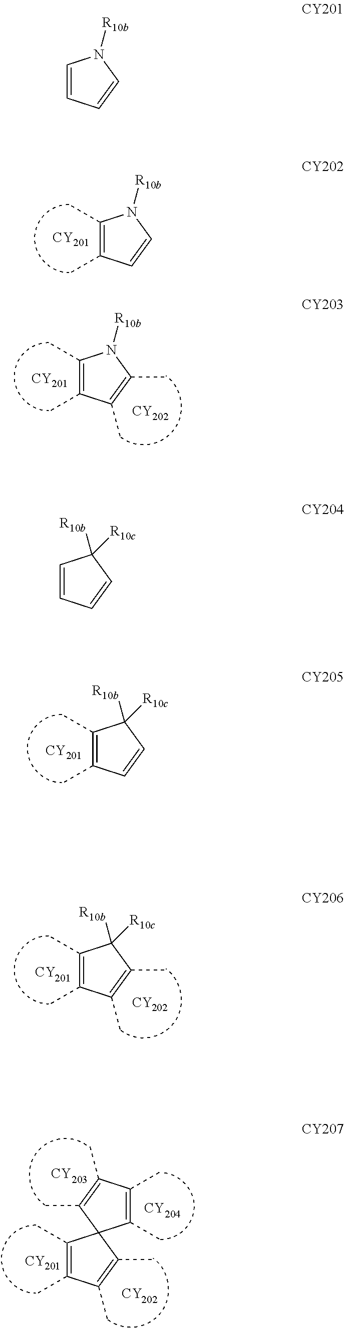

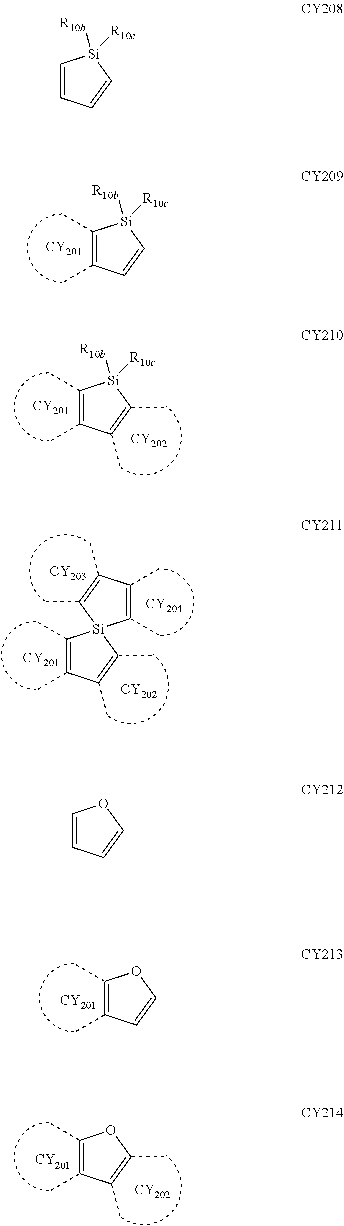

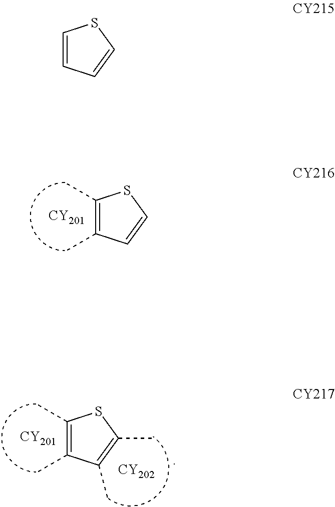

In Formulae CY201 to CY217, R_{10b} and R_{10c} may each independently be the same as described with respect to R₁₀ₐ, ring CY201 to ring CY204 may each independently be a C₃-C₂₀ carbocyclic group or a C₁-C₂₀ heterocyclic group, and at least one hydrogen in Formulae CY201 to CY217 may be unsubstituted or substituted with R₁₀ₐ as described herein.

According to an embodiment, in Formulae CY201 to CY217, ring CY₂₀₁ to ring CY₂₀₄ may each independently be a benzene group, a naphthalene group, a phenanthrene group, or an anthracene group.

According to another embodiment, the compound represented by Formula 201 and the compound represented by Formula 202 may each independently include at least one of groups represented by Formulae CY201 to CY203.

According to another embodiment, the compound represented by Formula 201 may include at least one of groups represented by Formulae CY201 to CY203 and at least one of the groups represented by Formulae CY204 to CY217.

According to another embodiment, in Formula 201, xa1 may be 1, R₂₀₁ may be a group represented by one of Formulae CY201 to CY203, xa2 may be 0, and R₂₀₂ may be a group represented by one of Formulae CY204 to CY207.

According to another embodiment, the compound represented by Formula 201 and the compound represented by Formula 202 may each not include groups represented by Formulae CY201 to CY203.

According to another embodiment, the compound represented by Formula 201 and the compound represented by Formula 202 may each not include groups represented by Formulae CY201 to CY203, and may each independently include at least one of groups represented by Formulae CY204 to CY217.

According to another embodiment, the compound represented by Formula 201 and the compound represented by Formula 202 may each not include groups represented by Formulae CY201 to CY217.

In an embodiment, the hole transport region may include one of Compounds HT1 to HT46, m-MTDATA, TDATA, 2-TNATA, NPB (NPD), β-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), or any combination thereof:

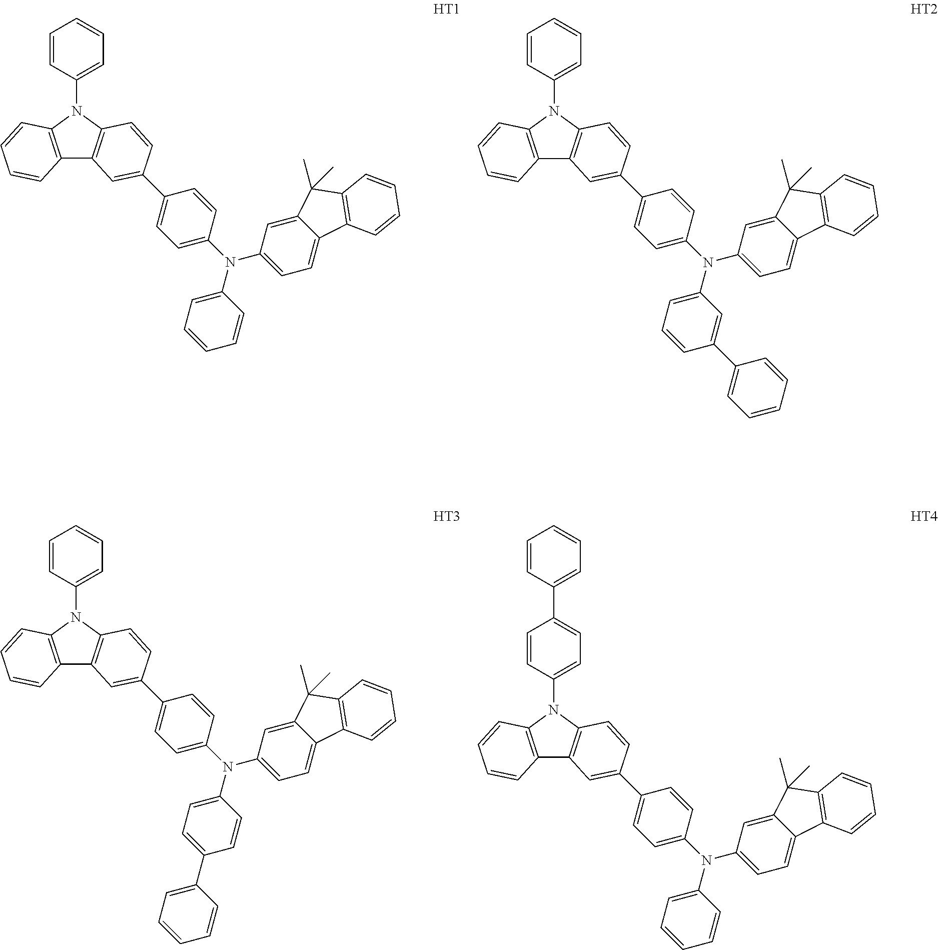 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

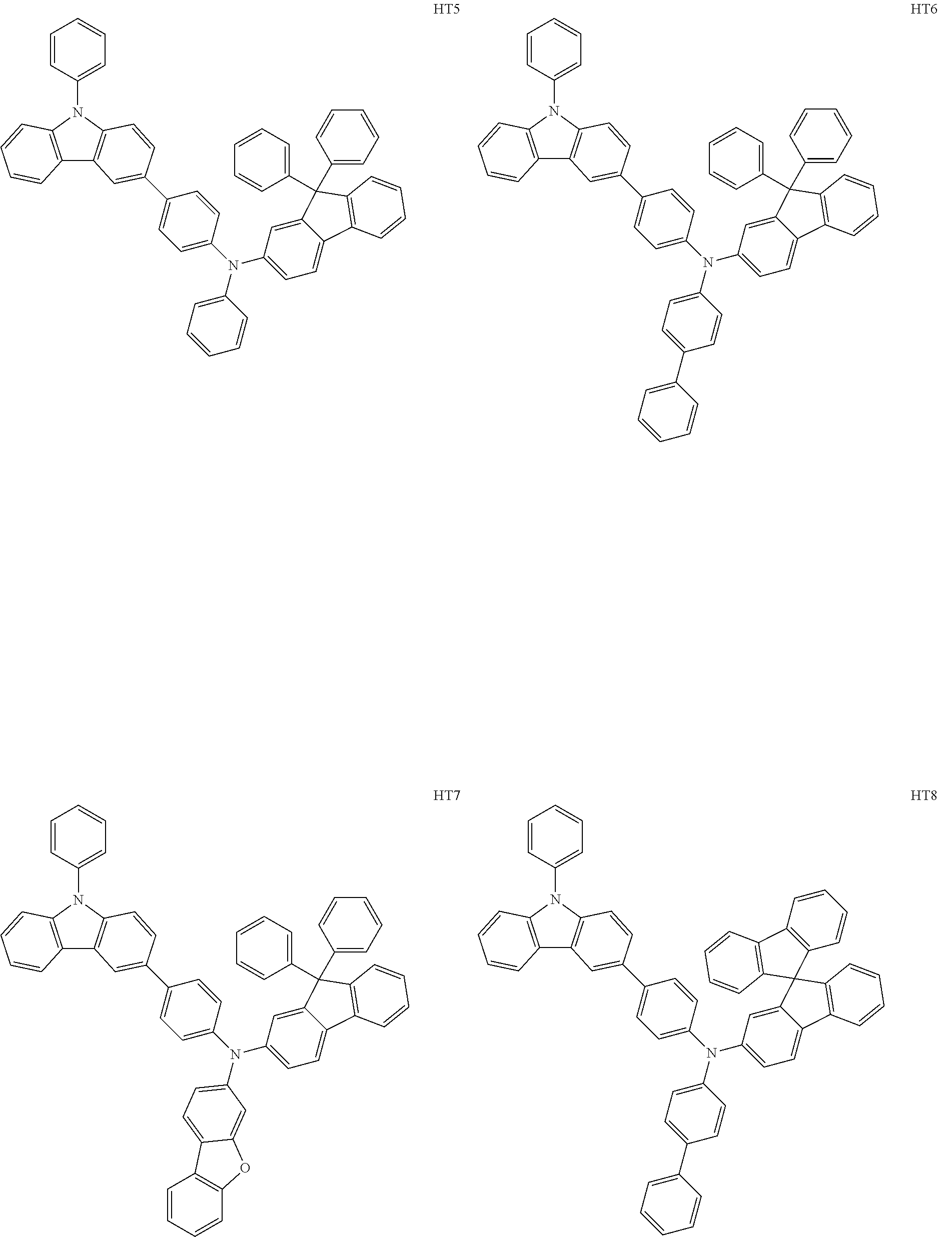 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

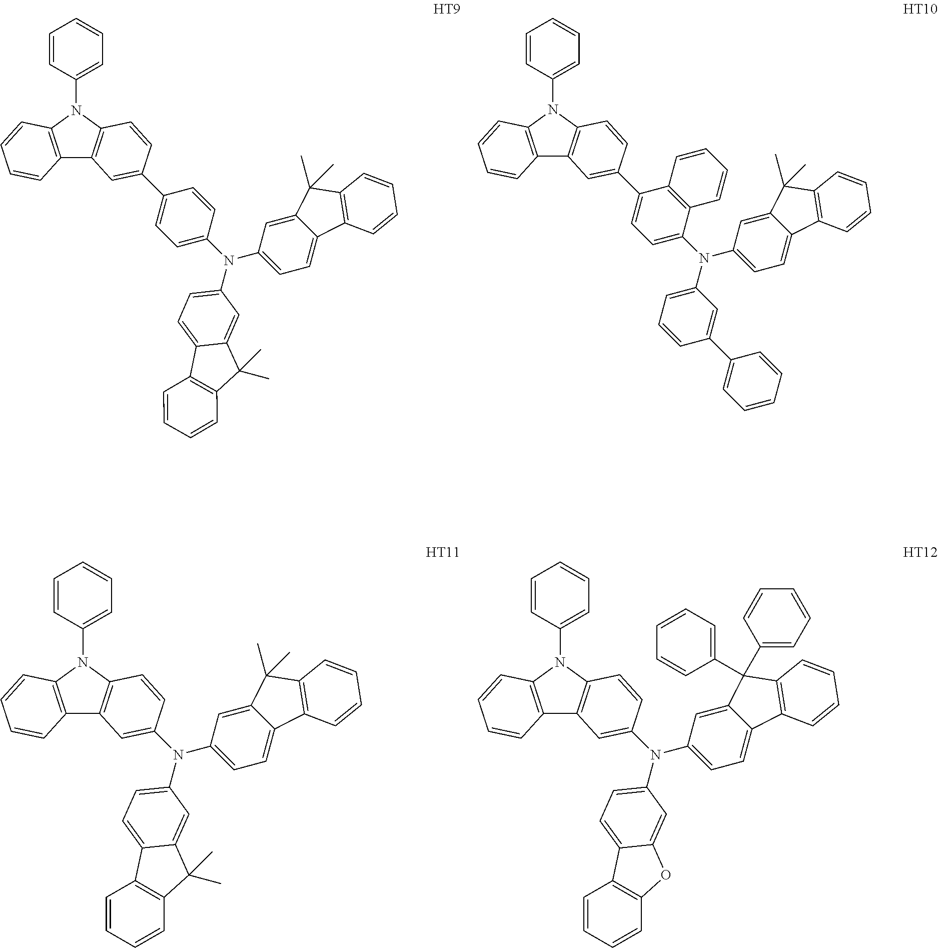 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

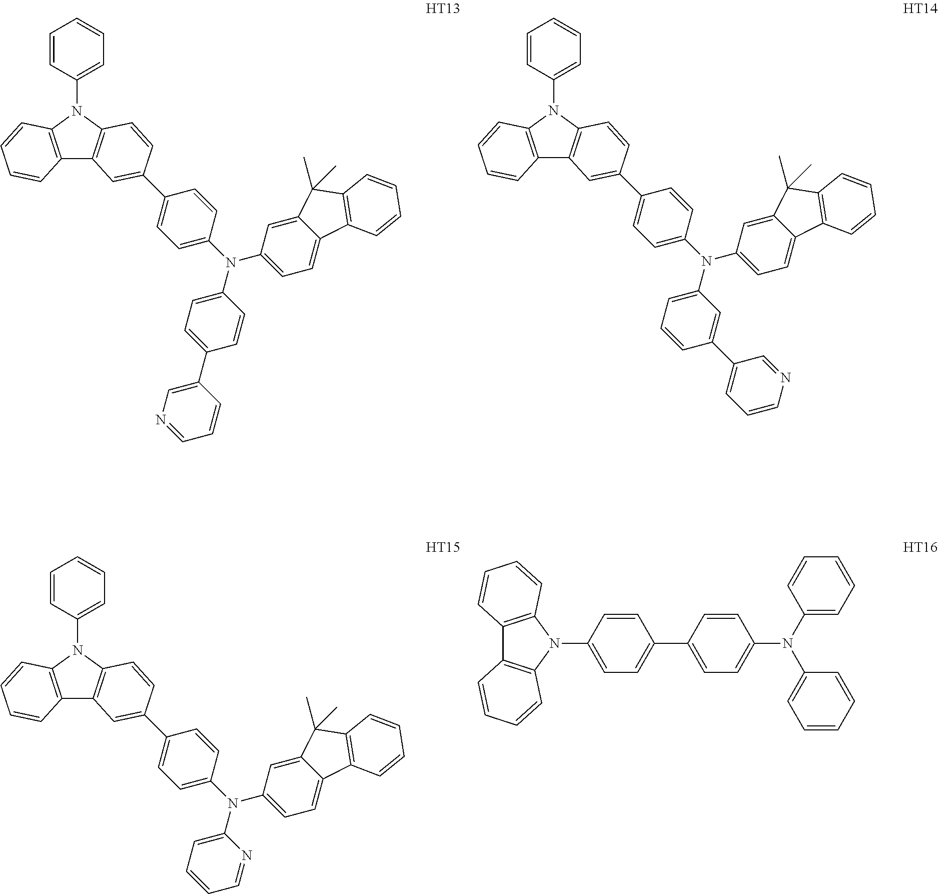 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1]

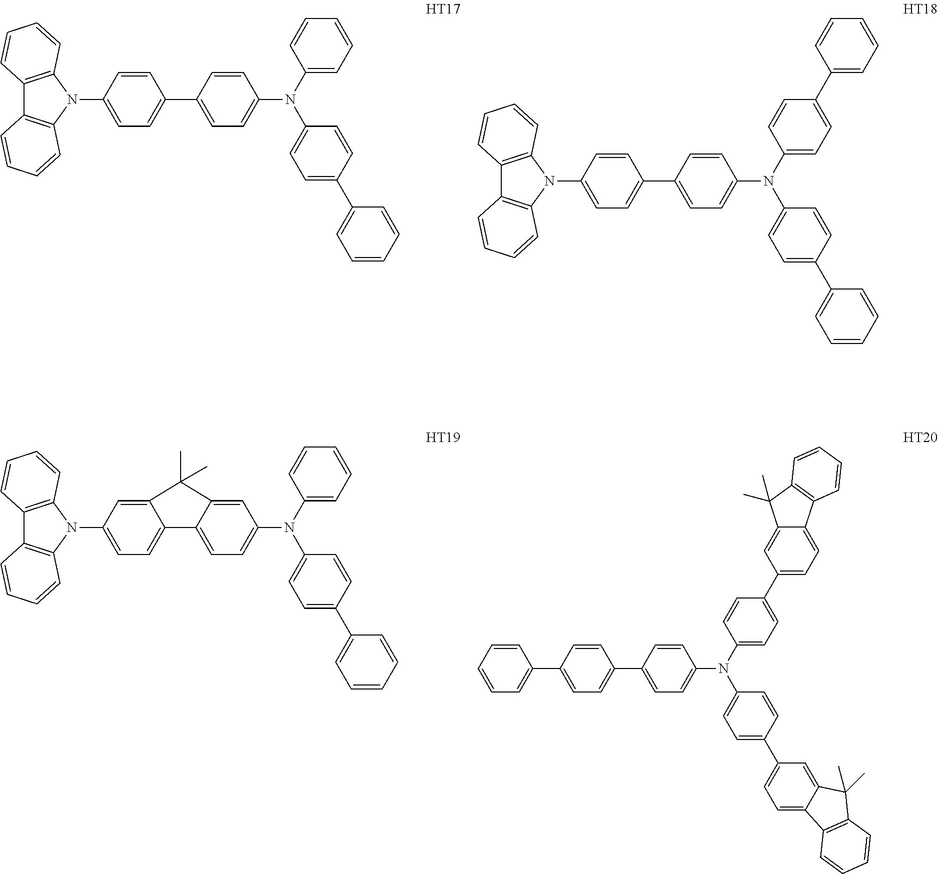 [SMILES: c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21]

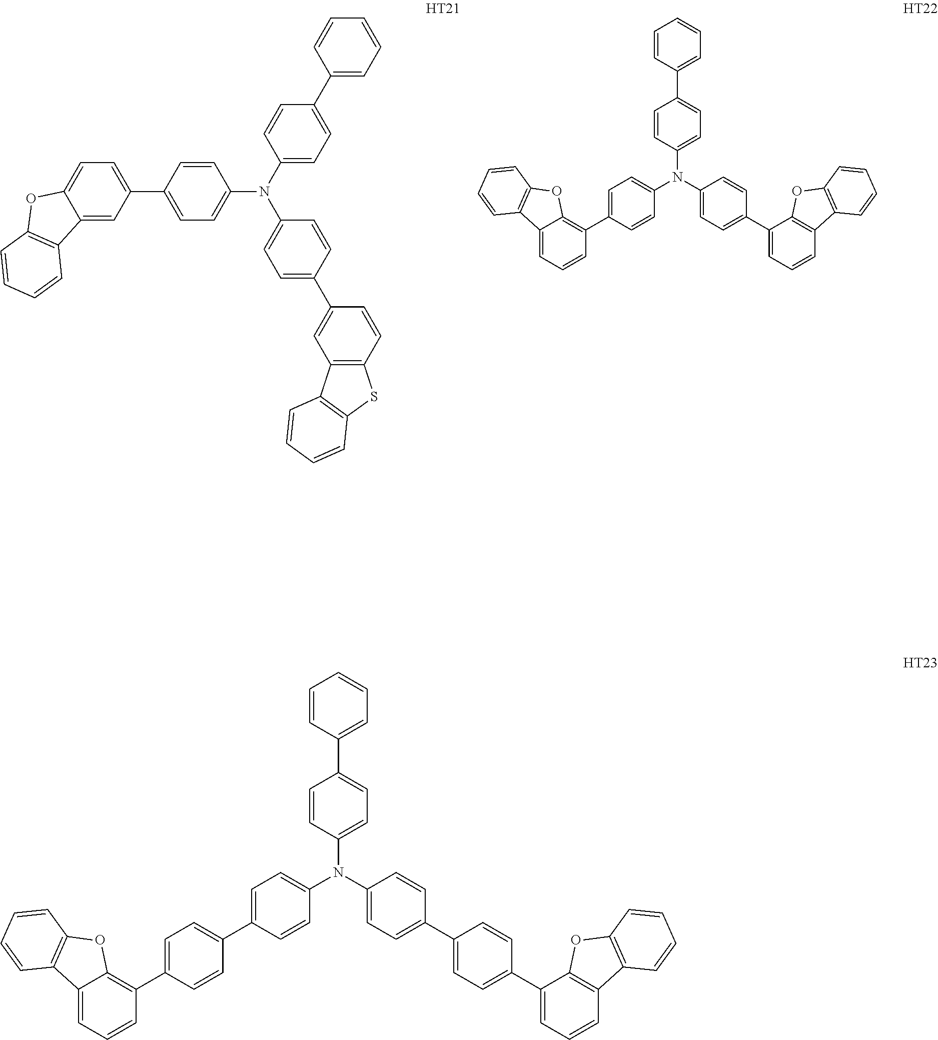 [SMILES: c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

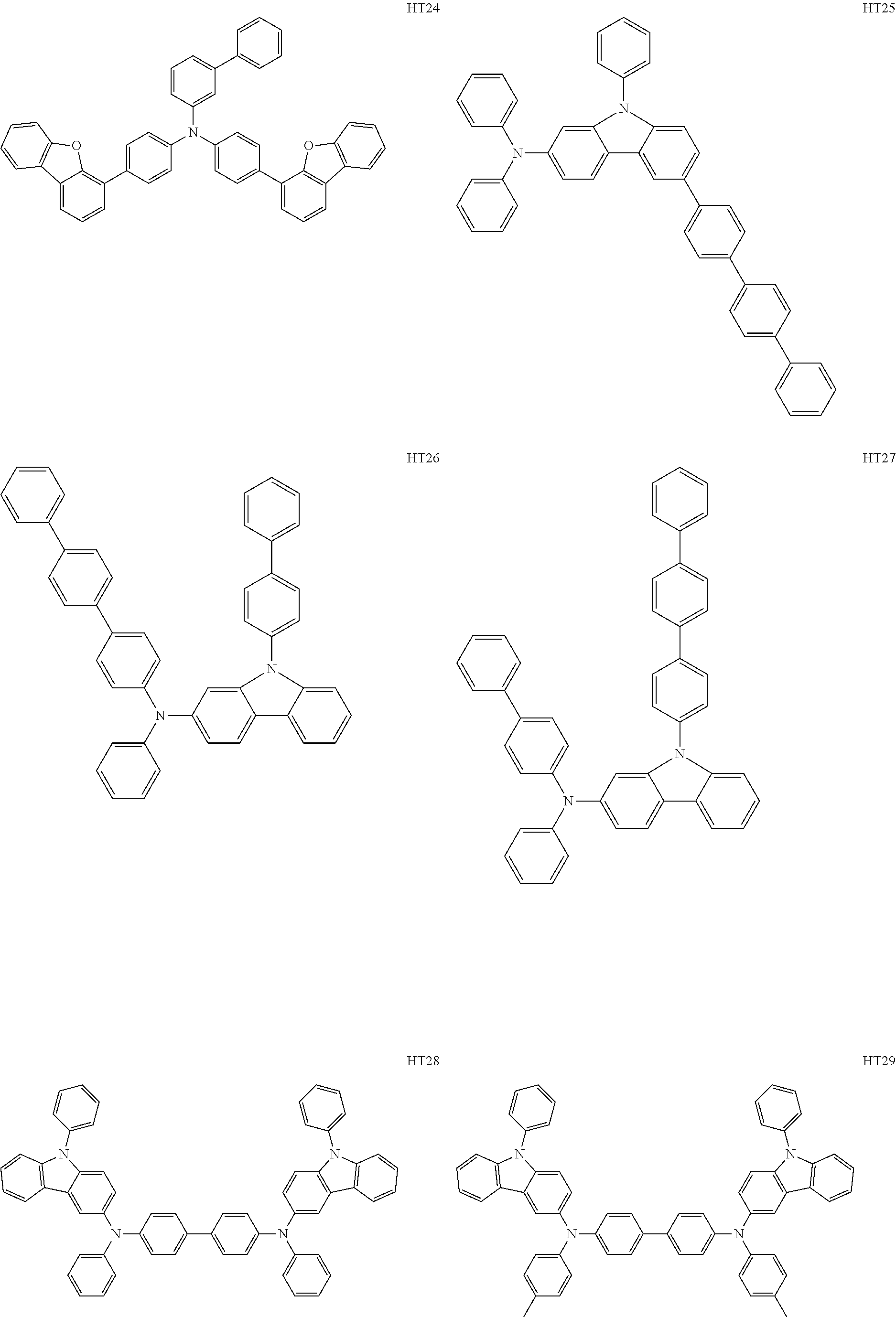

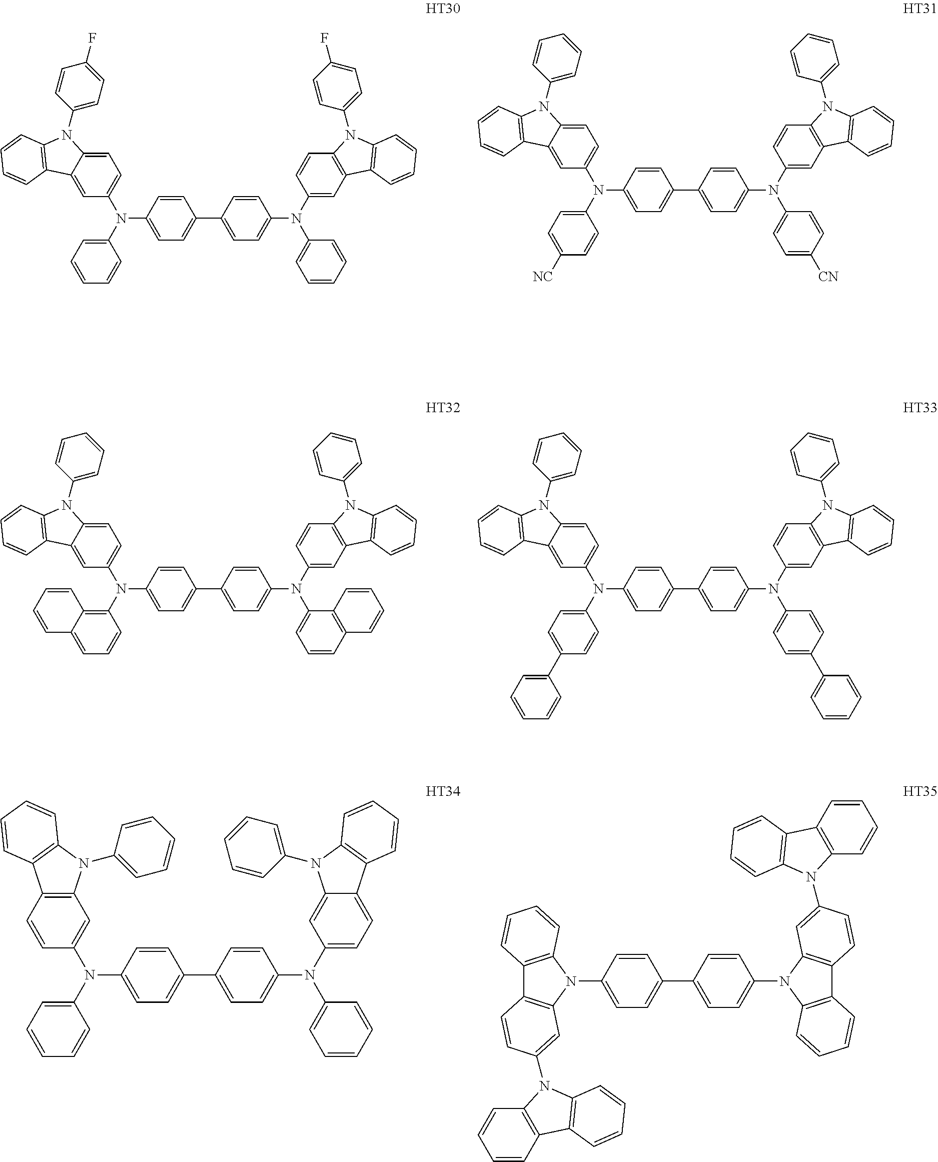

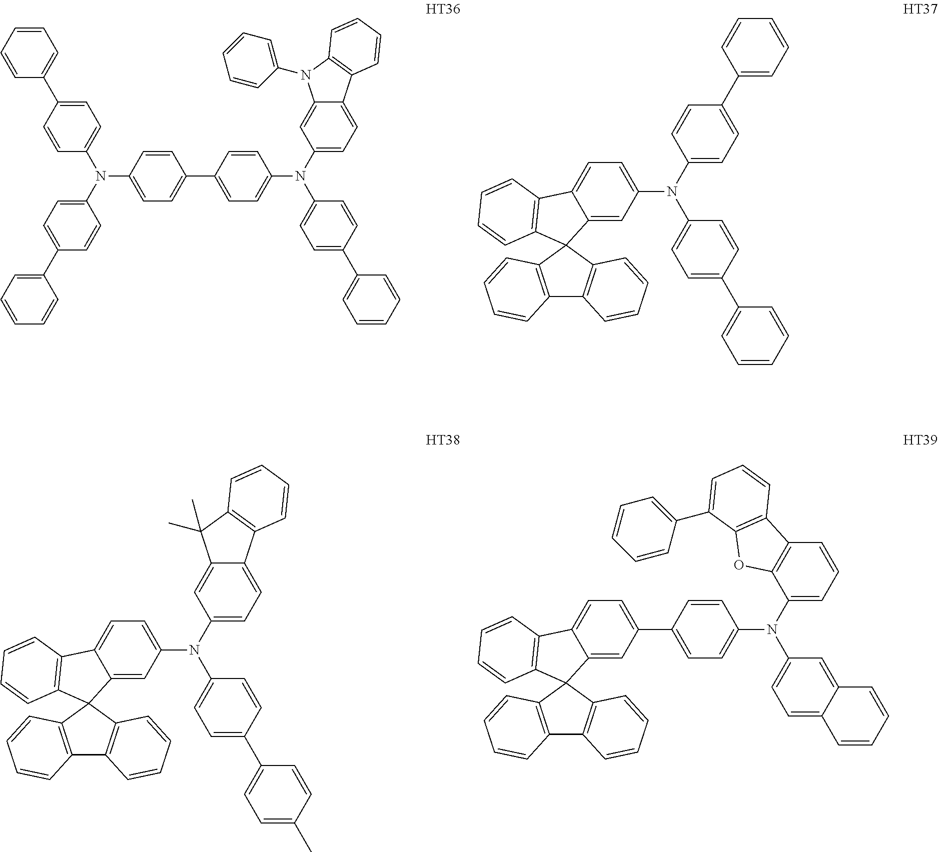 [SMILES: c1ccc(-c2ccc(N(c3ccc(-c4ccccc4)cc3)c3ccc(-c4ccc(N(c5ccc(-c6ccccc6)cc5)c5ccc6c7ccccc7n(-c7ccccc7)c6c5)cc4)cc3)cc2)cc1 ; c1ccc(-c2ccc(N(c3ccc(-c4ccccc4)cc3)c3ccc4c(c3)C3(c5ccccc5-c5ccccc53)c3ccccc3-4)cc2)cc1 ; Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1]

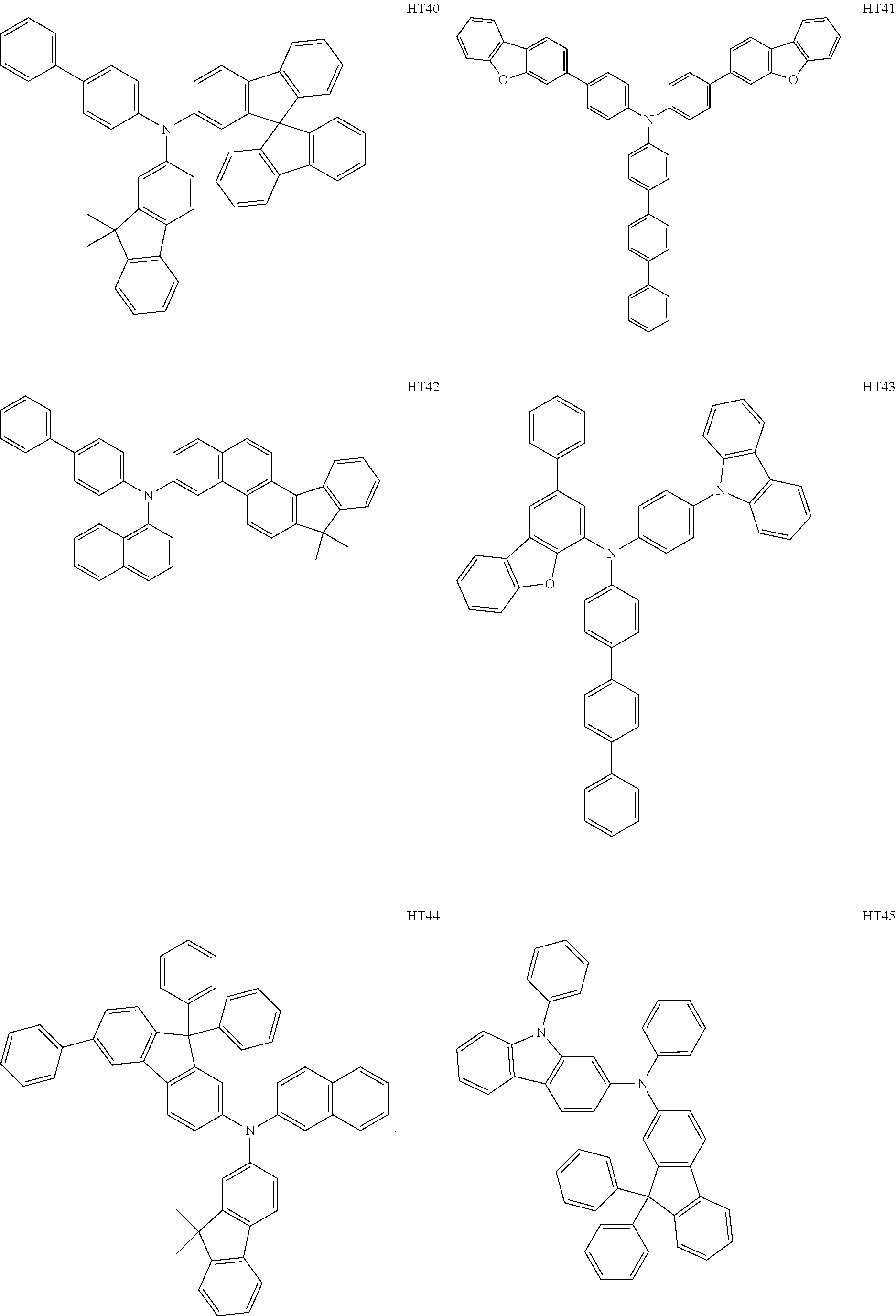

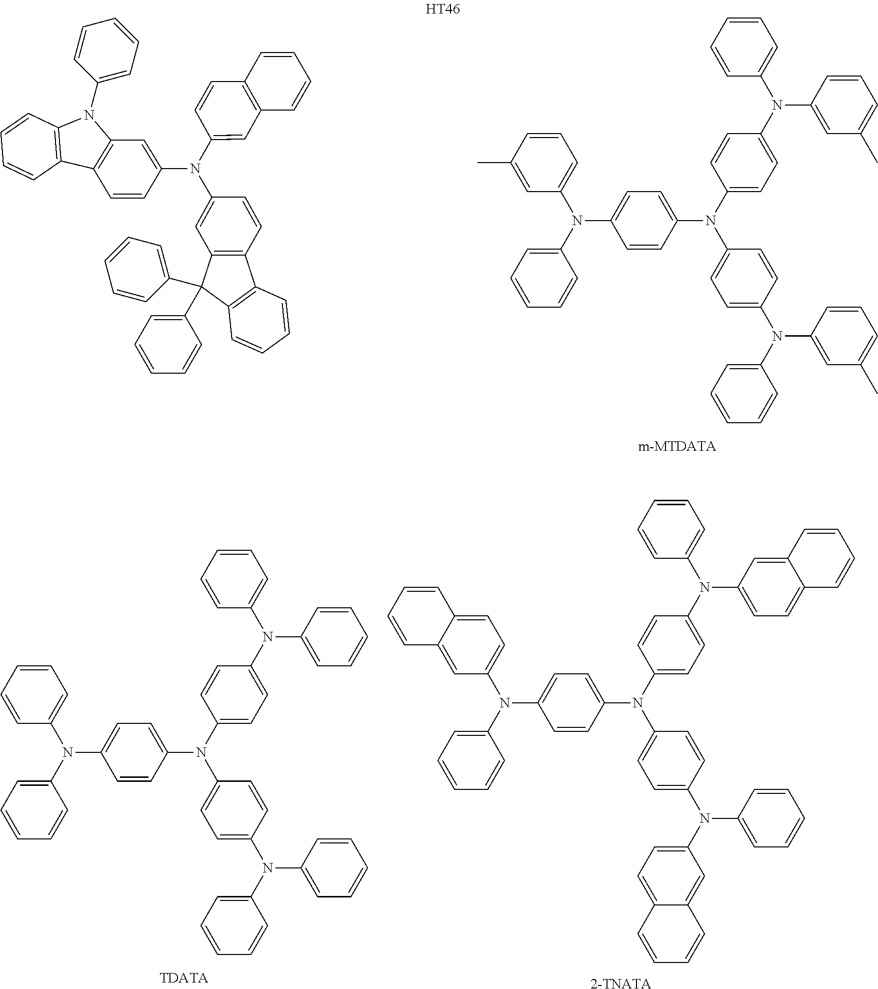

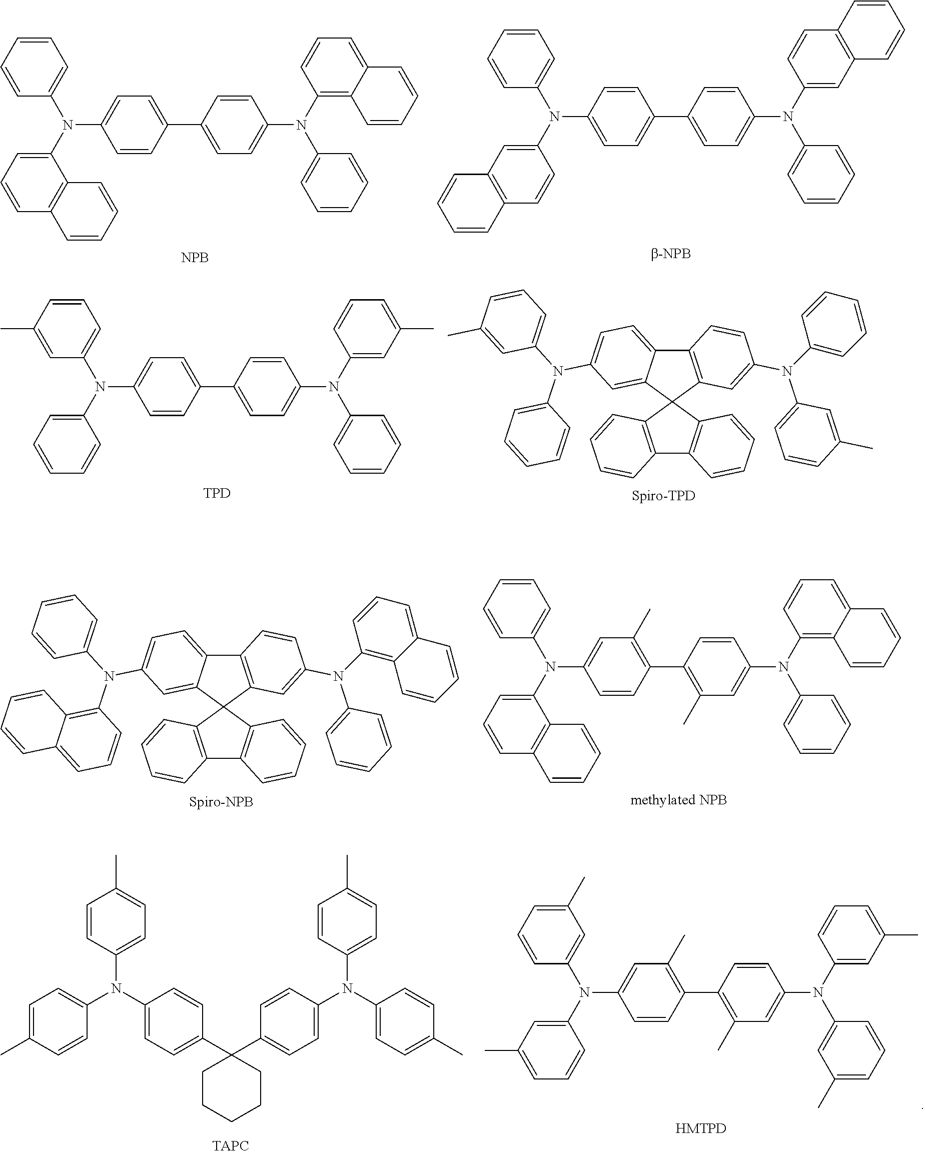

A thickness of the hole transport region may be in a range of about 50 Å to about 10,000 Å. For example, the thickness of the hole transport region may be in a range of about 100 Å to about 4,000 Å. When the hole transport region includes a hole injection layer, a hole transport layer, or any combination thereof, a thickness of the hole injection layer may be in a range of about 100 Å to about 9,000 Å, and a thickness of the hole transport layer may be in a range of about 50 Å to about 2,000 Å. For example, the thickness of the hole injection layer may be in a range of about 100 Å to about 1,000 Å. For example, the thickness of the hole transport layer may be in a range of about 100 Å to about 1,500 Å. When the thicknesses of the hole transport region, the hole injection layer, and the hole transport layer are within these ranges, satisfactory hole transporting characteristics may be obtained without a substantial increase in driving voltage.

The emission auxiliary layer may increase light emission efficiency by compensating for an optical resonance distance according to a wavelength of light emitted by an emission layer, and the electron blocking layer may block the leakage of electrons from an emission layer to a hole transport region. Materials that may be included in the hole transport region may be included in the emission auxiliary layer and the electron blocking layer.

[p-dopant]

The hole transport region may further include, in addition to the materials described above, a charge-generation material for the improvement of conductive properties. The charge-generation material may be uniformly or non-uniformly dispersed in the hole transport region (for example, in the form of a single layer consisting of a charge-generation material).

The charge-generation material may be, for example, a p-dopant.

In an embodiment, the p-dopant may have a lowest unoccupied molecular orbital (LUMO) energy level equal to or less than about −3.5 eV.

According to an embodiment, the p-dopant may include a quinone derivative, a cyano group-containing compound, a compound including element EL1 and element EL2, or any combination thereof.

Examples of a quinone derivative may include TCNQ, F4-TCNQ, and the like.

Examples of a cyano group-containing compound may include HAT-CN, a compound represented by Formula 221, and the like:

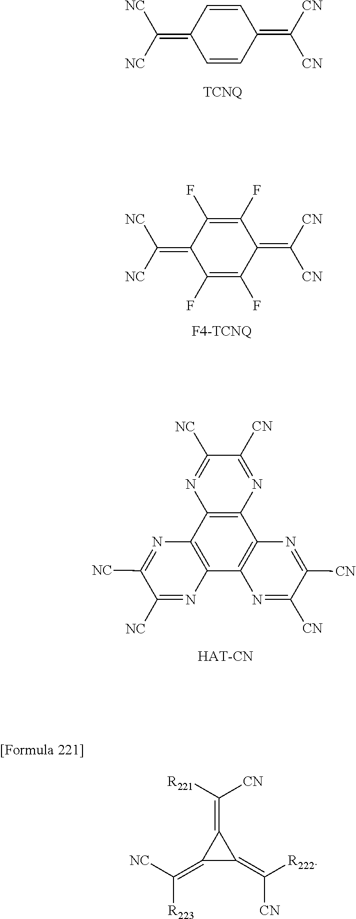

In Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one of R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

In the compound including element EL1 and element EL2, element EL1 may be a metal, a metalloid, or any combination thereof, and element EL2 may be a non-metal, a metalloid, or any combination thereof.

Examples of a metal may include: an alkali metal (for example, lithium (Li), sodium (Na), potassium (K), rubidium (Rb), cesium (Cs), etc.); an alkaline earth metal (for example, beryllium (Be), magnesium (Mg), calcium (Ca), strontium (Sr), barium (Ba), etc.); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); a post-transition metal (for example, zinc (Zn), indium (In), tin (Sn), etc.); a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.); and the like.

Examples of a metalloid may include silicon (Si), antimony (Sb), tellurium (Te), and the like.

Examples of a non-metal may include oxygen (O), a halogen (for example, F, Cl, Br, I, etc.), and the like.

Examples of a compound including element EL1 and element EL2 may include a metal oxide, a metal halide (for example, a metal fluoride, a metal chloride, a metal bromide, a metal iodide, etc.), a metalloid halide (for example, a metalloid fluoride, a metalloid chloride, a metalloid bromide, a metalloid iodide, etc.), a metal telluride, or any combination thereof.

Examples of a metal oxide may include a tungsten oxide (for example, WO, W₂O₃, WO₂, WO₃, W₂O₅, etc.), a vanadium oxide (for example, VO, V₂O₃, VO₂, V₂O₅, etc.), a molybdenum oxide (MoO, Mo₂O₃, MoO₂, MoO₃, Mo₂O₅, etc.), a rhenium oxide (for example, ReO₃, etc.), and the like.

Examples of a metal halide may include an alkali metal halide, an alkaline earth metal halide, a transition metal halide, a post-transition metal halide, a lanthanide metal halide, and the like.

Examples of an alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, CsI, and the like.

Examples of an alkaline earth metal halide may include BeF₂, MgF₂, CaF₂, SrF₂, BaF₂, BeCl₂, MgCl₂, CaCl₂, SrCl₂, BaCl₂, BeBr₂, MgBr₂, CaBr₂, SrBr₂, BaBr₂, BeI₂, MgI₂, CaI₂, SrI₂, BaI₂, and the like.

Examples of a transition metal halide may include a titanium halide (for example, TiF₄, TiCl₄, TiBr₄, TiI₄, etc.), a zirconium halide (for example, ZrF₄, ZrCl₄, ZrBr₄, ZrI₄, etc.), a hafnium halide (for example, HfF₄, HfCl₄, HfBr₄, HfI₄, etc.), a vanadium halide (for example, VF₃, VCl₃, VBr₃, VI₃, etc.), a niobium halide (for example, NbF₃, NbCl₃, NbBr₃, NbI₃, etc.), a tantalum halide (for example, TaF₃, TaCl₃, TaBr₃, TaI₃, etc.), a chromium halide (for example, CrF₃, CrCl₃, CrBr₃, CrI₃, etc.), a molybdenum halide (for example, MoF₃, MoCl₃, MoBr₃, MoI₃, etc.), a tungsten halide (for example, WF₃, WCl₃, WBr₃, WI₃, etc.), a manganese halide (for example, MnF₂, MnCl₂, MnBr₂, MnI₂, etc.), a technetium halide (for example, TcF₂, TcCl₂, TcBr₂, TcI₂, etc.), a rhenium halide (for example, ReF₂, ReCl₂, ReBr₂, ReI₂, etc.), an iron halide (for example, FeF₂, FeCl₂, FeBr₂, FeI₂, etc.), a ruthenium halide (for example, RuF₂, RuCl₂, RuBr₂, RuI₂, etc.), an osmium halide (for example, OsF₂, OsCl₂, OsBr₂, OsI₂, etc.), a cobalt halide (for example, CoF₂, CoCl₂, CoBr₂, CoI₂, etc.), a rhodium halide (for example, RhF₂, RhCl₂, RhBr₂, RhI₂, etc.), an iridium halide (for example, IrF₂, IrCl₂, IrBr₂, IrI₂, etc.), a nickel halide (for example, NiF₂, NiCl₂, NiBr₂, NiI₂, etc.), a palladium halide (for example, PdF₂, PdCl₂, PdBr₂, PdI₂, etc.), a platinum halide (for example, PtF₂, PtCl₂, PtBr₂, PtI₂, etc.), a copper halide (for example, CuF, CuCl, CuBr, CuI, etc.), a silver halide (for example, AgF, AgCl, AgBr, AgI, etc.), a gold halide (for example, AuF, AuCl, AuBr, AuI, etc.), and the like.

Examples of a post-transition metal halide may include a zinc halide (for example, ZnF₂, ZnCl₂, ZnBr₂, ZnI₂, etc.), an indium halide (for example, InI₃, etc.), a tin halide (for example, SnI₂, etc.), and the like.

Examples of a lanthanide metal halide may include YbF, YbF₂, YbF₃, SmF₃, YbCl, YbCl₂, YbCl₃ SmCl₃, YbBr, YbBr₂, YbBr₃ SmBr₃, YbI, YbI₂, YbI₃, SmI₃, and the like.

Examples of a metalloid halide may include an antimony halide (for example, SbCl₅, etc.) and the like.

Examples of a metal telluride may include an alkali metal telluride (for example, Li₂Te, Na₂Te, K₂Te, Rb₂Te, Cs₂Te, etc.), an alkaline earth metal telluride (for example, BeTe, MgTe, CaTe, SrTe, BaTe, etc.), a transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, etc.), a post-transition metal telluride (for example, ZnTe, etc.), a lanthanide metal telluride (for example, LaTe, CeTe, PrTe, NdTe, PmTe, EuTe, GdTe, TbTe, DyTe, HoTe, ErTe, TmTe, YbTe, LuTe, etc.), and the like.

### [Emission Layer in Interlayer 130]

When the light-emitting device 1A is a full-color light-emitting device, the emission layer may be patterned into a red emission layer, a green emission layer, and/or a blue emission layer, according to a subpixel. In an embodiment, the emission layer may have a stacked structure of two or more layers of a red emission layer, a green emission layer, and a blue emission layer, in which the two or more layers may contact each other or may be separated from each other to emit white light. In embodiments, the emission layer may include two or more materials of a red light-emitting material, a green light-emitting material, and a blue light-emitting material, in which the two or more materials may be mixed with each other in a single layer to emit white light.

According to embodiments, the emission layer may include a quantum dot, which may be a quantum dot as described herein.

The emission layer may be formed by applying an ink composition on a hole transport region and volatilizing at least a portion of the solvent included in the ink composition.

The ink composition may be applied by using an ink jet printing method, a spin coat method, a casting method, a micro gravure coat method, a gravure coat method, a bar coat method, a roll coat method, a wire bar coat method, a dip coat method, a spray coat method, a screen printing method, a flexographic method, an offset printing method, etc.

In an embodiment, the emission layer may further include a host and a dopant, in addition to the quantum dots. The dopant may include a phosphorescent dopant, a fluorescent dopant, or any combination thereof.

An amount of the dopant in the emission layer may be in a range of about 0.01 parts by weight to about 15 parts by weight, based on 100 parts by weight of the host.

In an embodiment, the emission layer may include a delayed fluorescence material. The delayed fluorescence material may serve as a host or as a dopant in the emission layer.

A thickness of the emission layer may be in a range of about 100 Å to about 1,000 Å. For example, the thickness of the emission layer may be in a range of about 200 Å to about 600 Å. When the thickness of the emission layer is within any of these ranges, excellent luminescence characteristics may be obtained without a substantial increase in driving voltage.

### [Host]

In an embodiment, the host may include a compound represented by Formula 301:

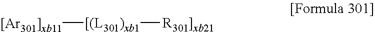

In Formula 301,
Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to Q₃₀₃ may each independently be the same as described herein with respect to Q₁.

In an embodiment, in Formula 301, when xb11 is 2 or more, two or more of Ar₃₀₁(s) may be linked to each other via a single bond.

In an embodiment, the host may include a compound represented by Formula 301-1, a compound represented by Formula 301-2, or any combination thereof:

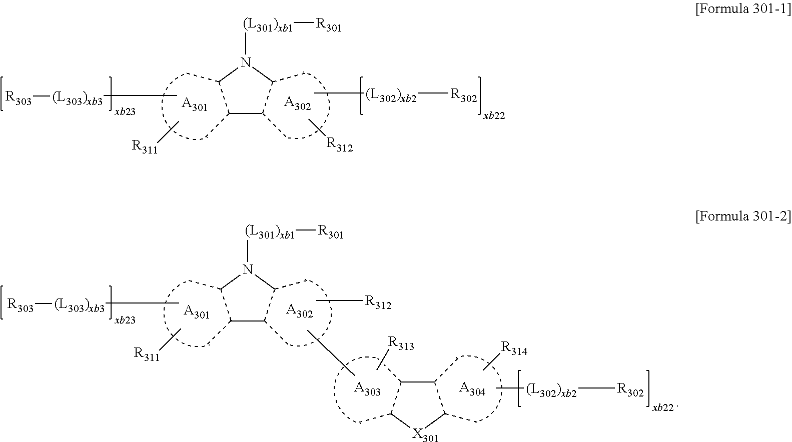

In Formula 301-1 and 301-2,
ring A₃₀₁ to ring A₃₀₄ may each independently be a C₅-C₆₀ carbocyclic group unsubstituted or substituted with at least one R₁₀ₐ or a C₁-C₆₀ heterocyclic group unsubstituted or substituted with at least one R₁₀ₐ,
X₃₀₁ may be O, S, N-[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ may each be the same as described herein,
L₃₀₂ to L₃₀₄ may each independently be the same as described herein with respect to with L₃₀₁,
xb2 to xb4 may each independently be the same as described herein with respect to xb1, and
R₃₀₂ to R₃₀₅ and R₃₁₁ to R₃₁₄ may each independently be the same as described herein with respect to R₃₀₁.

In an embodiment, the host may include an alkali earth metal complex, a post-transition metal complex, or any combination thereof. For example, the host may include a Be complex (for example, Compound H55), an Mg complex, a Zn complex, or any combination thereof.

In an embodiment, the host may include one of Compounds H1 to H128, 9,10-di(2-naphthyl)anthracene (ADN), 2-methyl-9,10-bis(naphthalen-2-yl)anthracene (MADN), 9,10-di-(2-naphthyl)-2-t-butyl-anthracene (TBADN), 4,4′-bis(N-carbazolyl)-1,1′-biphenyl (CBP), 1,3-di-9-carbazolylbenzene (mCP), 1,3,5-tri (carbazol-9-yl)benzene (TCP), or any combination thereof:

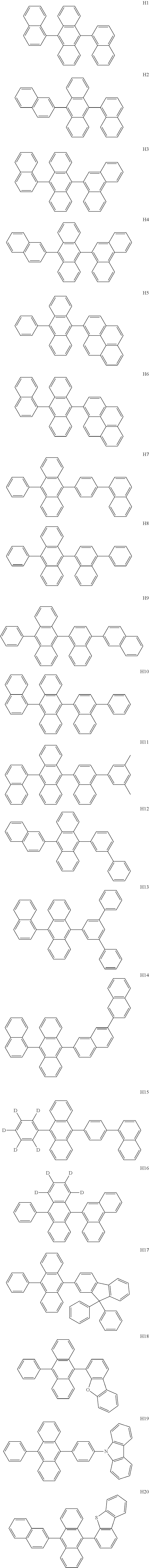

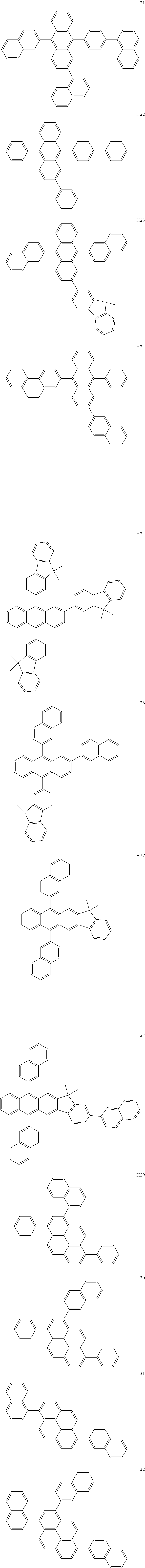

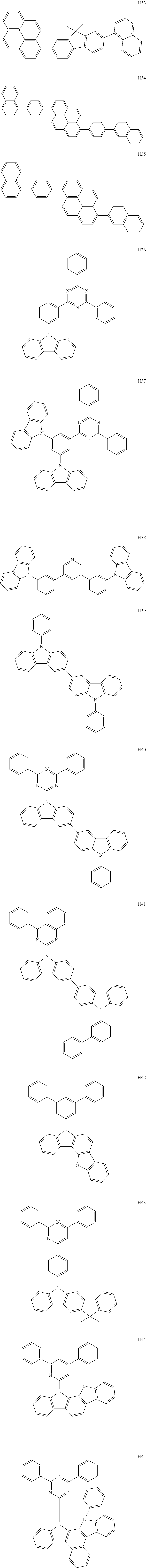

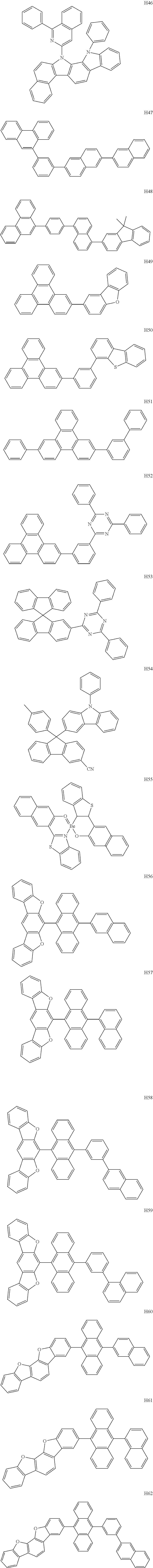

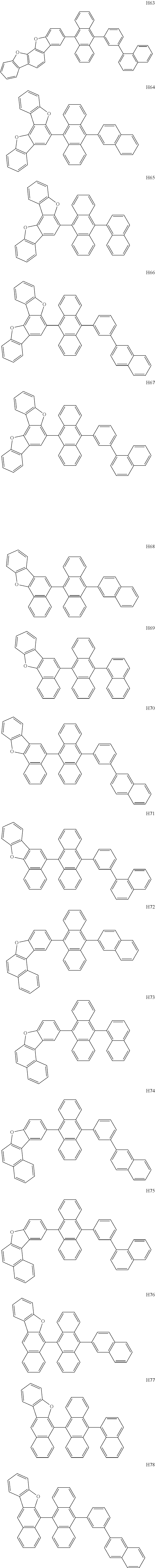

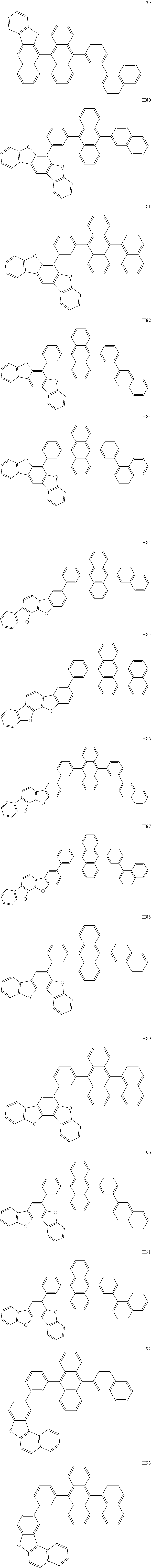

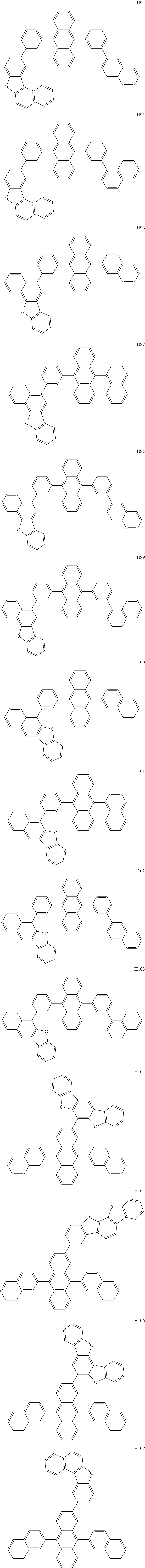

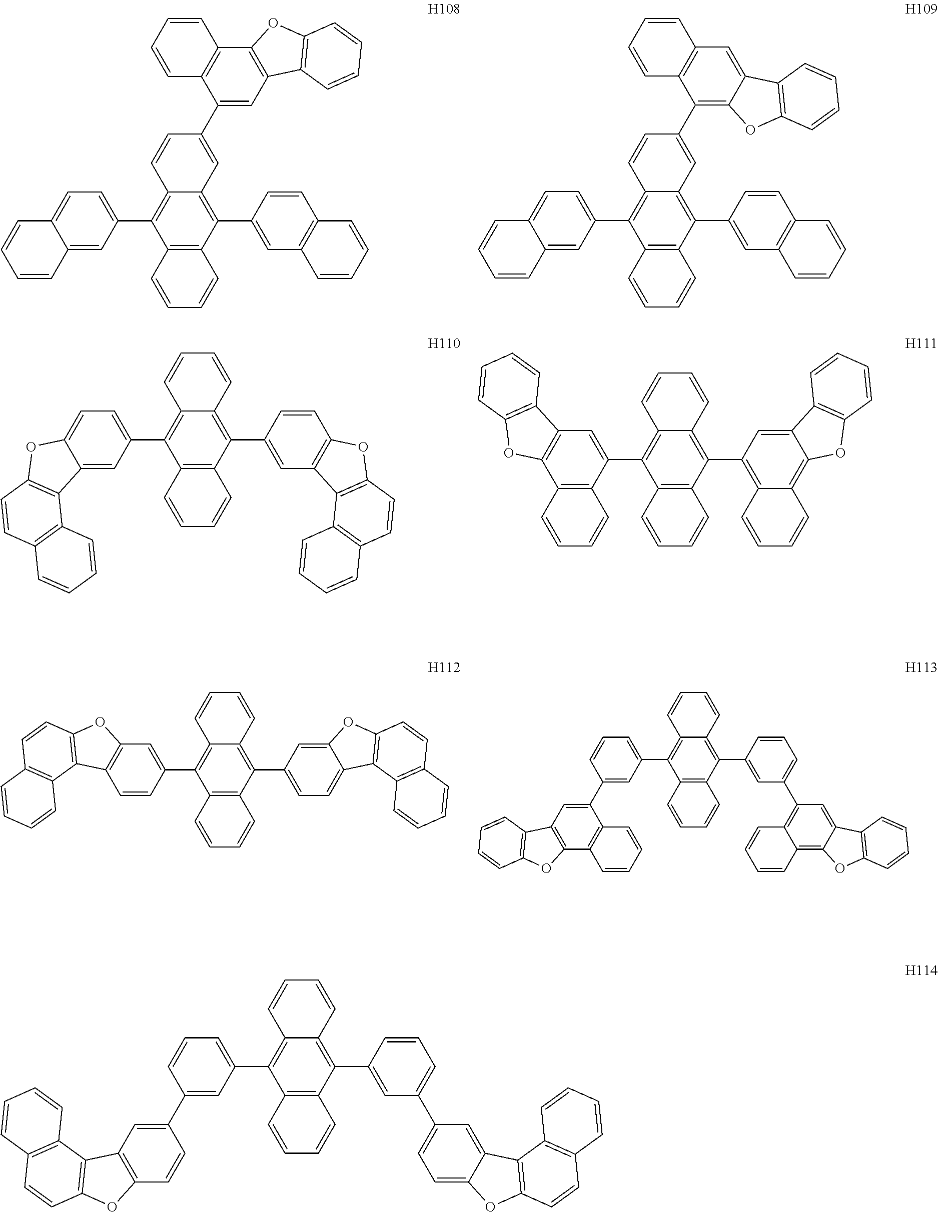

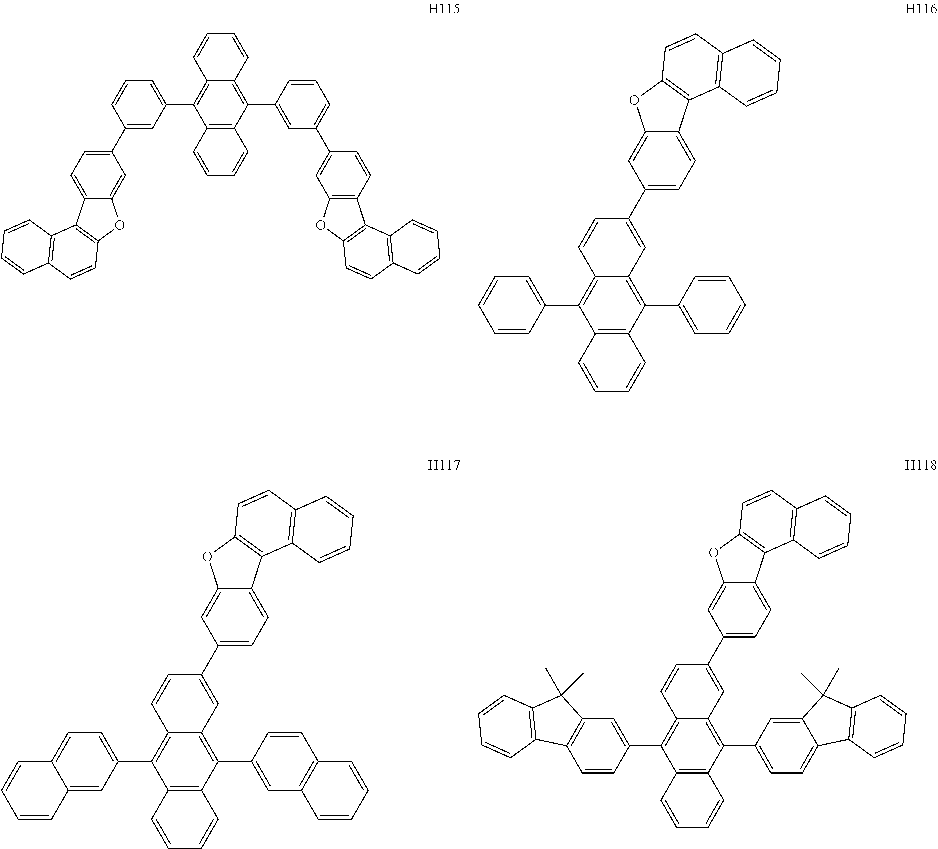 [SMILES: c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1 ; c1ccc2cc(-c3c4ccccc4c(-c4ccc5ccccc5c4)c4cc(-c5ccc6c(c5)oc5ccc7ccccc7c56)ccc34)ccc2c1 ; CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21]

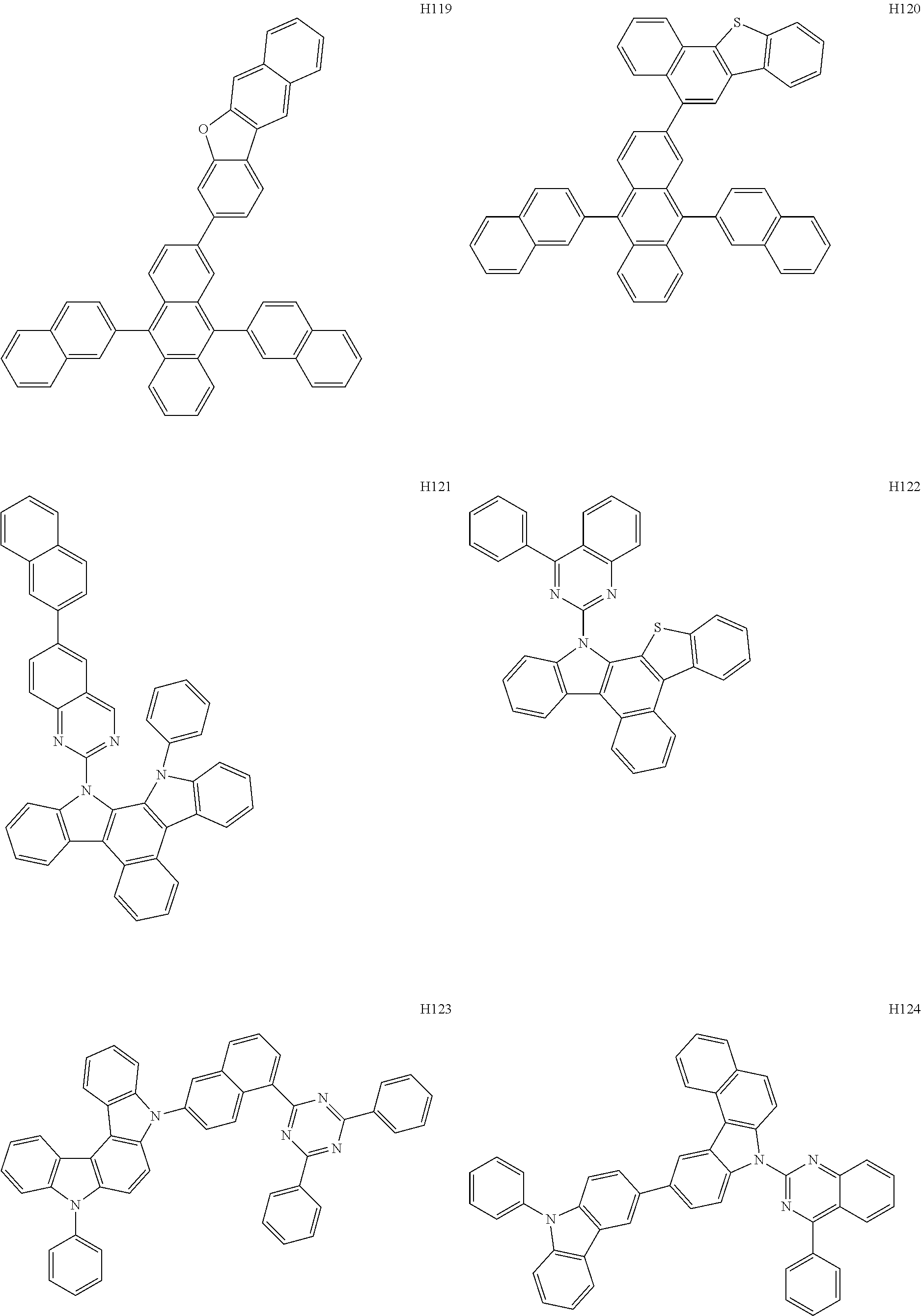

### [Phosphorescent Dopant]

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In an embodiment, the phosphorescent dopant may include an organometallic compound represented by Formula 401:

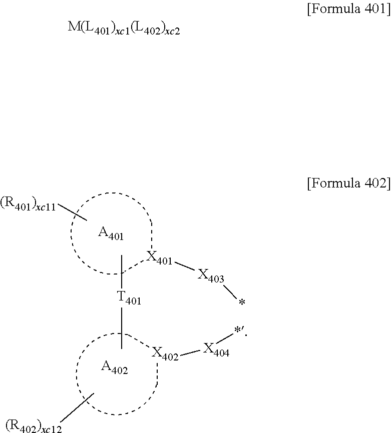

In Formulae 401 and 402,
M may be a transition metal (for example, iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 may be 1, 2, or 3, wherein when xc1 is two or more, two or more of L₄₀₁(s) may be identical to or different from each other,
L₄₀₂ may be an organic ligand, and xc2 may be 0, 1, 2, 3, or 4, wherein when xc2 is 2 or more, two or more of L₄₀₂(s) may be identical to or different from each other,
X₄₀₁ and X₄₀₂ may each independently be nitrogen or carbon,
ring A₄₀₁ and ring A₄₀₂ may each independently be a C₃-C₆₀ carbocyclic group or a C₁-C₆₀ heterocyclic group,
T₄₀₁ may be a single bond, *—O—*′, *—S—*′, *—C(═O)—*′, *—N(Q₄₁₁)-*′, *—C(Q₄₁₁)(Q₄₁₂)-*′, *—C(Q₄₁₁)=C(Q₄₁₂)-*′, *—C(Q₄₁₁)=*′, or *=C=*′,
X₄₀₃ and X₄₀₄ may each independently be a chemical bond (for example, a covalent bond or a coordination bond), O, S, N(Q₄₁₃), B(Q₄₁₃), P(Q₄₁₃), C(Q₄₁₃)(Q₄₁₄), or Si(Q₄₁₃)(Q₄₁₄),
Q₄₁₁ to Q₄₁₄ may each independently be the same as described herein with respect to Q₁,
R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ may each independently be the same as described herein with respect to Q₁,
xc11 and xc12 may each independently be an integer from 0 to 10, and
and *′ in Formula 402 may each indicate a binding site to M in Formula 401.

For example, in Formula 402, X₄₀₁ may be nitrogen and X₄₀₂ may be carbon, or X₄₀₁ and X₄₀₂ may each be nitrogen.

In an embodiment, in Formula 401, when xc1 is 2 or more, two ring A₄₀₁(s) among two or more L₄₀₁(s) may optionally be linked to each other via T₄₀₂, which is a linking group, and two ring A₄₀₂(s) among two or more L₄₀₁(s) may optionally be linked to each other via T₄₀₃, which is a linking group (see Compounds PD1 to PD4 and PD7). T₄₀₂ and T₄₀₃ may each independently be the same as described herein with respect to T₄₀₁.

In Formula 401, L₄₀₂ may be an organic ligand. For example, L₄₀₂ may include a halogen group, a diketone group (for example, an acetylacetonate group), a carboxylic acid group (for example, a picolinate group), —C(═O), an isonitrile group, —CN group, a phosphorus group (for example, a phosphine group, a phosphite group, etc.), or any combination thereof.

In an embodiment, the phosphorescent dopant may include, for example, one of Compounds PD1 to PD39, or any combination thereof:

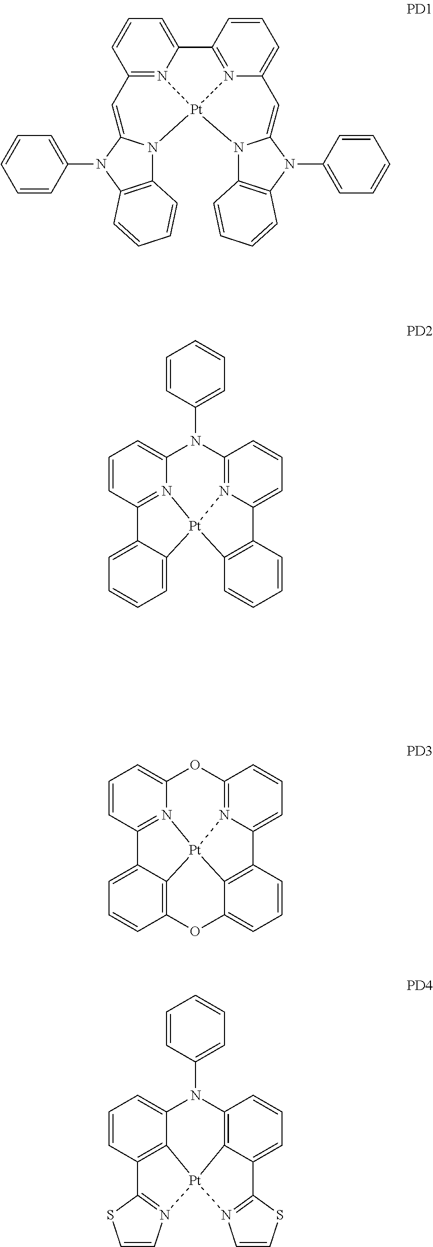

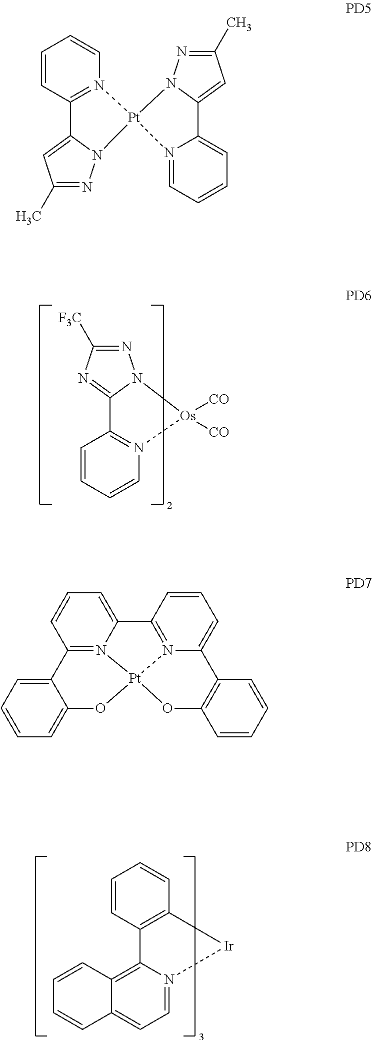

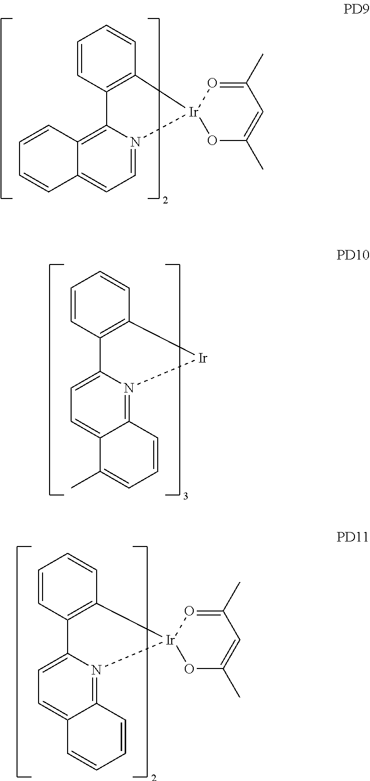

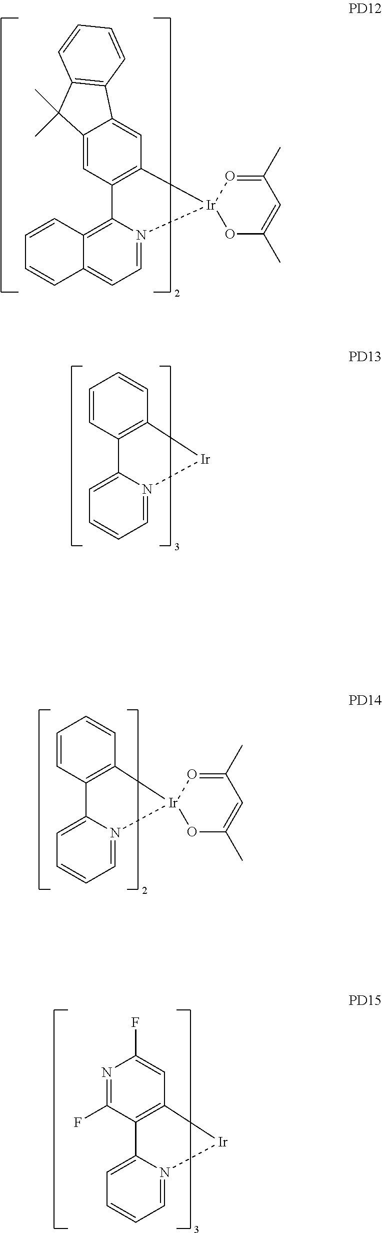

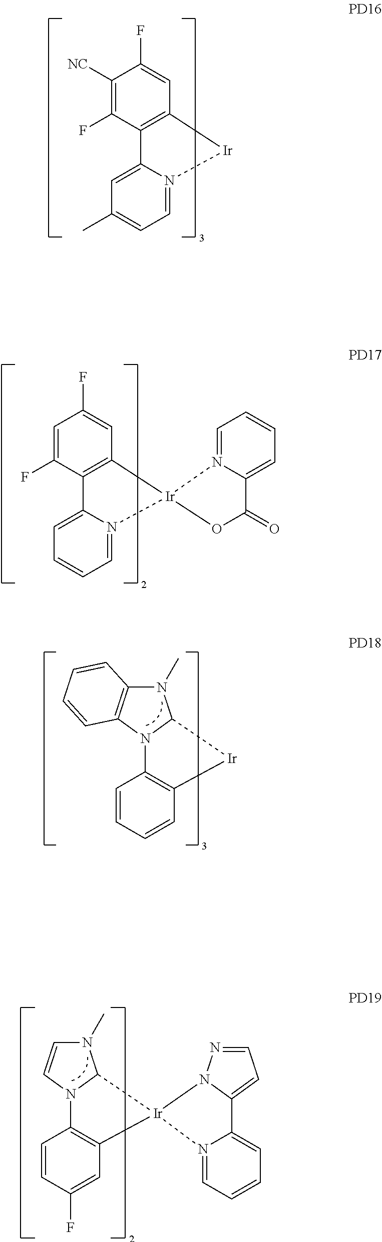

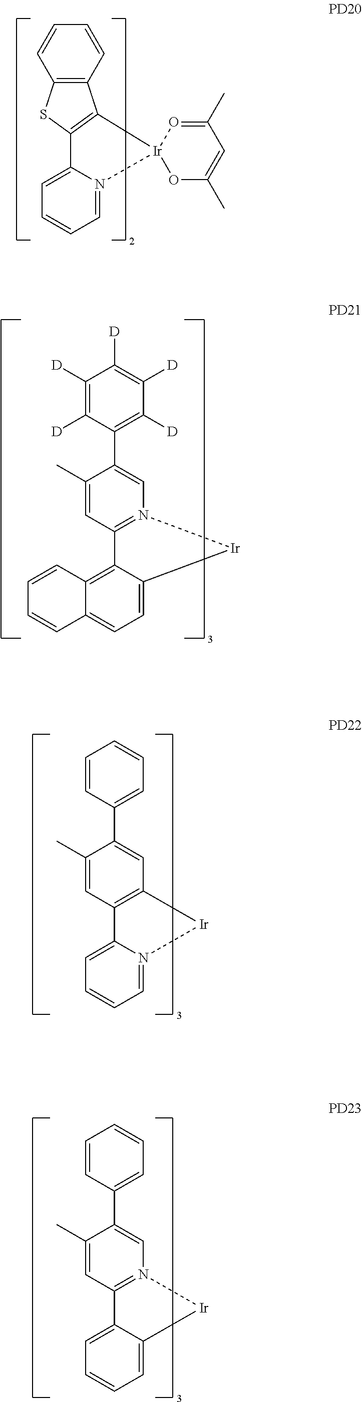

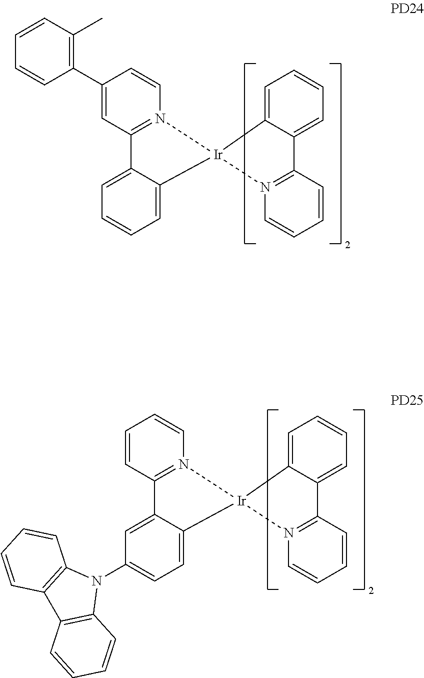

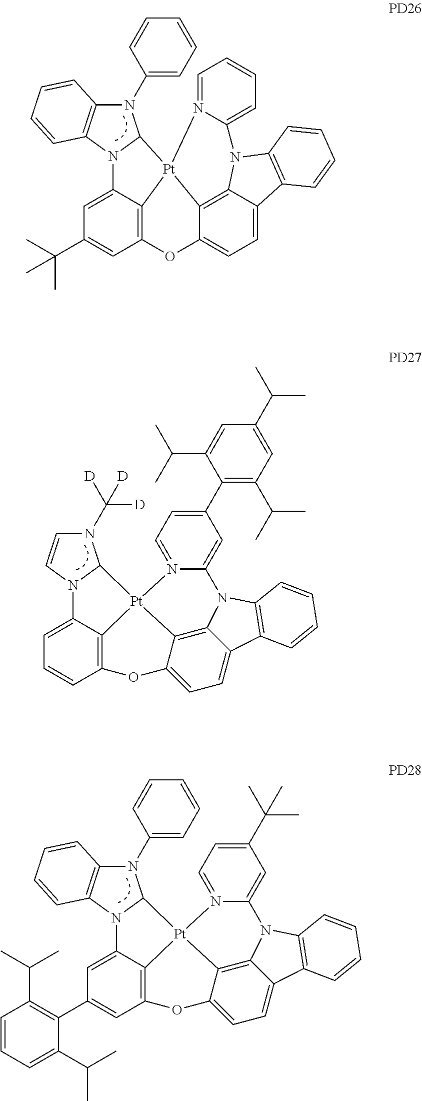

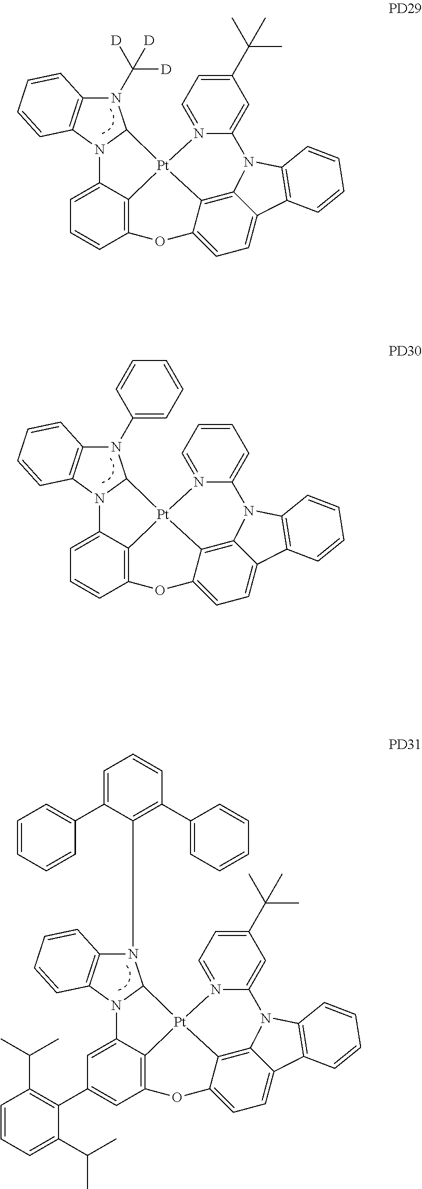

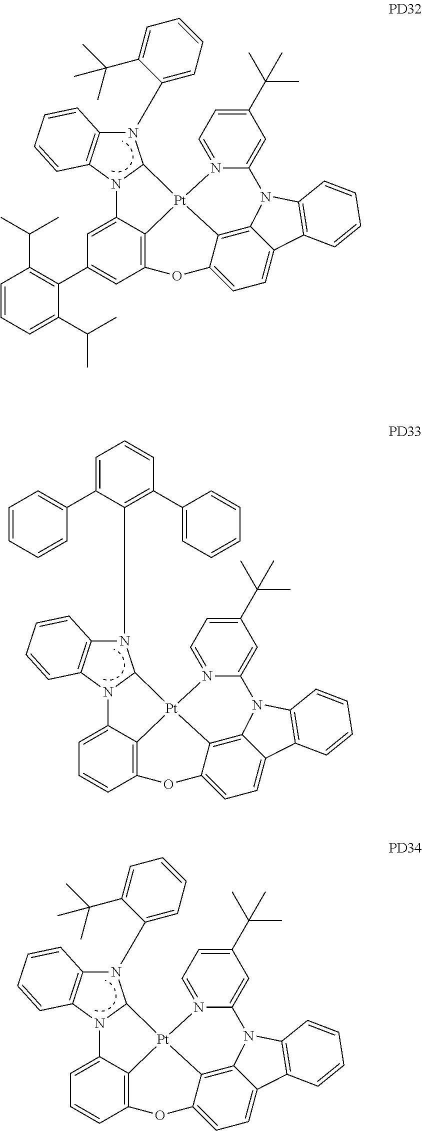

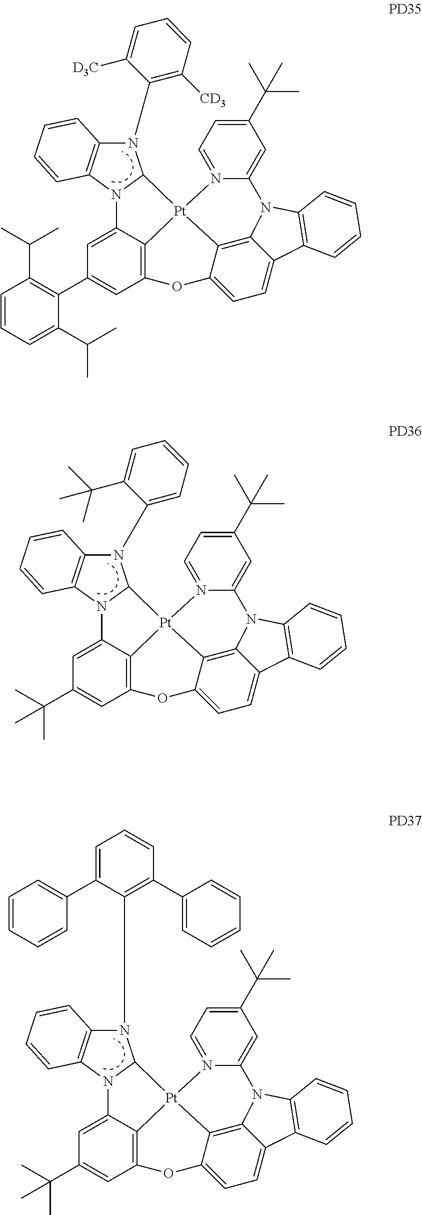

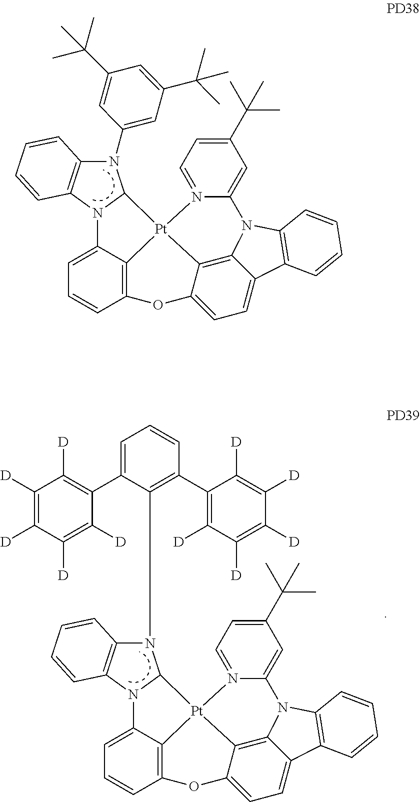

### [Fluorescent Dopant]

The fluorescent dopant may include an amine group-containing compound, a styryl group-containing compound, or any combination thereof.

In an embodiment, the fluorescent dopant may include a compound represented by Formula 501:

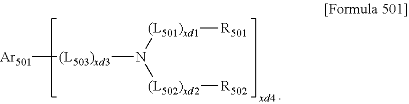

In Formula 501,
Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xd1 to xd3 may each independently be 0, 1, 2, or 3, and
xd4 may be 1, 2, 3, 4, 5, or 6.

For example, in Formula 501, Ar₅₀₁ may be a condensed cyclic group (for example, an anthracene group, a chrysene group, a pyrene group, etc.) in which three or more monocyclic groups are condensed together.

In an embodiment, in Formula 501, xd4 may be 2.

In an embodiment, the fluorescent dopant may include one of Compounds FD1 to FD37, DPVBi, DPAVBi, or any combination thereof:

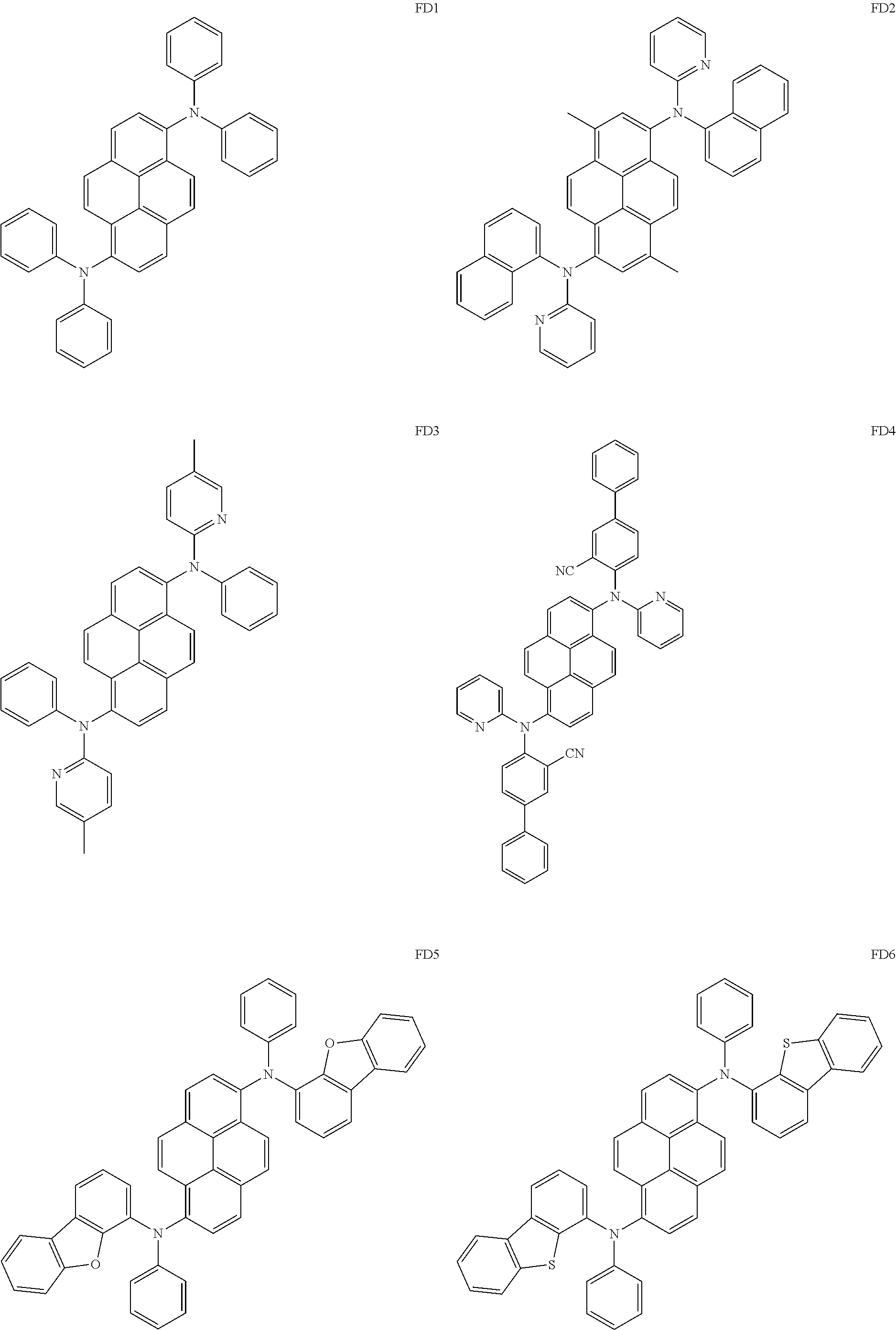

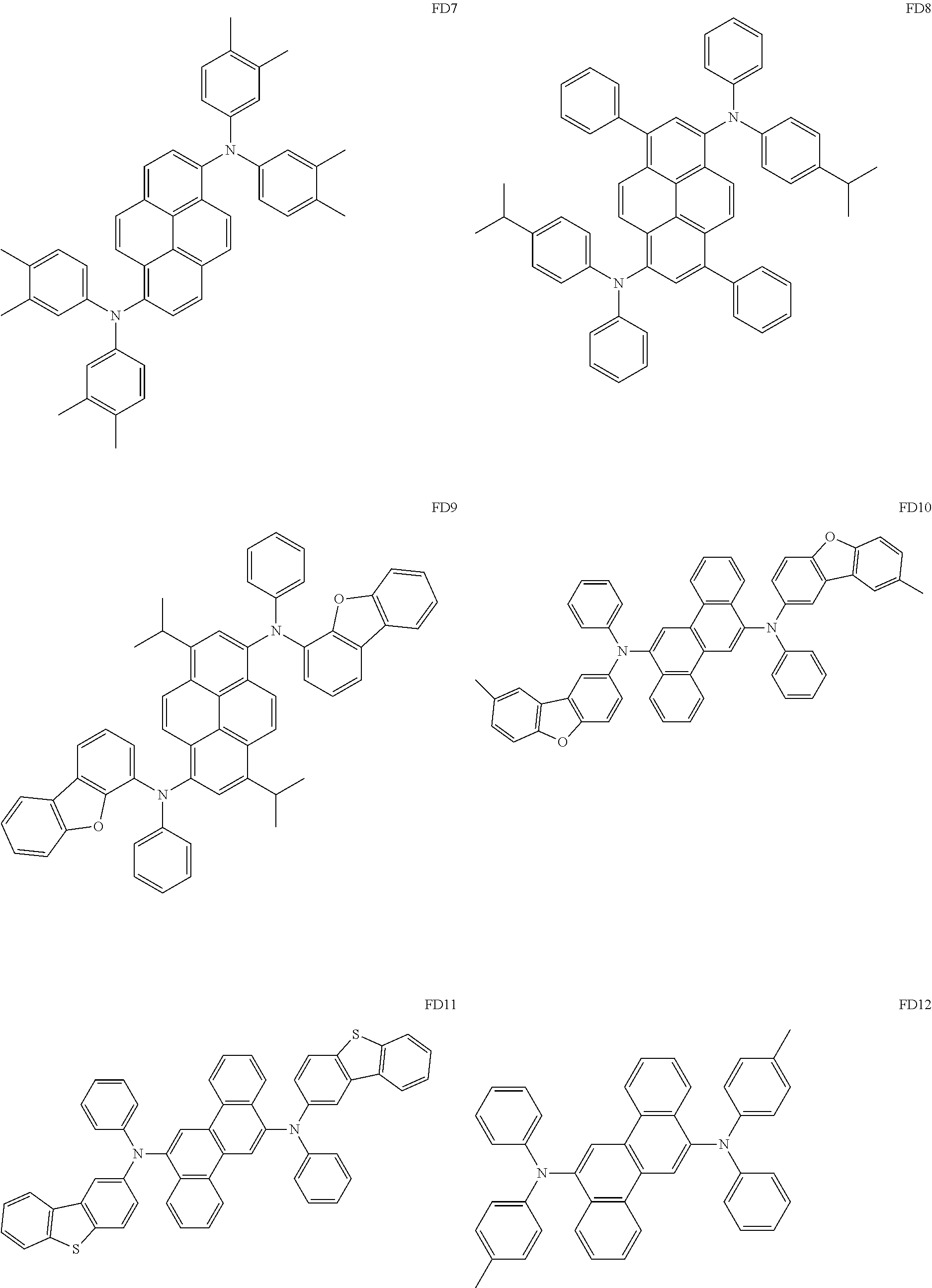

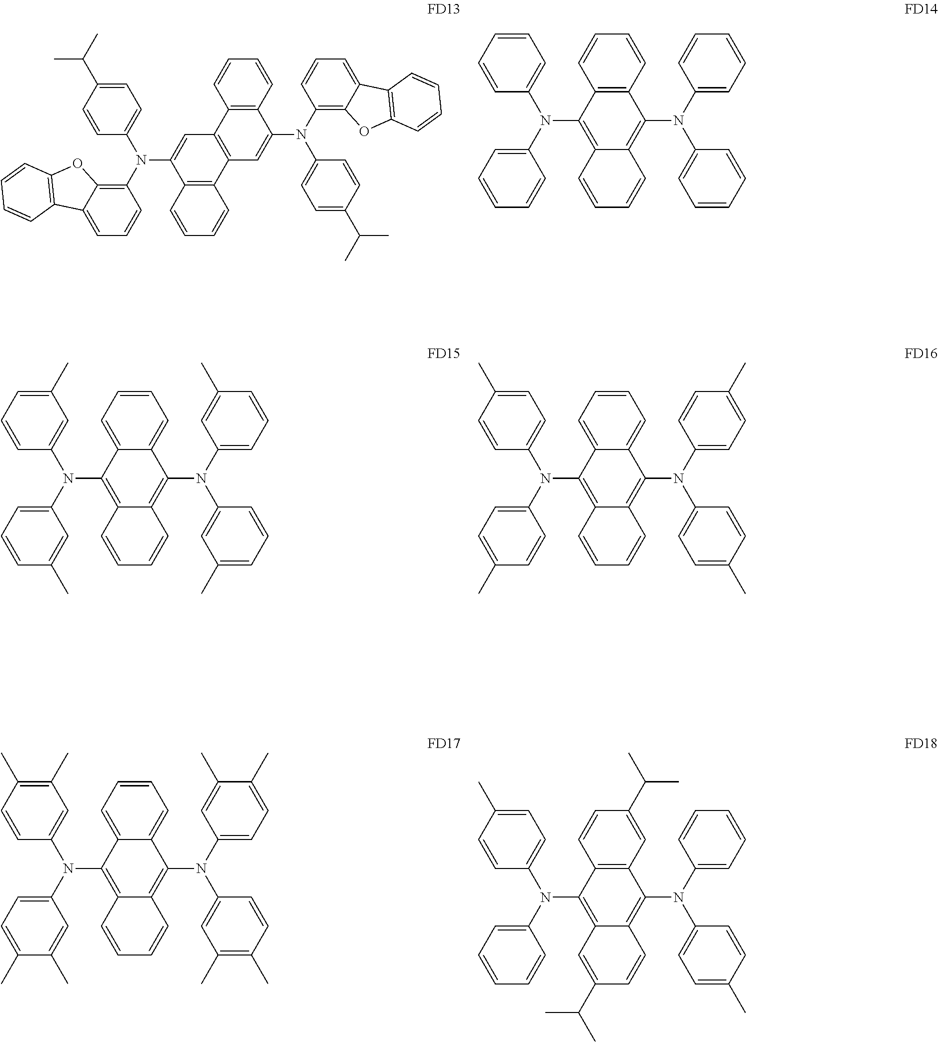

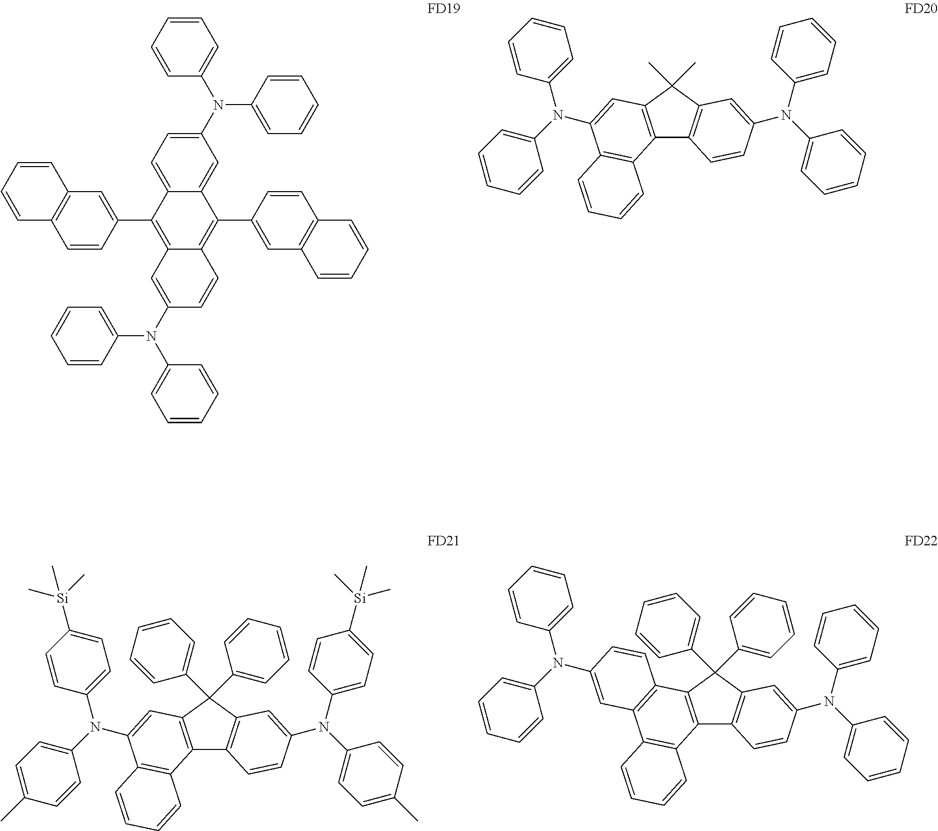

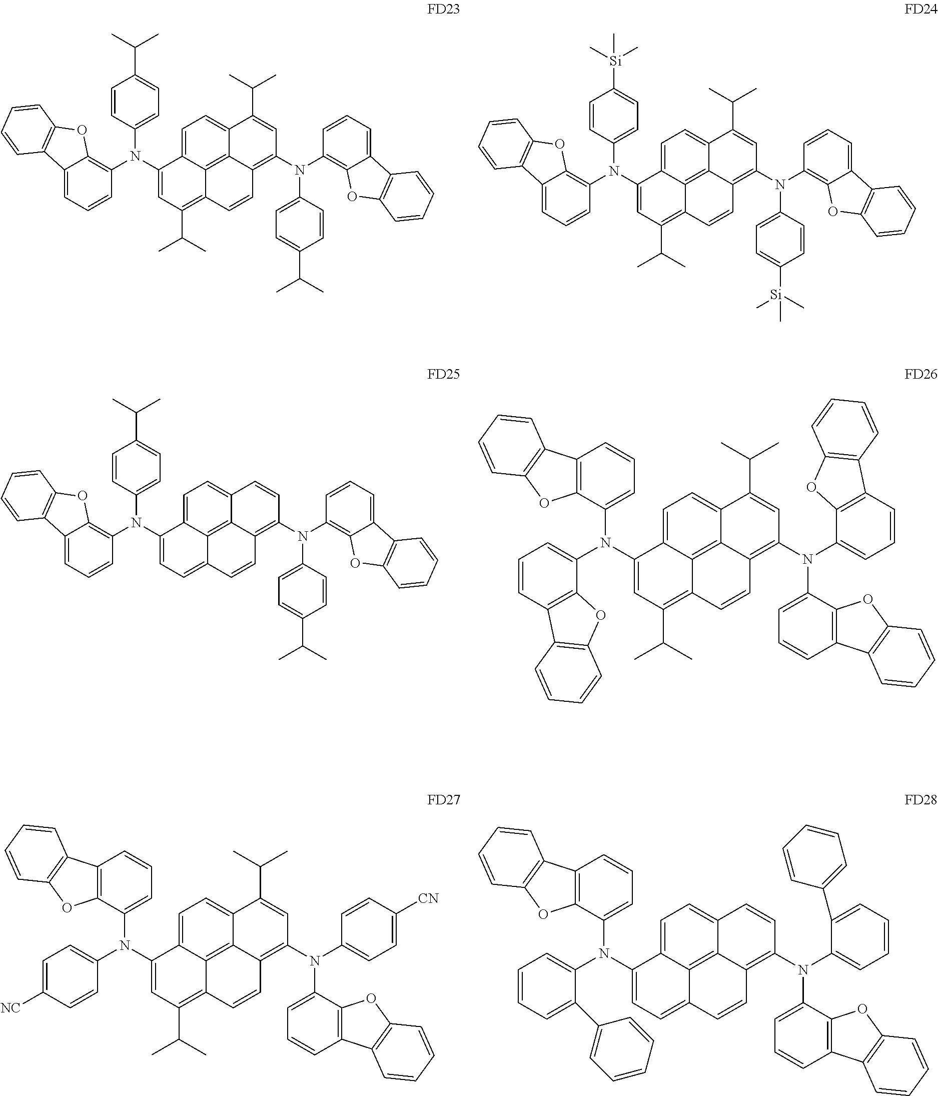

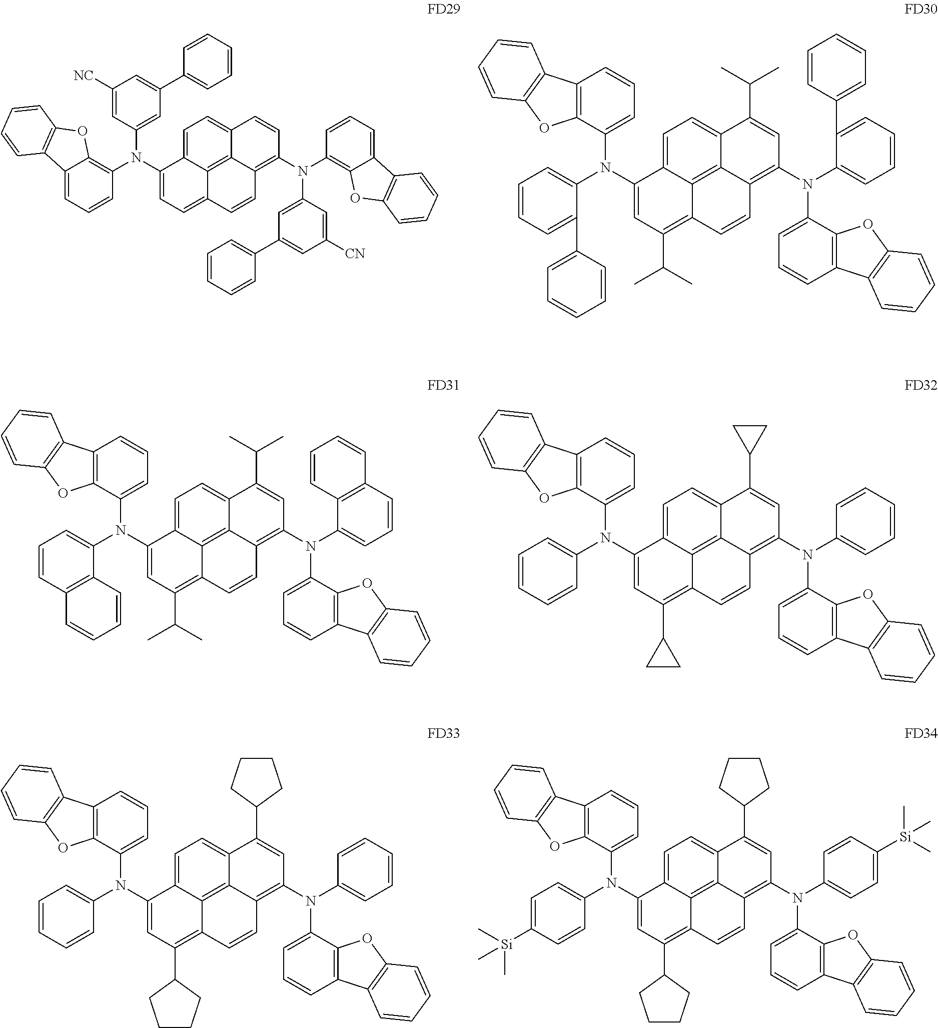

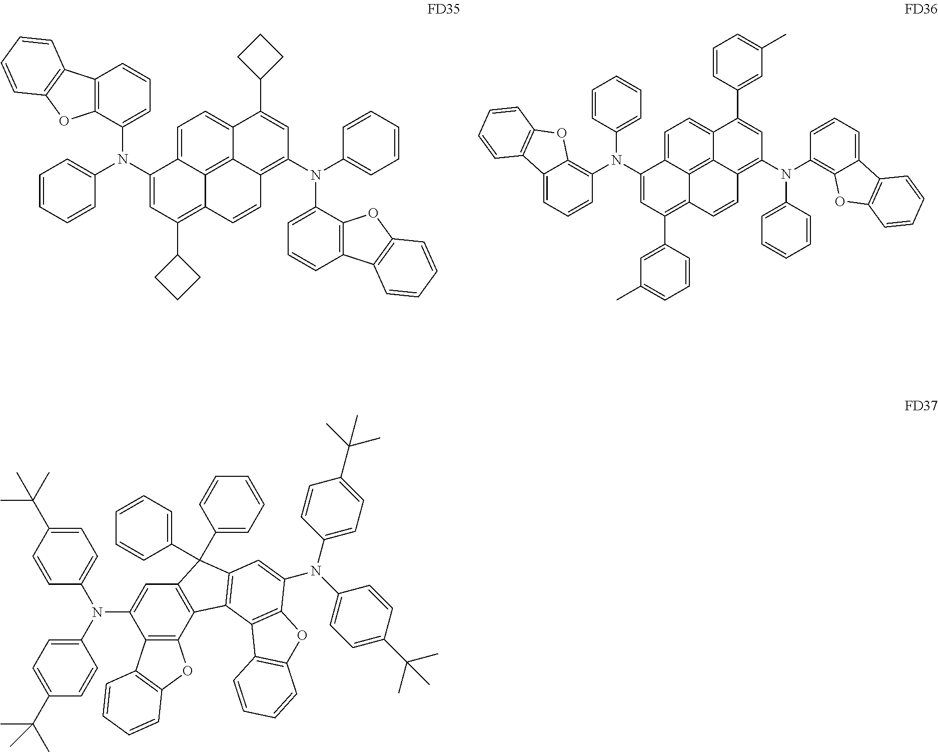 [SMILES: c1ccc(N(c2cc(C3CCC3)c3ccc4c(N(c5ccccc5)c5cccc6c5oc5ccccc56)cc(C5CCC5)c5ccc2c3c54)c2cccc3c2oc2ccccc23)cc1 ; Cc1cccc(-c2cc(N(c3ccccc3)c3cccc4c3oc3ccccc34)c3ccc4c(-c5cccc(C)c5)cc(N(c5ccccc5)c5cccc6c5oc5ccccc56)c5ccc2c3c45)c1 ; CC(C)(C)c1ccc(N(c2ccc(C(C)(C)C)cc2)c2cc3c(c4c2oc2ccccc24)-c2c(cc(N(c4ccc(C(C)(C)C)cc4)c4ccc(C(C)(C)C)cc4)c4c2oc2ccccc24)C3(c2ccccc2)c2ccccc2)cc1]

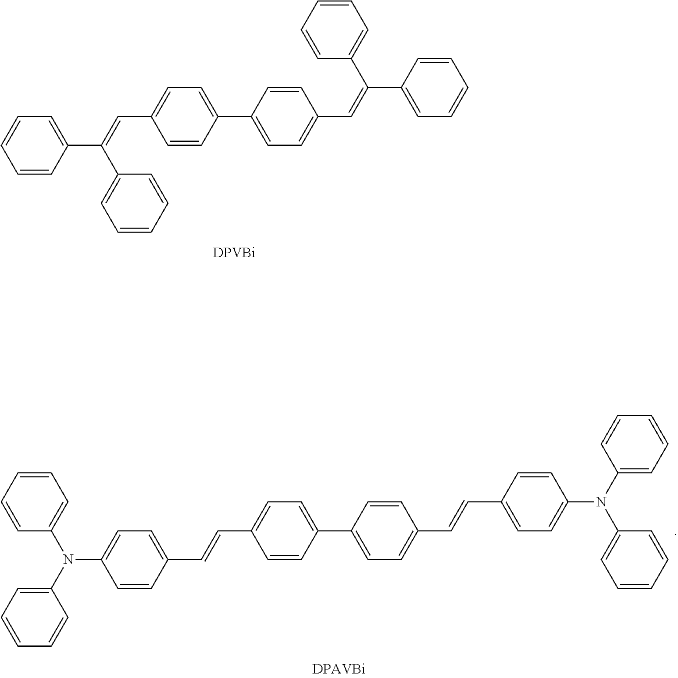

### [Delayed Fluorescence Material]

The emission layer may include a delayed fluorescence material.

In the specification, a delayed fluorescence material may be any compound that is capable of emitting delayed fluorescence, based on a delayed fluorescence emission mechanism.

The delayed fluorescence material included in the emission layer may serve as a host or as a dopant, depending on the types of other materials included in the emission layer.

According to an embodiment, a difference between a triplet energy level (eV) of the delayed fluorescence material and a singlet energy level (eV) of the delayed fluorescence material may be at least 0 eV but not more than about 0.5 eV. When the difference between the triplet energy level (eV) of the delayed fluorescence material and the singlet energy level (eV) of the delayed fluorescence material satisfies the range described above, up-conversion from a triplet state to a singlet state of the delayed fluorescence materials may effectively occur, and thus, the light-emitting device 1A may have improved luminescence efficiency.

In an embodiment, the delayed fluorescence material may include: a material including at least one electron donor (for example, a TT electron-rich C₃-C₆₀ cyclic group, such as a carbazole group, etc.) and at least one electron acceptor (for example, a sulfoxide group, a cyano group, or a π electron-deficient nitrogen-containing C₁-C₆₀ cyclic group, etc.); a material including a C₈-C₆₀ polycyclic group in which two or more cyclic groups are condensed while sharing boron (B); or the like.

In an embodiment, the delayed fluorescence material may include at least one of Compounds DF1 to DF14:

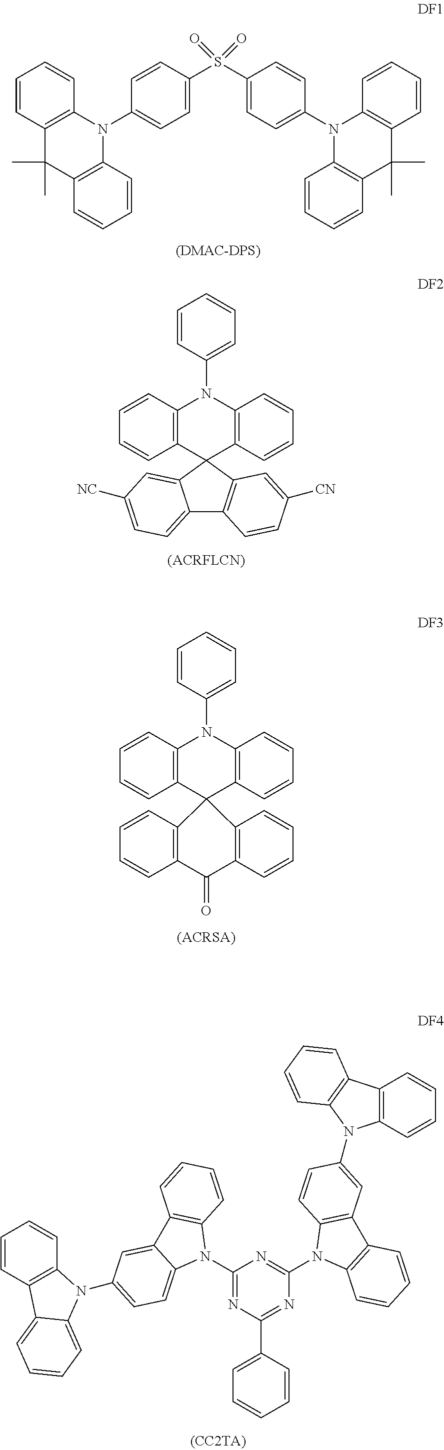

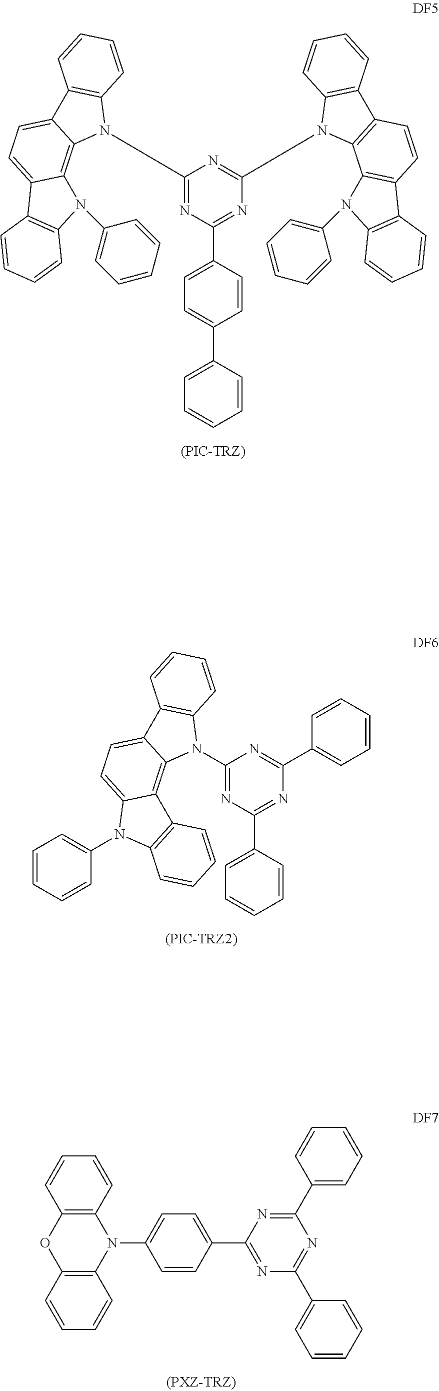 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-c3ccc(N4c5ccccc5Oc5ccccc54)cc3)n2)cc1]

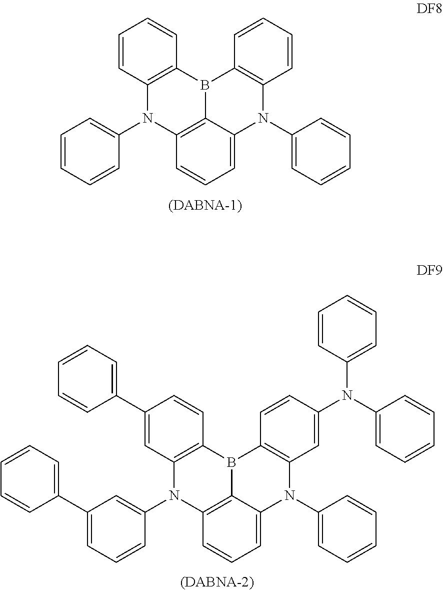

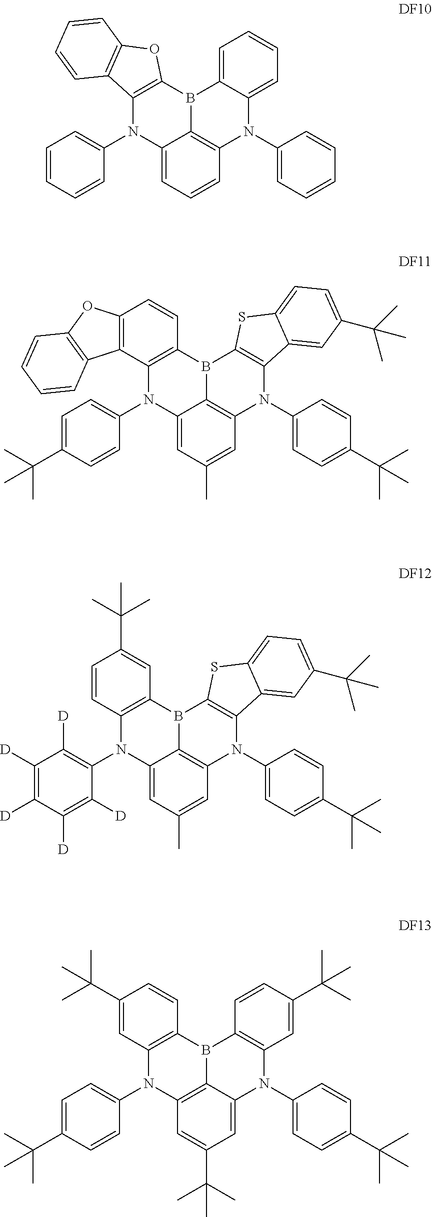

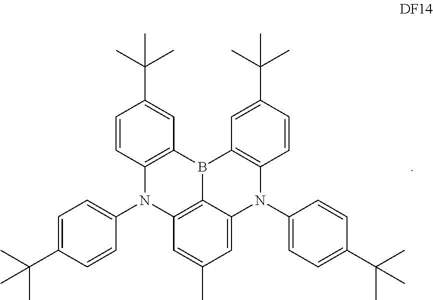 [SMILES: Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1]

### [Electron Transport Region in Interlayer 130]

The electron transport region may have a structure consisting of a layer consisting of a single material, a structure consisting of a layer including different materials, or a structure including multiple layers including different materials.

The electron transport region may include a buffer layer, a hole blocking layer, an electron control layer, an electron transport layer, an electron injection layer, or any combination thereof.

In embodiments, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein the layers of each structure may be stacked from an emission layer in its respective stated order, but the structure of the electron transport region is not limited thereto.

The electron transport region (for example, a buffer layer, a hole blocking layer, an electron control layer, or an electron transport layer in the electron transport region) may include a metal-free compound including at least one TT electron-deficient nitrogen-containing C₁-C₆₀ cyclic group.

In an embodiment, the electron transport region may include a compound represented by Formula 601:

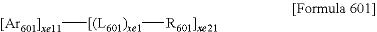

In Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₅-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each independently be the same as described herein with respect to Q₁,
xe21 may be 1, 2, 3, 4, or 5, and
at least one of Ar₆₀₁, L₆₀₁, and R₆₀₁ may each independently be a π electron-deficient nitrogen-containing C₁-C₆₀ cyclic group unsubstituted or substituted with at least one R₁₀ₐ.

In an embodiment, in Formula 601, when xe11 is 2 or more, two or more of Ar₆₀₁(s) may be linked to each other via a single bond.

In an embodiment, in Formula 601, Ar₆₀₁ may be an anthracene group unsubstituted or substituted with at least one R₁₀ₐ.

In an embodiment, the electron transport region may include a compound represented by Formula 601-1:

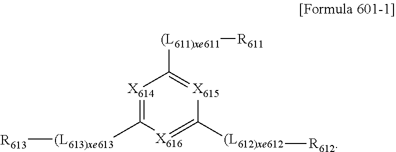

In Formula 601-1,
X₆₁₄ may be N or C(R₆₁₄), X₆₁₅ may be N or C(R₆₁₅), X₆₁₆ may be N or C(R₆₁₆), and at least one of X₆₁₄ to X₆₁₆ may be N,
L₆₁₁ to L₆₁₃ may each independently be the same as described herein with respect to L₆₀₁,
xe611 to xe613 may each independently be the same as described herein with respect to xe1,
R₆₁₁ to R₆₁₃ may each independently be the same as described herein with respect to R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

In an embodiment, in Formulae 601 and 601-1, xe1 and xe611 to xe613 may each independently be 0, 1, or 2.

In an embodiment, electron transport region may include one of Compounds ET1 to ET45, 2,9-dimethyl-4,7-diphenyl-1,10-phenanthroline (BCP), 4,7-diphenyl-1,10-phenanthroline (Bphen), Alq3, BAlq, TAZ, NTAZ, or any combination thereof:

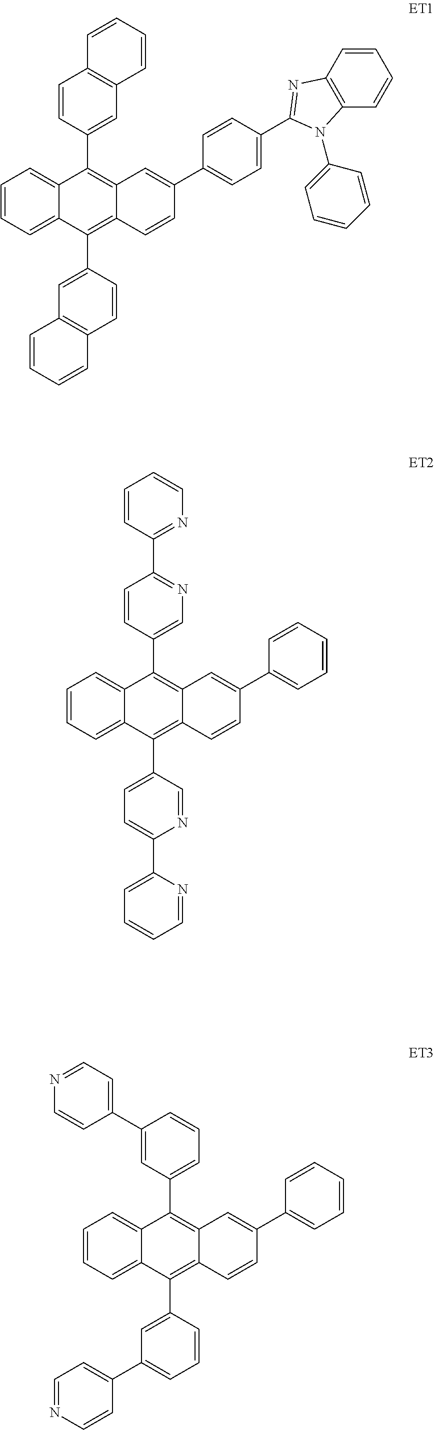 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

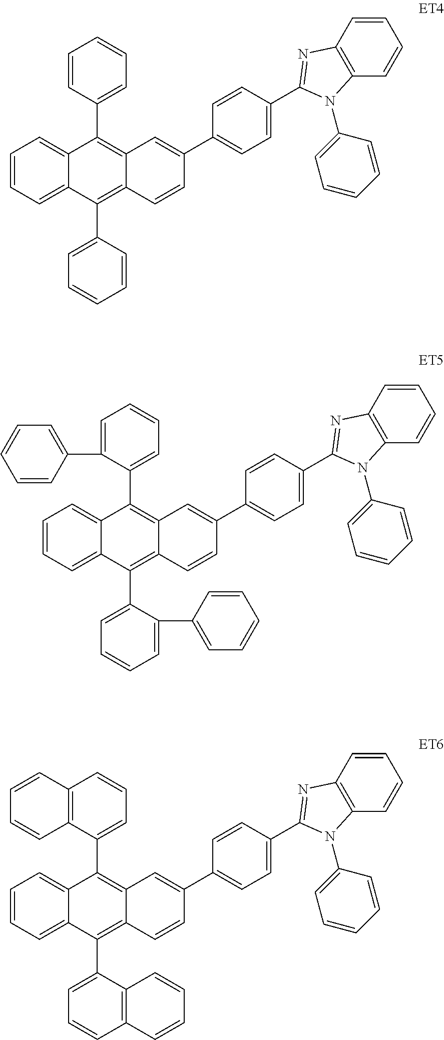 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

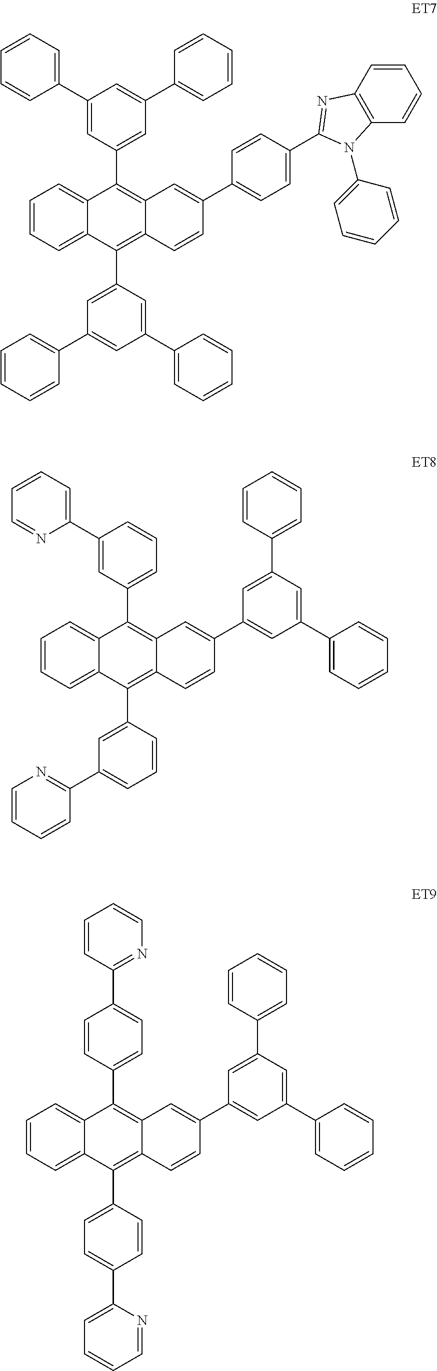 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

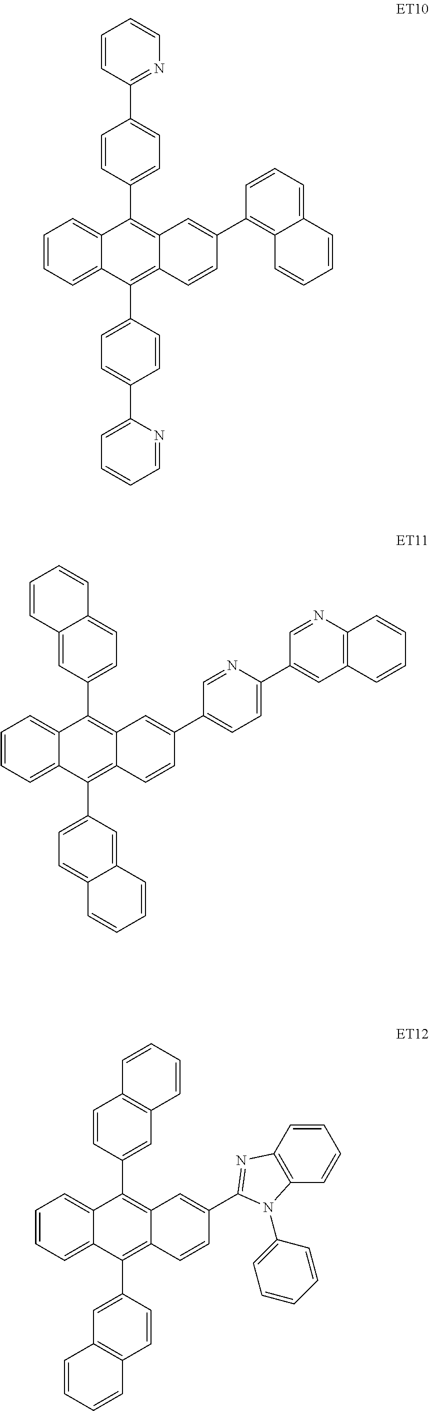 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

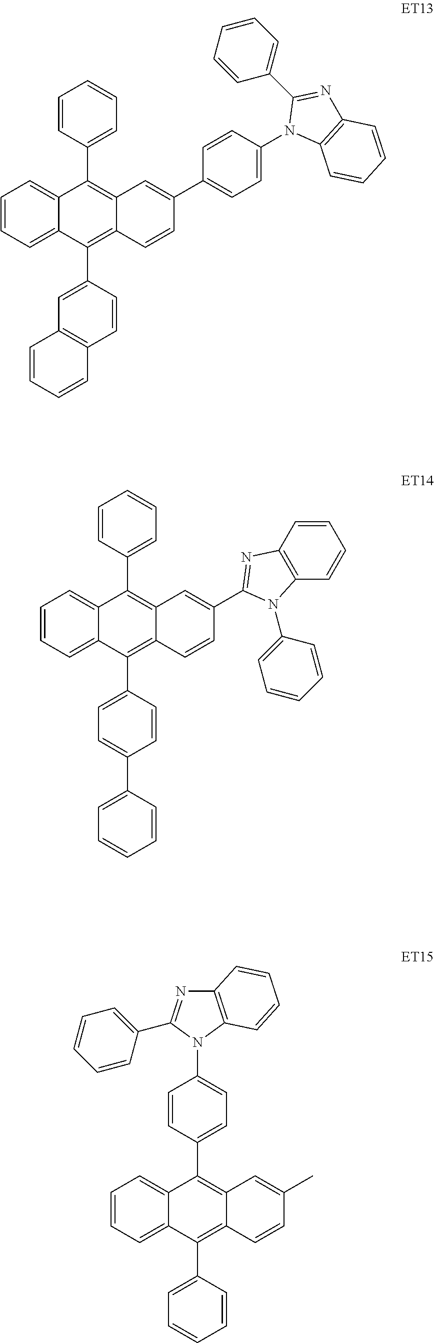 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

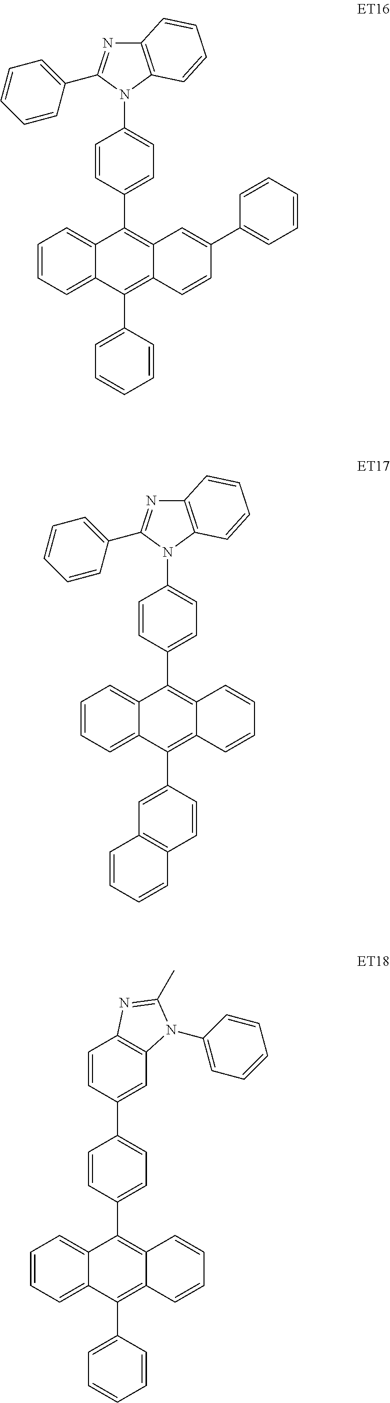 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

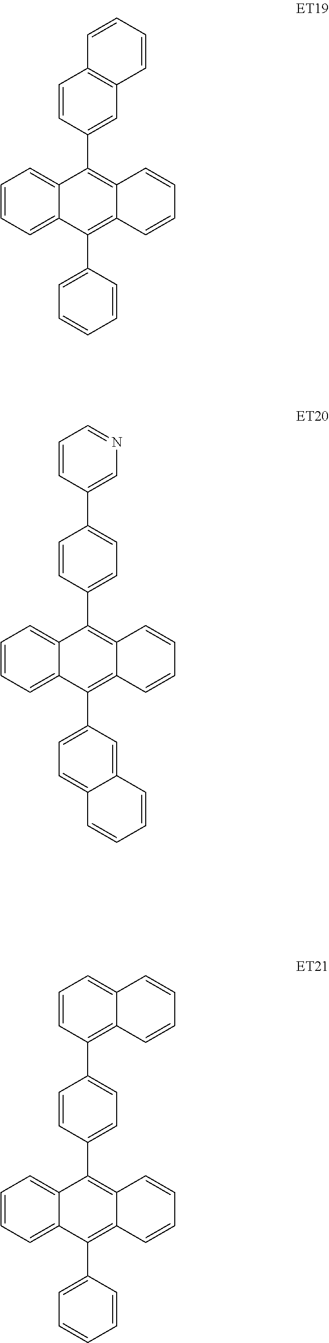

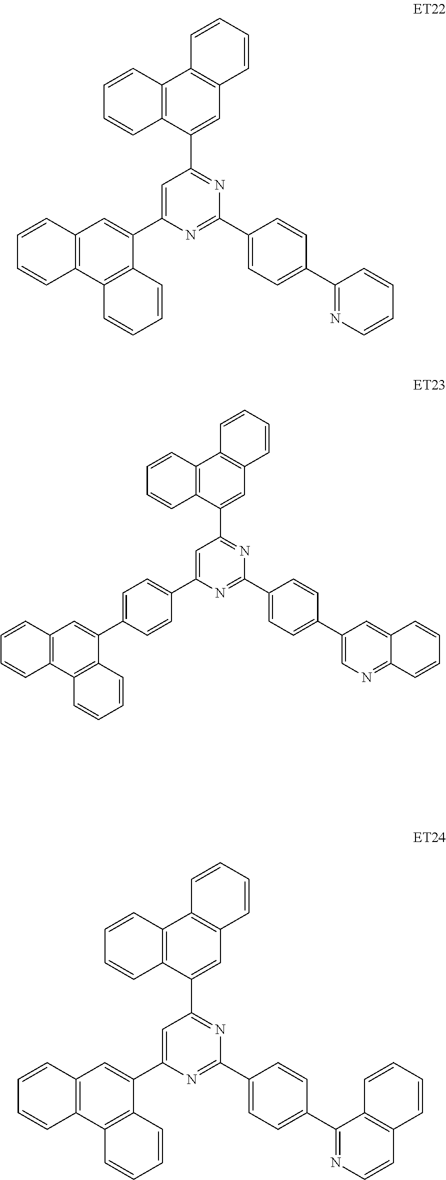 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

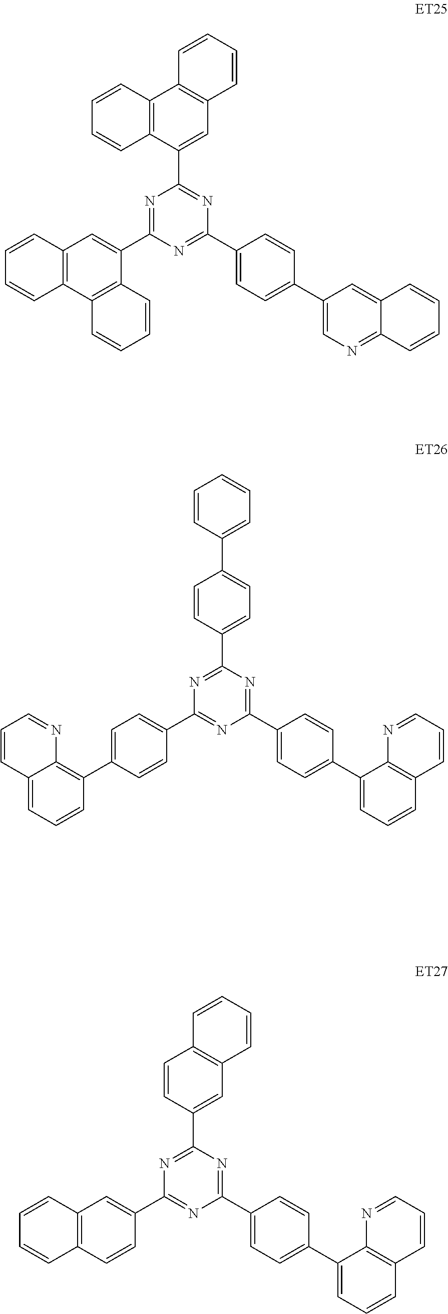 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

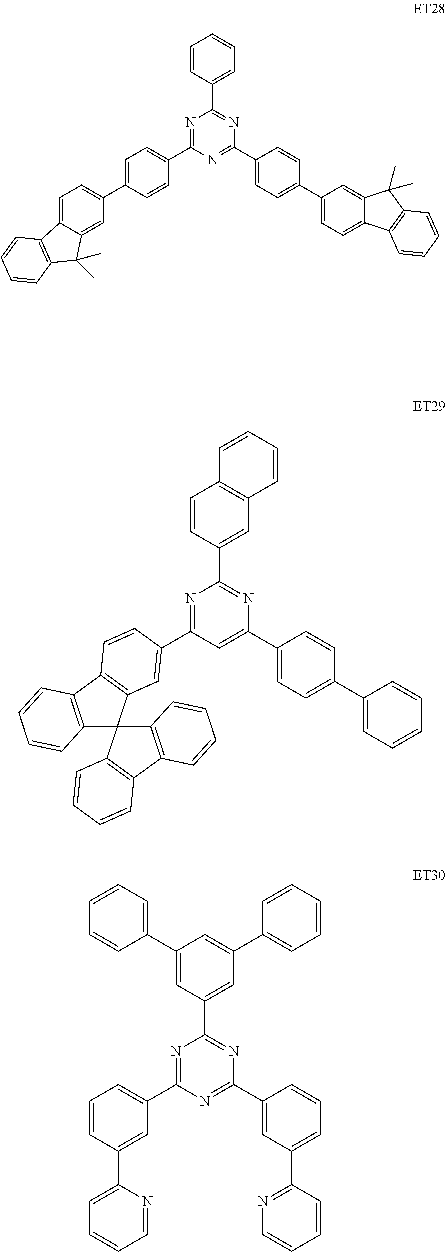 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

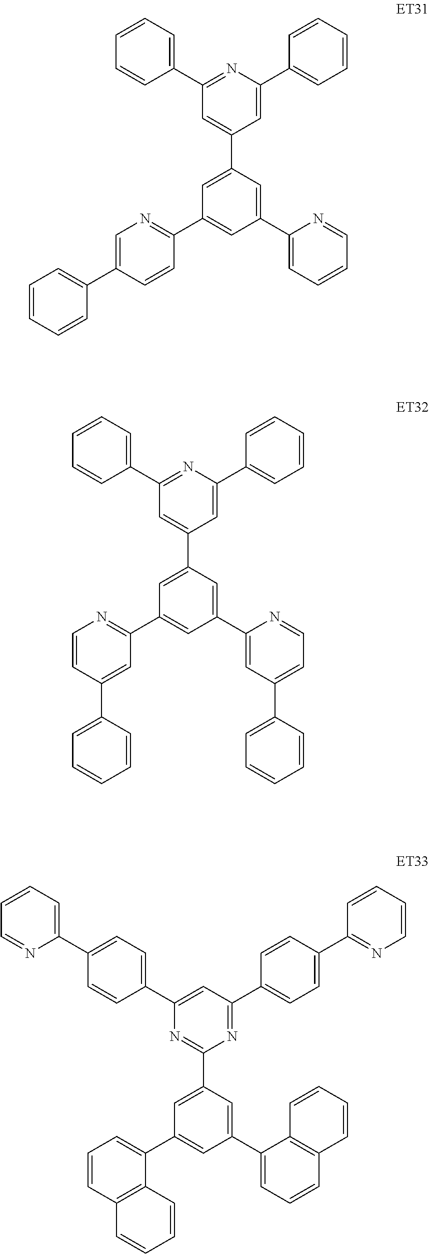 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

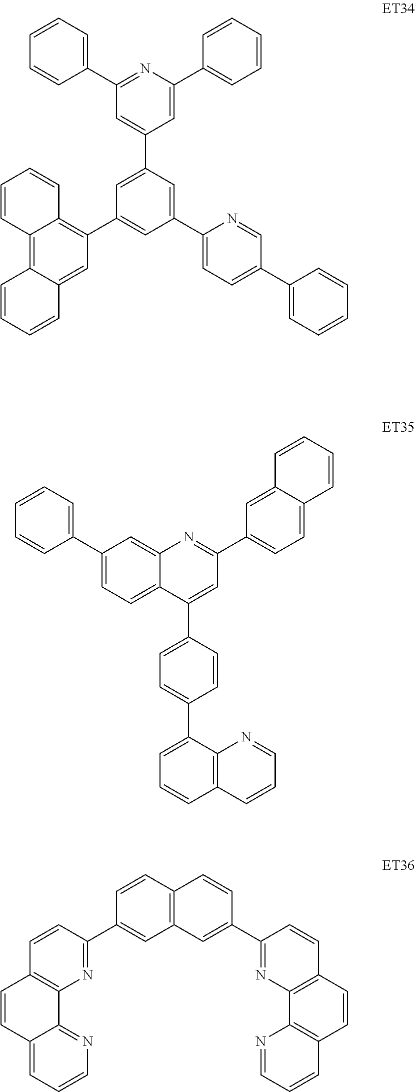 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

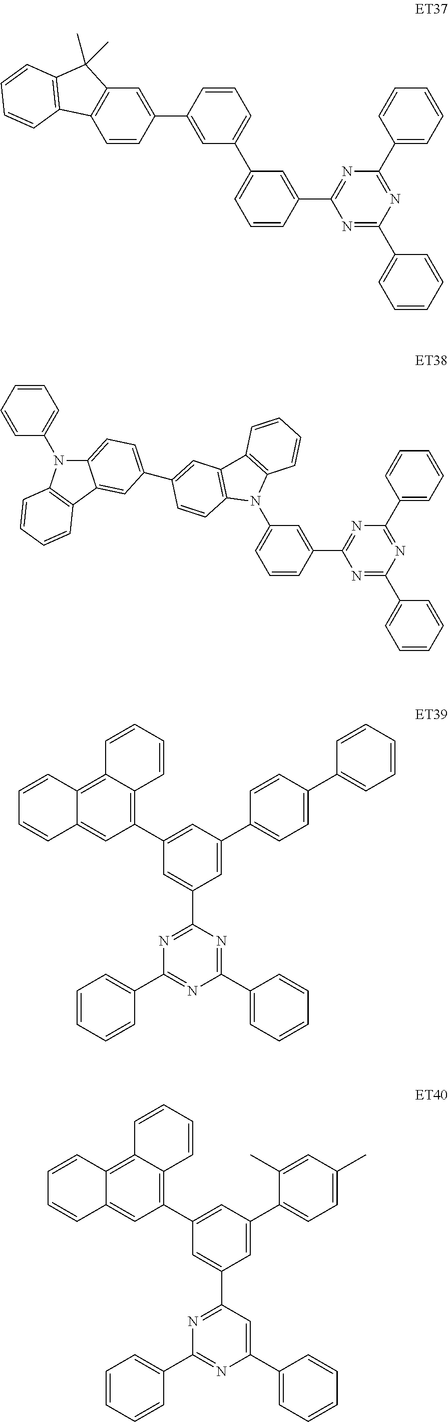 [SMILES: CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1]

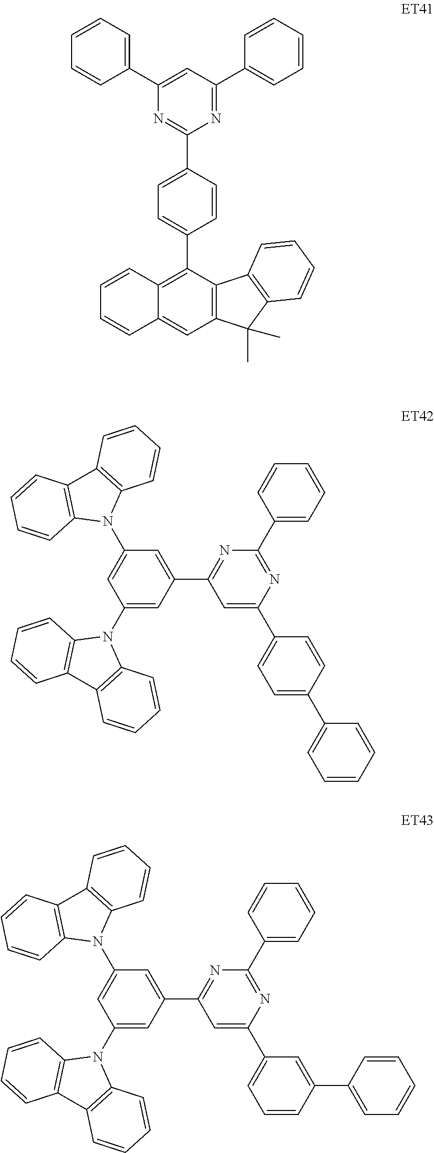 [SMILES: CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1]

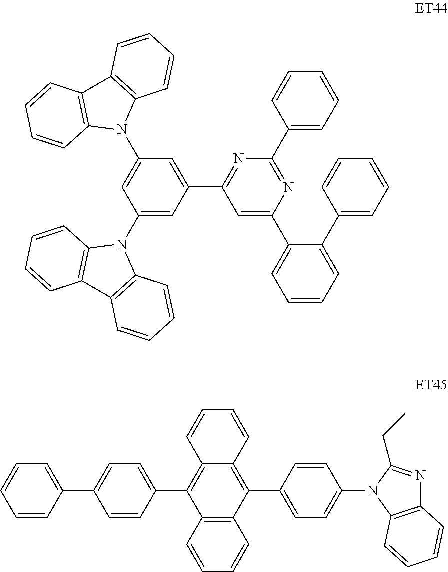 [SMILES: c1ccc(-c2nc(-c3cc(-n4c5ccccc5c5ccccc54)cc(-n4c5ccccc5c5ccccc54)c3)cc(-c3ccccc3-c3ccccc3)n2)cc1 ; CCc1nc2ccccc2n1-c1ccc(-c2c3ccccc3c(-c3ccc(-c4ccccc4)cc3)c3ccccc23)cc1]

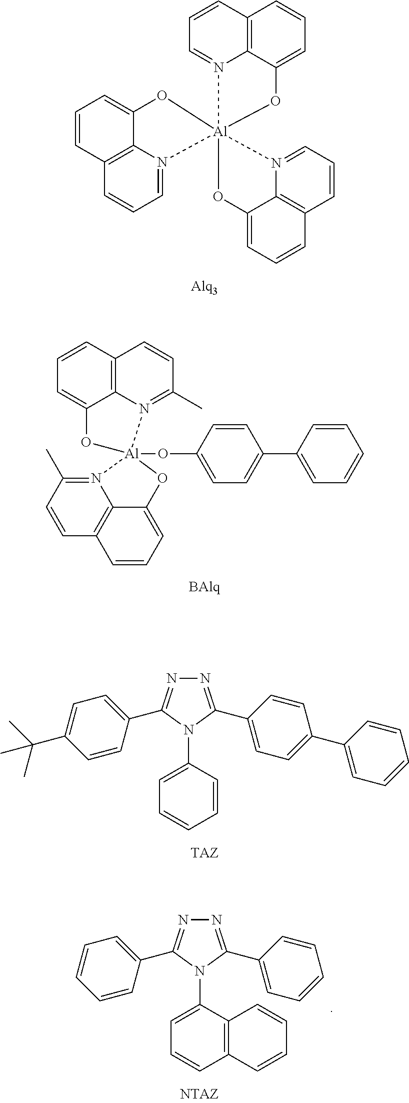

A thickness of the electron transport region may be in a range of about 100 Å to about 5,000 Å. For example, the thickness of the electron transport region may be in a range of about 160 Å to about 4,000 Å. When the electron transport region includes a buffer layer, a hole blocking layer, an electron control layer, an electron transport layer, or any combination thereof, a thickness of the buffer layer, the hole blocking layer, or the electron control layer may each independently be in a range of about 20 Å to about 1,000 Å, and a thickness of the electron transport layer may be in a range of about 100 Å to about 1,000 Å. For example, the thickness of the buffer layer, the hole blocking layer, or the electron control layer may each independently be in a range of about 30 Å to about 300 Å. For example, the thickness of the electron transport layer may be in a range of about 150 Å to about 500 Å. When the thickness of the buffer layer, the hole blocking layer, the electron control layer, the electron transport layer, and/or the electron transport region are within these ranges, satisfactory electron transporting characteristics may be obtained without a substantial increase in driving voltage.

The electron transport region (for example, an electron transport layer in the electron transport region) may further include, in addition to the materials described above, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion.

A ligand coordinated with a metal ion of an alkali metal complex or with a metal ion of an alkaline earth metal complex may each independently include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

In an embodiment, the metal-containing material may include a Li complex. The Li complex may include, for example, Compound ET-D1 (LiQ) or Compound ET-D2:

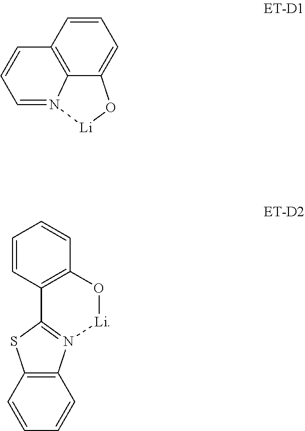

The electron transport region may include an electron injection layer that facilitates the injection of electrons from the second electrode 150. The electron injection layer may directly contact the second electrode 150.

The electron injection layer may have a structure consisting of a layer consisting of a single material, a structure consisting of a layer including different materials, or a structure including multiple layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may be oxides, halides (for example, fluorides, chlorides, bromides, iodides, etc.), or tellurides of the alkali metal, the alkaline earth metal, and the rare earth metal, or any combination thereof.

The alkali metal-containing compound may include: an alkali metal oxide, such as Li₂O, Cs₂O, K₂O, and the like; an alkali metal halide, such as LiF, NaF, CsF, KF, LiI, NaI, CsI, KI, and the like; or any combination thereof. The alkaline earth metal-containing compound may include an alkaline earth metal oxide, such as BaO, SrO, CaO, BaₓSr₁₋ₓO (wherein x is a real number satisfying the condition of 0<x<1), BaₓCa₁₋ₓO (wherein x is a real number satisfying the condition of 0<x<1), and the like. The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In an embodiment, the rare earth metal-containing compound may include a lanthanide metal telluride. Examples of a lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, Lu₂Te₃, and the like.

The alkali metal complex, the alkaline earth metal complex, and the rare earth metal complex may include: an alkali metal ion, an alkaline earth metal ion, or a rare earth metal ion; and a ligand bonded to the metal ion (for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or any combination thereof).

In an embodiment, the electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In embodiments, the electron injection layer may further include an organic material (for example, a compound represented by Formula 601).

According to an embodiment, the electron injection layer may consist of an alkali metal-containing compound (for example, an alkali metal halide); or the electron injection layer may consist of an alkali metal-containing compound (for example, an alkali metal halide), and an alkali metal, an alkaline earth metal, a rare earth metal, or any combination thereof. For example, the electron injection layer may be a KI:Yb co-deposited layer, an RbI:Yb co-deposited layer, a LiF:Yb co-deposited layer, or the like.

When the electron injection layer further includes an organic material, an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof may be uniformly or non-uniformly dispersed in a matrix including the organic material.

A thickness of the electron injection layer may be in a range of about 1 Å to about 100 Å. For example, the thickness of the electron injection layer may be in a range of about 3 Å to about 90 Å. When the thickness of the electron injection layer is within any of the ranges described above, satisfactory electron injection characteristics may be obtained without a substantial increase in driving voltage.

### [Second Electrode 150]

The second electrode 150 may be arranged on the interlayer 130 having a structure as described above. The second electrode 150 may be a cathode, which is an electron injection electrode. When the second electrode 150 is a cathode, the second electrode 150 may include a material having a low-work function, such as a metal, an alloy, an electrically conductive compound, or any combination thereof.

The second electrode 150 may include lithium (Li), silver (Ag), magnesium (Mg), aluminum (AI), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a transflective electrode, or a reflective electrode.

The second electrode 150 may have a single-layered structure or a multi-layered structure.

### [Capping Layer]

The light-emitting device 1A may include a first capping layer arranged outside the first electrode 110, and/or a second capping layer arranged outside the second electrode 150. In embodiments, the light-emitting device 1A may have a structure in which the first capping layer, the first electrode 110, the interlayer 130, and the second electrode 150 are stacked in this stated order, a structure in which the first electrode 110, the interlayer 130, the second electrode 150, and the second capping layer are stacked in this stated order, or a structure in which the first capping layer, the first electrode 110, the interlayer 130, the second electrode 150, and the second capping layer are stacked in this stated order.

Light generated in an emission layer of the interlayer 130 of the light-emitting device 1A may be extracted through the first electrode 110, which may be a transflective electrode or a transmissive electrode, and through the first capping layer to the outside. Light generated in an emission layer of the interlayer 130 of the light-emitting device 1A may be extracted through the second electrode 150, which may be a transflective electrode or a transmissive electrode, and through the second capping layer to the outside.

The first capping layer and the second capping layer may each increase external emission efficiency according to the principle of constructive interference. Accordingly, light extraction efficiency of the light-emitting device 1A may be increased, so that the luminescence efficiency of the light-emitting device 1A may be improved.

the first capping layer and the second capping layer may each include a material having a refractive index equal to or greater than about 1.6 (with respect to a wavelength of about 589 nm).

The first capping layer and the second capping layer may each independently be a capping layer including quantum dots, an organic capping layer including an organic material, an inorganic capping layer including an inorganic material, or an organic-inorganic composite capping layer including an organic material and an inorganic material.

At least one of the first capping layer and the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. In an embodiment, the carbocyclic compound, the heterocyclic compound, and the amine group-containing compound may each be optionally substituted with a substituent including O, N, S, Se, Si, F, Cl, Br, I, or any combination thereof. According to an embodiment, at least one of the first capping layer and the second capping layer may each independently include an amine group-containing compound.

For example, at least one of the first capping layer and the second capping layer may each independently include a compound represented by Formula 201, a compound represented by Formula 202, or any combination thereof.

In an embodiment, at least one of the first capping layer and the second capping layer may each independently include one of Compounds HT28 to HT33, one of Compounds CP1 to CP6, β-NPB, or any combination thereof:

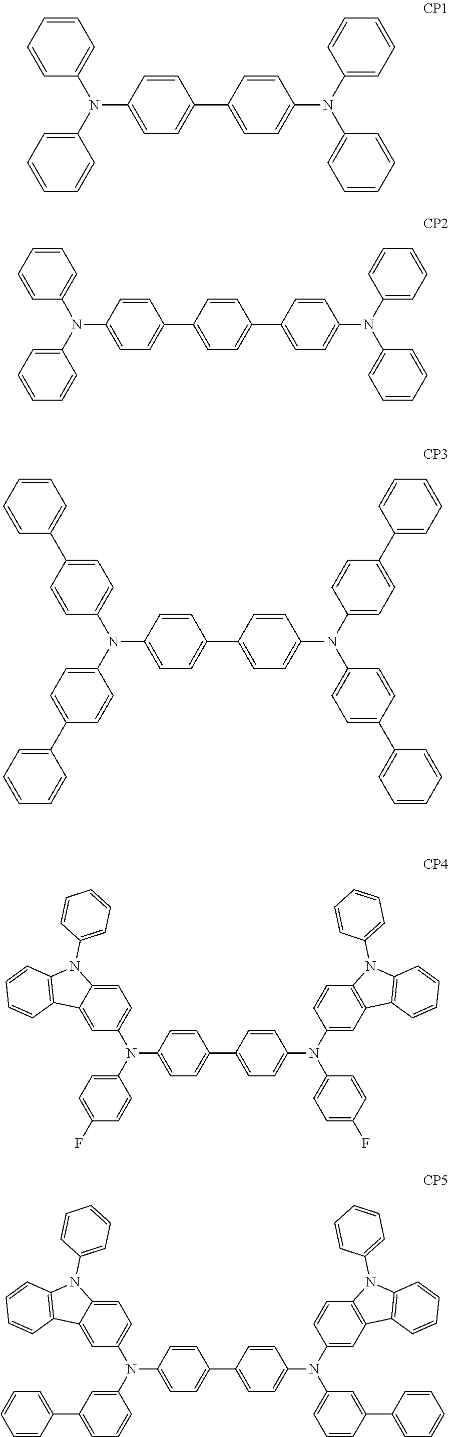 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

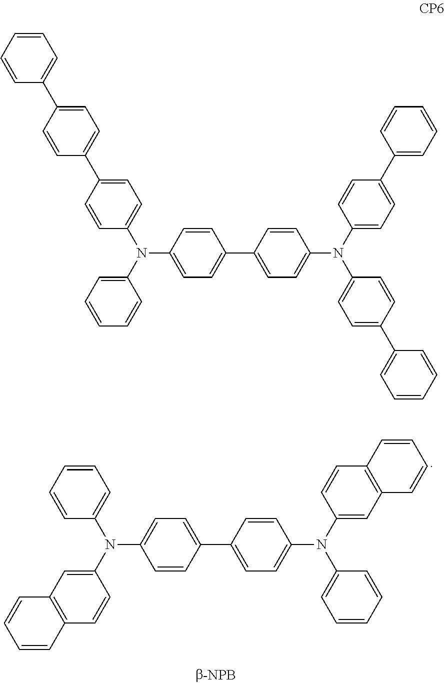 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

### [Film]

The quantum dot may be included in various films. Therefore, according to another embodiment, a film may include the quantum dot. The film may be, for example, an optical member (or a light control means)(for example, a color filter, a color conversion member, a capping layer, a light extraction efficiency enhancement layer, a selective light absorbing layer, a polarizing layer, a quantum dot-containing layer, etc.), a light blocking member (for example, a light reflective layer, a light absorbing layer, etc.), a protective member (for example, an insulating layer, a dielectric layer, etc.), or the like.

### [Optical Member]

The quantum dot may be used in various optical members. Therefore, according to another embodiment, an optical member may include the quantum dot.

According to an embodiment, the optical member may be a light control means.

According to another embodiment, the optical member may be a color filter, a color conversion member, a capping layer, a light extraction efficiency enhancement layer, a selective light absorption layer, or a polarizing layer.

For example, the optical member may be a color conversion member.

The color conversion member may include a substrate and a pattern layer formed on the substrate.

The substrate may be a substrate constituting the color conversion member, or may be a region of various apparatuses (for example, a display apparatus) in which the color conversion member is arranged. The substrate may be glass, silicon (Si), silicon oxide (SiOₓ), or a polymer substrate, and the polymer substrate may be polyethersulfone (PES) or polycarbonate (PC).

The pattern layer may include a quantum dot in the form of a thin film. For example, the pattern layer may be in the form of a thin film that includes quantum dots.

The color conversion member including the substrate and the pattern layer may further include a partition wall or a black matrix formed between pattern layers. In an embodiment, the color conversion member may further include a color filter to further improve light conversion efficiency.

The color conversion member may include a red pattern layer that transmits red light, a green pattern layer that transmits green light, a blue pattern layer that transmits blue light, or any combination thereof. The red pattern layer, the green pattern layer, and/or the blue pattern layer may be implemented by controlling the components, composition, and/or structure of the quantum dots.

According to another embodiment, an apparatus may include the quantum dots (or an optical member including the quantum dots).

The apparatus may further include a light source, and the quantum dots (or optical members including the quantum dots) may be arranged in an optical path of light emitted from the light source.

The light source may emit blue light, red light, green light, or white light. For example, the light source may emit blue light or red light. Light emitted from the light source may be absorbed by the quantum dots.

The light source may be an organic light-emitting device (OLED) or a light-emitting diode (LED).

Light emitted from the light source as described above may have its wavelength converted by the quantum dot while passing through the quantum dot, and thus, light having a different wavelength from the wavelength of the light emitted from the light source may be emitted by the quantum dot.

For example, the quantum dot may absorb and convert light emitted from the light source to emit light with a maximum emission wavelength of about 400 nm to about 2500 nm.

### [Electronic Apparatus]

The quantum dot and the light-emitting device including the quantum dot may be included in various electronic apparatuses. For example, an electronic apparatus including the quantum dot and a light-emitting device including the quantum dot may be a light-emitting apparatus, an authentication apparatus, or the like.

The electronic apparatus (for example, a light-emitting apparatus) may further include, in addition to the light-emitting device, a color filter, a color conversion layer, or a color filter and a color conversion layer. The color filter and/or the color conversion layer may be arranged in at least one direction in which light emitted from the light-emitting device travels. For example, the light emitted from the light-emitting device may be red light, blue light, or white light. Further details on the light-emitting device may be the same as described herein. According to an embodiment, the color conversion layer may include a quantum dot. The quantum dot may be, for example, a quantum dot as described herein.

The electronic apparatus may include a substrate. The substrate may include subpixels, the color filter may include a color filter areas respectively corresponding to the subpixels, and the color conversion layer may include color conversion areas respectively corresponding to the subpixels.

A pixel-defining film may be arranged between the subpixels to define each subpixel.

The color filter may further include color filter areas and light-shielding patterns arranged between the color filter areas, and the color conversion layer may further include color conversion areas and light-shielding patterns arranged between the color conversion areas.

The color filter areas (or the color conversion areas) may include: a first area emitting first color light; a second area emitting second color light; and/or a third area emitting third color light, wherein the first color light, the second color light, and/or the third color light may have different maximum emission wavelengths from one another. For example, the first color light may be red light, the second color light may be green light, and the third color light may be blue light. In an embodiment, the color filter areas (or the color conversion areas) may include quantum dots. For example, the first area may include a red quantum dot, the second area may include a green quantum dot, and the third area may not include a quantum dot. Further details on the quantum dots may be the same as described herein. The first area, the second area, and/or the third area may each further include a scatterer.

In an embodiment, the light-emitting device may emit first light, the first area may absorb the first light to emit first-first color light, the second area may absorb the first light to emit second-first color light, and the third area may absorb the first light to emit third-first color light. The first-first color light, the second-first color light, and the third-first color light may have different maximum emission wavelengths. For example, the first light may be blue light, the first-first color light may be red light, the second-first color light may be green light, and the third-first color light may be blue light.

The electronic apparatus may further include a thin-film transistor, in addition to the light-emitting device as described above. The thin-film transistor may include a source electrode, a drain electrode, and an active layer, wherein any one of the source electrode and the drain electrode may be electrically connected to any one of the first electrode and the second electrode of the light-emitting device.

The thin-film transistor may further include a gate electrode, a gate insulating film, or the like.

The active layer may include crystalline silicon, amorphous silicon, an organic semiconductor, an oxide semiconductor, or the like.

The electronic apparatus may further include a sealing portion for sealing the light-emitting device. The sealing portion may be arranged between the color filter and/or the color conversion layer and the light-emitting device. The sealing portion allows light from the light-emitting device to be extracted to the outside, and simultaneously prevents ambient air and moisture from penetrating into the light-emitting device. The sealing portion may be a sealing substrate that includes a transparent glass substrate or a plastic substrate. The sealing portion may be a thin-film encapsulation layer that includes at least one of an organic layer and/or an inorganic layer. When the sealing portion is a thin-film encapsulation layer, the electronic apparatus may be flexible.

Various functional layers may be further included on the sealing portion, in addition to the color filter and/or the color conversion layer, according to a use of the electronic apparatus. Examples of a functional layer may include a touch screen layer, a polarizing layer, and the like. The touch screen layer may be a pressure-sensitive touch screen layer, a capacitive touch screen layer, or an infrared touch screen layer. The authentication apparatus may be, for example, a biometric authentication apparatus that authenticates an individual by using biometric information of a living body (for example, fingertips, pupils, etc.).

The authentication apparatus may further include, in addition to the light-emitting device as described above, a biometric information collector.

The electronic apparatus may be applied to various displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, various measuring instruments, meters (for example, meters for a vehicle, an aircraft, and a vessel), projectors, and the like.

### [Electronic Device]

The quantum dot and a light-emitting device including the quantum dot may be included in various electronic devices.

In embodiments, the electronic device including the light-emitting device may be a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a mobile phone, a tablet computer, a phablet, a personal digital assistant (PDA), a wearable device, a laptop computer, a digital camera, a camcorder, a viewfinder, a micro display, a three-dimensional (3D) display, a virtual reality display, an augmented reality display, a vehicle, a video wall with multiple displays tiled together, a theater screen, a stadium screen, a phototherapy device, or a signboard.

The light-emitting device may have excellent effects in terms of luminescence efficiency and long lifespan, and thus the electronic device including the light-emitting device may have characteristics such as high luminance, high resolution, and low power consumption.

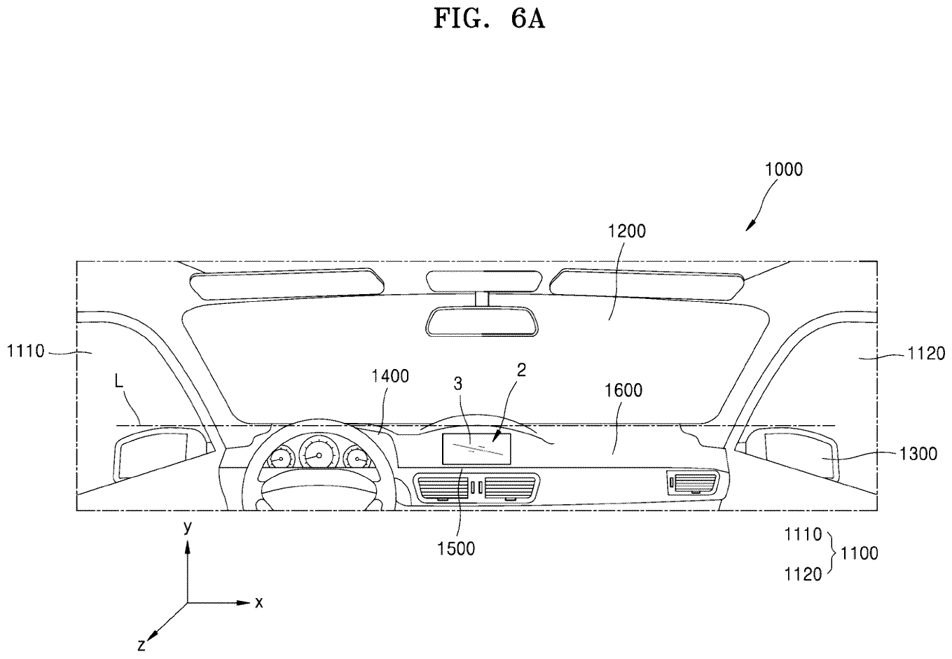

### [Description of FIG. 4]

FIG. 4 is a schematic perspective view of an electronic device 1 including a light-emitting device according to an embodiment.

The electronic device 1, which may be an apparatus that displays a moving image or still image, may be not only a portable electronic device, such as a mobile phone, a smartphone, a tablet computer, a mobile communication terminal, an electronic notebook, an electronic book, a portable multimedia player (PMP), a navigation device, or an ultra-mobile PC (UMPC), but may also be various products, such as a television, a laptop computer, a monitor, a billboards, or an Internet of things (IOT). The electronic device 1 may be any product as described above or a part thereof.

In an embodiment, the electronic device 1 may be a wearable device, such as a smart watch, a watch phone, a glasses-type display, or a head mounted display (HMD), or a part of the wearable device. However, embodiments are not limited thereto.

In embodiments, examples of the electronic device 1 may include a dashboard of a vehicle, a center information display (CID) on a center fascia or on a dashboard of a vehicle, a room mirror display that replaces a side mirror of a vehicle, an entertainment display arranged for a rear seat of a vehicle or arranged on the back of a front seat, a head-up display (HUD) installed at the front of a vehicle or projected on a front window glass, or a computer generated hologram augmented reality head up display (CGH AR HUD). FIG. 4 illustrates an embodiment in which the electronic device 1 is a smartphone, for convenience of explanation.

The electronic device 1 may include a display area DA and a non-display area NDA outside the display area DA. A display device may implement an image through a two-dimensional array of pixels that are arranged in the display area DA.

The non-display area NDA is an area that does not display an image, and may surround (for example, entirely surround) the display area DA. A driver for providing electrical signals or power to display devices arranged in the display area DA may be arranged in the non-display area NDA. A pad, which is an area to which an electronic element or a printed circuit board may be electrically connected, may be arranged in the non-display area NDA.

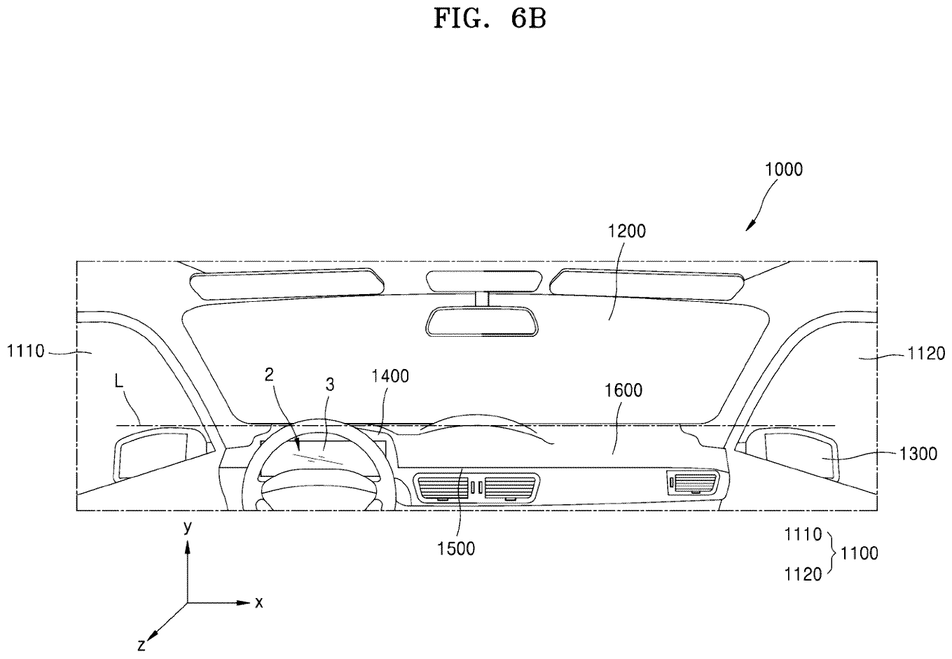

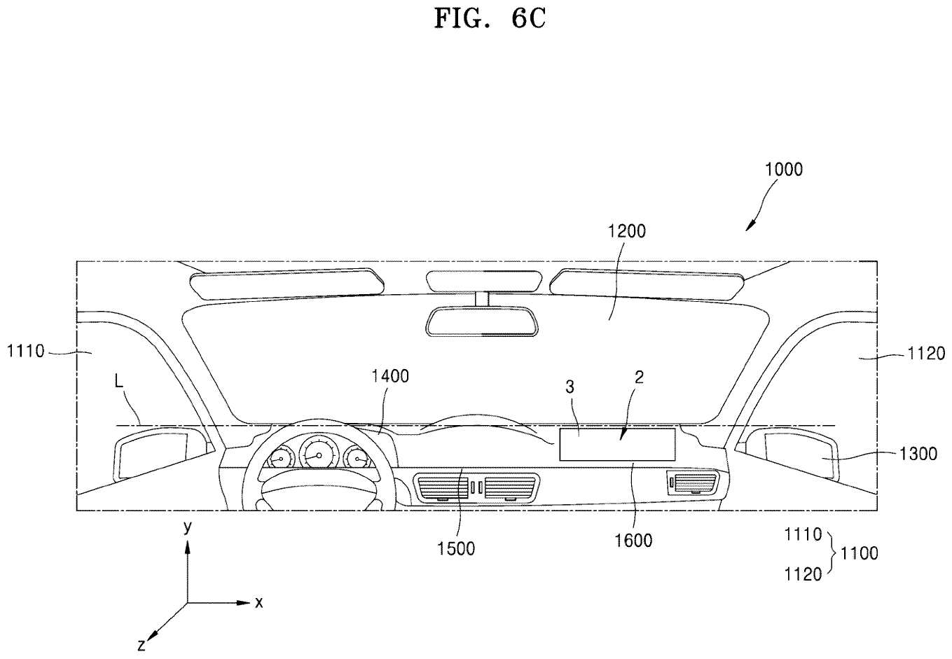

In the electronic device 1, a length in an x-axis direction and a length in a y-axis direction may be different from each other. For example, as shown in FIG. 4, the length in the x-axis direction may be shorter than the length in the y-axis direction. In embodiments, the length in the x-axis direction may be the same as the length in the y-axis direction. In embodiments, the length in the x-axis direction may be longer than the length in the y-axis direction.

[Descriptions of FIGS. 5 and 6a to 6c]

FIG. 5 is a schematic perspective view of an exterior of a vehicle 1000 as an electronic device including a light-emitting device, according to an embodiment. FIGS. 6A to 6C are each a schematic diagram of an interior of a vehicle 1000 according to embodiments.

Referring to FIGS. 5, 6A, 6B, and 6C, embodiments of a vehicle 1000 may include various apparatuses for moving a subject to be transported, such as a person, an object, or an animal, from a departure point to a destination. Examples of a vehicle 1000 may include a vehicle traveling on a road or a track, a vessel moving over a sea or a river, an airplane flying in the sky using the action of air, and the like.

The vehicle 1000 may travel on a road or a track. The vehicle 1000 may move in a selected or given direction according to the rotation of at least one wheel. In an embodiment, examples of a vehicle 1000 may include a three-wheeled or four-wheeled vehicle, a construction machine, a two-wheeled vehicle, a prime mover device, a bicycle, and a train running on a track.

The vehicle 1000 may include a vehicle body having an interior and an exterior, and a chassis that is a portion excluding the vehicle body in which mechanical apparatuses necessary for driving are installed. The exterior of the vehicle body may include a front panel, a bonnet, a roof panel, a rear panel, a trunk, a pillar provided at a boundary between doors, and the like. The chassis of the vehicle 1000 may include a power generating device, a power transmitting device, a driving device, a steering device, a braking device, a suspension device, a transmission device, a fuel device, front and rear wheels, left and right wheels, and the like.

The vehicle 1000 may include a side window glass 1100, a front window glass 1200, a side mirror 1300, a cluster 1400, a center fascia 1500, a passenger seat dashboard 1600, and a display device 2.

The side window glass 1100 and the front window glass 1200 may be partitioned by a pillar arranged between the side window glass 1100 and the front window glass 1200.

The side window glass 1100 may be installed on a side of the vehicle 1000. In an embodiment, the side window glass 1100 may be installed on a door of the vehicle 1000. Multiple side window glasses 1100 may be provided and may face each other. In an embodiment, the side window glass 1100 may include a first side window glass 1110 and a second side window glass 1120. In an embodiment, the first side window glass 1110 may be arranged adjacent to the cluster 1400, and the second side window glass 1120 may be arranged adjacent to the passenger seat dashboard 1600.

In an embodiment, the side window glasses 1100 may be spaced apart from each other in the x-direction or the −x-direction. For example, the first side window glass 1110 and the second side window glass 1120 may be spaced apart from each other in the x direction or the −x direction. For example, a virtual straight line L connecting the side window glasses 1100 may extend in the x-direction or the −x-direction. For example, a virtual straight line L connecting the first side window glass 1110 and the second side window glass 1120 to each other may extend in the x direction or the −x direction.

The front window glass 1200 may be installed in the front of the vehicle 1000. The front window glass 1200 may be arranged between the side window glasses 1100 facing each other.

The side mirror 1300 may provide a rear view of the vehicle 1000. The side mirror 1300 may be installed on the exterior of the vehicle body. In an embodiment, multiple side mirrors 1300 may be provided. For example, one of the side mirrors 1300 may be arranged outside the first side window glass 1110, and another of the side mirrors 1300 may be arranged outside the second side window glass 1120.

The cluster 1400 may be arranged in front of the steering wheel. The cluster 1400 may include a tachometer, a speedometer, a coolant thermometer, a fuel gauge, a turn signal indicator, a high beam indicator, a warning light, a seat belt warning light, an odometer, a tachograph, an automatic shift selector indicator light, a door open warning light, an engine oil warning light, and/or a low fuel warning light.

The center fascia 1500 may include a control panel on which buttons for adjusting an audio device, an air conditioning device, and a seat heater are arranged. The center fascia 1500 may be arranged on a side of the cluster 1400.

A passenger seat dashboard 1600 may be spaced apart from the cluster 1400, and the center fascia 1500 may be arranged between the cluster 1400 and the passenger seat dashboard 1600. In an embodiment, the cluster 1400 may be arranged to correspond to a driver seat (not shown), and the passenger seat dashboard 1600 may be arranged to correspond to a passenger seat (not shown). In an embodiment, the cluster 1400 may be adjacent to the first side window glass 1110, and the passenger seat dashboard 1600 may be adjacent to the second side window glass 1120.

In an embodiment, the display device 2 may include a display panel 3, and the display panel 3 may display an image. The display device 2 may be arranged inside the vehicle 1000. In an embodiment, the display device 2 may be arranged between the side window glasses 1100 facing each other. The display device 2 may be arranged on at least one of the cluster 1400, the center fascia 1500, and the passenger seat dashboard 1600.

The display device 2 may include an organic light-emitting display, an inorganic electroluminescent (EL) display, a quantum dot display, or the like. Hereinafter, an organic light-emitting display device including the light-emitting device according to an embodiment will be described as an example of the display device 2. However, various types of display devices as described above may be used in embodiments.

Referring to FIG. 6A, the display device 2 may be arranged on the center fascia 1500. In an embodiment, the display device 2 may display navigation information. In an embodiment, the display device 2 may display information regarding audio, video, or vehicle settings.

Referring to FIG. 6B, the display device 2 may be arranged on the cluster 1400. When the display device 2 is arranged on the cluster 1400, the cluster 1400 may display driving information and the like through the display device 2. For example, the cluster 1400 may digitally implement driving information and the like. The cluster 1400 may display vehicle information and driving information as images. For example, a needle and a gauge of a tachometer and various warning lights or icons may be displayed by a digital signal.

Referring to FIG. 6C, the display device 2 may be arranged on the passenger seat dashboard 1600. The display device 2 may be embedded in the passenger seat dashboard 1600 or located on the passenger seat dashboard 1600. In an embodiment, the display device 2 arranged on the passenger seat dashboard 1600 may display an image that is related to information displayed on the cluster 1400 and/or information displayed on the center fascia 1500. In an embodiment, the display device 2 arranged on the passenger seat dashboard 1600 may display information that is different from information displayed on the cluster 1400 and/or information displayed on the center fascia 1500.

### [Manufacturing Method]

Layers constituting the hole transport region, the emission layer, and the layers constituting the electron transport region may be formed in a selected region by using various methods such as vacuum deposition, spin coating, casting, Langmuir-Blodgett (LB) deposition, ink-jet printing, laser-printing, laser-induced thermal imaging, and the like.

When the layers constituting the hole transport region, the emission layer, and the layers constituting the electron transport region are formed by vacuum deposition, the deposition may be performed at a deposition temperature in a range of about 100° C. to about 500° C., at a vacuum degree in a range of about 10⁻⁸ torr to about 10⁻³ torr, and at a deposition speed in a range of about 0.01 Å/sec to about 100 Å/sec, depending on a material to be included in a layer to be formed and the structure of a layer to be formed.

### Definitions of Terms

The term “C₃-C₆₀ carbocyclic group” as used herein may be a cyclic group consisting of carbon atoms as the only ring-forming atoms and having 3 to 60 carbon atoms. The term “C₁-C₆₀ heterocyclic group” as used herein may be a cyclic group that has 1 to 60 carbon atoms and further includes, in addition to a carbon atom, at least one heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. For example, the number of ring-forming atoms in a C₁-C₆₀ heterocyclic group may be from 3 to 61.

The term “cyclic group” as used herein may be a C₃-C₆₀ carbocyclic group or a C₁-C₆₀ heterocyclic group.

The term “TT electron-rich C₃-C₆₀ cyclic group” as used herein may be a cyclic group that has 3 to 60 carbon atoms and may not include *—N=*′ as a ring-forming moiety. The term “TT electron-deficient nitrogen-containing C₁-C₆₀ cyclic group” as used herein may be a heterocyclic group that has 1 to 60 carbon atoms and may include *—N=*′ as a ring-forming moiety.

### In Embodiments,

a C₃-C₆₀ carbocyclic group may be a T1 group or a group in which two or more T1 groups are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
a C₁-C₆₀ heterocyclic group may be a T2 group, a group in which two or more T2 groups are condensed with each other, or a group in which at least one T2 group and at least one T1 group are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
a π electron-rich C₃-C₆₀ cyclic group may be a T1 group, a group in which two or more T1 groups are condensed with each other, a T3 group, a group in which two or more T3 groups are condensed with each other, or a group in which at least one Group T3 group and at least one T1 group are condensed with each other (for example, a C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.), and
a π electron-deficient nitrogen-containing C₁-C₆₀ cyclic group may be a T4 group, a group in which two or more T4 groups are condensed with each other, a group in which at least one T4 group and at least one T1 group are condensed with each other, a group in which at least one T4 group and at least one T3 group are condensed with each other, or a group in which at least one T4 group, at least one T1 group, and at least one T3 group are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.), wherein
a T1 group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,
a T2 group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
a T3 group may be a furan group, a thiophene group, a 1H-pyrrole group, a silole group, or a borole group, and
a T4 group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “cyclic group”, “C₃-C₆₀ carbocyclic group”, “C₁-C₆₀ heterocyclic group”, “π electron-rich C₃-C₆₀ cyclic group”, and “π electron-deficient nitrogen-containing C₁-C₆₀ cyclic group” as used herein may each be a group condensed to any cyclic group, a monovalent group, or a polyvalent group (for example, a divalent group, a trivalent group, a tetravalent group, etc.) according to the structure of a formula for which the corresponding term is used. For example, a “benzene group” may be a benzo group, a phenyl group, a phenylene group, or the like, which may be readily understood by one of ordinary skill in the art according to the structure of a formula including the “benzene group.”

Examples of a monovalent C₅-C₆₀ carbocyclic group or a monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group. Examples of a divalent C₃-C₆₀ carbocyclic group or a divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein may be a linear or branched monovalent aliphatic hydrocarbon group that has 1 to 60 carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, and the like. The term “C₁-C₆₀ alkylene group” as used herein may be a divalent group having a same structure as the C₁-C₆₀ alkyl group.

The term “C₂-C₆₀ alkenyl group” as used herein may be a monovalent hydrocarbon group having at least one carbon-carbon double bond in the middle or at a terminus of a C₂-C₆₀ alkyl group, and examples thereof may include an ethenyl group, a propenyl group, a butenyl group, and the like. The term “C₂-C₆₀ alkenylene group” as used herein may be a divalent group having a same structure as the C₂-C₆₀ alkenyl group.

The term “C₂-C₆₀ alkynyl group” as used herein may be a monovalent hydrocarbon group having at least one carbon-carbon triple bond in the middle or at a terminus of a C₂-C₆₀ alkyl group, and examples thereof may include an ethynyl group, a propynyl group, and the like. The term “C₂-C₆₀ alkynylene group” as used herein may be a divalent group having a same structure as the C₂-C₆₀ alkynyl group.

The term “C₁-C₆₀ alkoxy group” as used herein may be a monovalent group represented by —O(A₁₀₁) (wherein A₁₀₁ may be a C₁-C₆₀ alkyl group), and examples thereof may include a methoxy group, an ethoxy group, an isopropyloxy group, and the like.

The term “C₃-C₁₀ cycloalkyl group” as used herein may be a monovalent saturated hydrocarbon cyclic group having 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1] heptyl group), a bicyclo[1.1.1] pentyl group, a bicyclo[2.1.1] hexyl group, a bicyclo[2.2.2] octyl group, and the like. The term “C₃-C₁₀ cycloalkylene group” as used herein may be a divalent group having a same structure as the C₃-C₁₀ cycloalkyl group.

The term “C₁-C₁₀ heterocycloalkyl group” as used herein may be a monovalent cyclic group that has 1 to 10 carbon atoms and further includes, in addition to carbon atoms, at least one heteroatom as a ring-forming atom, and examples thereof may include a 1,2,3,4-oxatriazolidinyl group, a tetrahydrofuranyl group, a tetrahydrothiophenyl group, and the like. The term “C₁-C₁₀ heterocycloalkylene group” as used herein may be a divalent group having a same structure as the C₁-C₁₀ heterocycloalkyl group.

The term “C₃-C₁₀ cycloalkenyl group” as used herein may be a monovalent cyclic group that has 3 to 10 carbon atoms and at least one carbon-carbon double bond in the cyclic structure thereof and no aromaticity, and examples thereof may include a cyclopentenyl group, a cyclohexenyl group, a cycloheptenyl group, and the like. The term “C₃-C₁₀ cycloalkenylene group” as used herein may be a divalent group having a same structure as the C₃-C₁₀ cycloalkenyl group.

The term “C₁-C₁₀ heterocycloalkenyl group” as used herein may be a monovalent cyclic group that has 1 to 10 carbon atoms that further includes, in addition to carbon atoms, at least one heteroatom as a ring-forming atom, and has at least one double bond in the cyclic structure thereof. Examples of a C₁-C₁₀ heterocycloalkenyl group may include a 4,5-dihydro-1,2,3,4-oxatriazolyl group, a 2,3-dihydrofuranyl group, a 2,3-dihydrothiophenyl group, and the like. The term “C₁-C₁₀ heterocycloalkenylene group” as used herein may be a divalent group having a same structure as the C₁-C₁₀ heterocycloalkenyl group.

The term “C₆-C₆₀ aryl group” as used herein may be a monovalent group having a carbocyclic aromatic system of 6 to 60 carbon atoms, and the term “C₆-C₆₀ arylene group” as used herein may be a divalent group having a carbocyclic aromatic system of 6 to 60 carbon atoms. Examples of a C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and the like. When the C₆-C₆₀ aryl group and the C₆-C₆₀ arylene group each include two or more rings, the respective two or more rings may be condensed with each other.

The term “C₁-C₆₀ heteroaryl group” as used herein may be a monovalent group having a heterocyclic aromatic system that has 1 to 60 carbon atoms and further includes, in addition to carbon atoms, at least one heteroatom as a ring-forming atom. The term “C₁-C₆₀ heteroarylene group” as used herein may be a divalent group having a heterocyclic aromatic system that has 1 to 60 carbon atoms and further includes, in addition to carbon atoms, at least one heteroatom as a ring-forming atom. Examples of a C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, and the like. When the C₁-C₆₀ heteroaryl group and the C₁-C₆₀ heteroarylene group each include two or more rings, the respective two or more rings may be condensed with each other.

The term “monovalent non-aromatic condensed polycyclic group” as used herein may be a monovalent group (for example, having 8 to 60 carbon atoms) having two or more rings condensed to each other, only carbon atoms as ring-forming atoms, and no aromaticity in its molecular structure as a whole. Examples of a monovalent non-aromatic condensed polycyclic group may include an indenyl group, a fluorenyl group, a spiro-bifluorenyl group, a benzofluorenyl group, an indenophenanthrenyl group, an indeno anthracenyl group, and the like. The term “divalent non-aromatic condensed polycyclic group” as used herein may be a divalent group having a same structure as the monovalent non-aromatic condensed polycyclic group.

The term “monovalent non-aromatic condensed heteropolycyclic group” as used herein may be a monovalent group (for example, having 1 to 60 carbon atoms) having two or more rings condensed to each other that further includes, in addition to carbon atoms, at least one heteroatom as a ring-forming atom, and having no aromaticity in its molecular structure as a whole. Examples of a monovalent non-aromatic condensed heteropolycyclic group may include a pyrrolyl group, a thiophenyl group, a furanyl group, an indolyl group, a benzoindolyl group, a naphtho indolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, a benzothienodibenzothiophenyl group, and the like. The term “divalent non-aromatic condensed heteropolycyclic group” as used herein may be a divalent group having a same structure as the monovalent non-aromatic condensed heteropolycyclic group.

The term “C₆-C₆₀ aryloxy group” as used herein may be a group represented by —O (A₁₀₂) (wherein A₁₀₂ may be a C₆-C₆₀ aryl group), and the term “C₆-C₆₀ arylthio group” as used herein may be a group represented by —S(A₁₀₃) (wherein A₁₀₃ may be a C₆-C₆₀ aryl group).

The term “C₇-C₆₀ arylalkyl group” as used herein may be a group represented by -(A₁₀₄)(A₁₀₅) (wherein A₁₀₄ may be a C₁-C₅₄ alkylene group, and A₁₀₅ may be a C₆-C₅₉ aryl group), and the term “C₂-C₆₀ heteroarylalkyl group” as used herein may be a group represented by -(A₁₀₆)(A₁₀₇) (wherein A₁₀₆ may be a C₁-C₅₉ alkylene group, and A₁₀₇ may be a C₁-C₅₉ heteroaryl group).

In the specification, the group R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₅-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the specification, Q₁ to Q₃, Q₁₁ to Q₁₃, Q₂₁ to Q₂₃ and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof; a C₇-C₆₀ aryl alkyl group; or a C₂-C₆₀ heteroaryl alkyl group.

The term “heteroatom” as used herein may be any atom other than a carbon atom or a hydrogen atom. Examples of a heteroatom may include O, S, N, P, Si, B, Ge, Se, and any combination thereof.

In the specification, examples of a “third-row transition metal” may include hafnium (Hf), tantalum (Ta), tungsten (W), rhenium (Re), osmium (Os), iridium (Ir), platinum (Pt), gold (Au), and the like.

In the specification, the term “Ph” may refer to a phenyl group, the term “Me” may refer to a methyl group, the term “Et” may refer to an ethyl group, the terms “tert-Bu” and “But” may each refer to a tert-butyl group, and the term “OMe” may refer to a methoxy group.

The term “biphenyl group” as used herein may be a “phenyl group substituted with a phenyl group.” For example, a “biphenyl group” may be interpreted as a “substituted phenyl group” having a “C₆-C₆₀ aryl group” as a substituent.

The term “terphenyl group” as used herein may be a “phenyl group substituted with a biphenyl group”. For example, a “terphenyl group” may be interpreted as a “substituted phenyl group” having a “C₆-C₆₀ aryl group substituted with a C₆-C₆₀ aryl group” as a substituent.

In the specification, the symbols * and *′, unless defined otherwise, each refer to a binding site to a neighboring atom in a corresponding formula or moiety.

In the specification, the terms “x-axis”, “y-axis”, and “z-axis” are not limited to three axes in an orthogonal coordinate system (for example, a Cartesian coordinate system), and may be interpreted in a broader sense than the aforementioned three axes in an orthogonal coordinate system. For example, the x-axis, y-axis, and z-axis may describe axes that are orthogonal to each other, or may describe axes that are in different directions that are not orthogonal to each other.

Hereinafter, quantum dots according to embodiments and light-emitting devices according to embodiments will be described in detail with reference to the following Synthesis Examples and Examples. The wording “B was used instead of A” used in describing Synthesis Examples means that an identical molar equivalent of B was used in place of A.

### EXAMPLES

### Example: Preparation of CuInGaS₂/ZnS Quantum Dots

### (Synthesis of CuInGaS₂ Core)

0.2 mmol of CuI, 0.5 mmol of GaCl₃, and 0.4 mmol of InCl₃ were mixed with 5 ml of oleylamine and 5 ml of 1-octadecene (ODE) in a three-neck flask, and oxygen and moisture inside the three-neck flask were removed while degassing and stirring the mixture at 120° C. for 30 minutes to thereby prepare a first composition.

1.8 mmol of 1 M sulfur(S)-oleylamine was added to the first composition in a nitrogen atmosphere, and the temperature was raised to 240° C. and maintained for a certain period of time to form a second composition.

0.2 mmol of CuI, 0.5 mmol of GaCl₃, 0.4 mmol of InCl₃, 5 ml of oleylamine, and 5 ml of 1-ODE were added to the second composition in a nitrogen atmosphere, and the temperature was raised to 280° C. and maintained for a certain period of time to form a third composition.

The third composition was maintained for a certain period of time and cooled to 200° C., and 4.48 mmol of trioctylphosphine (TOP) was added thereto for a reaction for a certain period of time to thereby synthesize a final core.

### (Synthesis of ZnS Shell)

The synthesized CuInGaS₂ core was diluted with toluene and precipitated by using ethanol for purification. 100 mmol of purified CuInGaS₂/GaS quantum dots were dispersed in toluene, mixed with 100 mmol of oleylamine, and degassed at 120° C. 1.6 mmol of zinc acetate (Zn(OA) 2) and 2.27 mmol of trioctylphosphine sulfide (TOP-S) were added thereto for a reaction at 280° C. or more for 20 minutes to form a ZnS shell.

### Comparative Example: Preparation of CuInGaS₂/ZnS Quantum Dots

### (Synthesis of CIGS (CuInGaS₂) Core)

0.2 mmol CuI, 0.5 mmol GaI₃, and 0.4 mmol of InI₃ were mixed with 5 ml of oleylamine, 0.85 mmol of trioctylphosphine oxide (TOPO), and 5 ml of trioctylamine (TOA) in a three-neck flask, and oxygen and moisture inside the three-neck flask were removed while degassing and stirring the mixture at 120° C. for 30 minutes to thereby form a reaction solution.

1 mmol to 2 mmol of S-oleylamine was added to the reaction solution in an argon atmosphere, and the temperature was raised to 240° C. and maintained for a certain time. After the reaction solution was cooled to 200° C., 4.48 mmol of trioctylphosphine (TOP) was injected therein for a reaction for a certain period of time to synthesize a CIGS (CuInGaS₂) core.

### (Synthesis of ZnS Shell)

The synthesized CuInGaS₂ core was diluted with toluene and precipitated by using ethanol for purification. 100 mmol of purified CuInGaS/GaS quantum dots were dispersed in toluene, mixed with 100 mmol of oleylamine, and degassed at 120° C. 1.6 mmol of zinc acetate (Zn(OA)₂) and 2.27 mmol of trioctylphosphine sulfide (TOP-S) were added thereto for a reaction at 280° C. or more for 20 minutes to form a ZnS shell.

### Evaluation Example 1: Analysis of Core Components

Each of the cores prepared in the above Example and Comparative Example was purified and precipitated once in a solvent to remove impurities, followed by dissolution in a nitric acid mixture and analysis on components thereof. The results are shown in Table 1.

TABLE 1
Total (weight fraction)

| | Cu | Ga | In | S | Sum |
|---|---|---|---|---|---|
| Core of Example | 0.080 | 0.375 | 0.109 | 0.436 | 1.000 |
| Core of Comparative | 0.142 | 0.151 | 0.194 | 0.513 | 1.000 |
| Example | | | | | |

Referring to Table 1, it was confirmed that the core according to the Example had a different element content from the core according to the Comparative Example, for example, a decreased copper content and an increased gallium content, compared to the core according to Comparative Example.

### Evaluation Example 2: Evaluation of the Characteristics of Quantum Dots

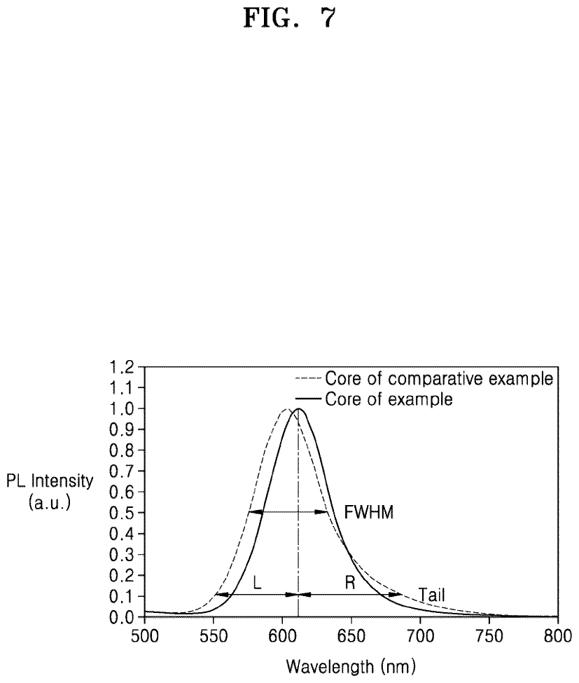

The maximum emission wavelength, the full width at half maximum (FWHM), the quantum yield (QY), and the tail value were evaluated for each of the cores and quantum dots prepared in Example and Comparative Example. The results are shown in Table 2 (core) and Table 3 (quantum dots), and the PL spectrum of the CIGS core is shown in FIG. 7.

2.8 ml of toluene and 0.2 ml of quantum dots were dispersed in a quartz cuvette, and the maximum emission wavelength and the full width at half maximum were evaluated by analyzing the PL spectrum measured using a PL spectrometer and a UV-vis spectrometer. The quantum yield was evaluated by using absolute quantum efficiency measuring equipment, and the tail value is expressed as an absolute value of the [right wavelength width-left wavelength width] value at 1/10 of the peak value of the maximum emission wavelength. For example, the tail value may be an absolute value of the [right half width of half maximum-left half width of half maximum] value at 1/10 of the peak value of the maximum emission wavelength.

TABLE 2

| | Maximum emission | FWHM | Tail value |
|---|---|---|---|
| | wavelength (nm) | (nm) | (nm) |
| Core of Example | 611 | 50 | 13 |
| Core of Comparative | 605 | 60 | 30 |
| Example | | | |

TABLE 3

| | Maximum emission | FWHM | Tail value | QY |
|---|---|---|---|---|
| | wavelength (nm) | (nm) | (nm) | (%) |
| Quantum dots of | 619 | 54 | 17 | 90 |
| Example | | | | |
| Quantum dots of | 610 | 66 | 41 | 65 |
| Comparative Example | | | | |

Referring to Table 2, Table 3, and FIG. 7, it was confirmed that the core and quantum dots according to the Example had a narrow full width at half maximum, a low tail value, and excellent quantum yield (QY) compared to the quantum dots and core according to the Comparative Example.

Therefore, it was confirmed that the quantum dots prepared manufactured by the method of manufacturing a quantum dot according to an embodiment may have a narrow full width at half maximum, a low tail value, and excellent quantum yield (QY).

Quantum dots according to the disclosure may have a narrow full width at half maximum and a low tail value through additional injection of precursors and high-temperature heat treatment. Accordingly, by using the quantum dots, high-quality optical members and electronic apparatuses can be provided.

Embodiments have been disclosed herein, and although terms are employed, they are used and are to be interpreted in a generic and descriptive sense only and not for the purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A quantum dot comprising:
a core comprising:
copper (Cu);
a Group III element; and
a Group VI element; and
a first shell covering the core, wherein
a full width at half maximum (FWHM) of an emission wavelength spectrum of the core is equal to or less than about 55 nm.

2. The quantum dot of claim 1, wherein a tail value of the emission wavelength spectrum of the core is equal to or less than about 15 nm.

3. The quantum dot of claim 1, wherein the core comprises an amount of Cu in a range of about 4 parts by weight to about 10 parts by weight, based on a total of 100 parts by weight of the core.

4. The quantum dot of claim 1, wherein the Group III element is aluminum (Al), gallium (Ga), indium (In), thallium (TI), nihonium (Nh), or a combination thereof.

5. The quantum dot of claim 1, wherein the Group VI element is oxygen (O), sulfur(S), selenium (Se), tellurium (Te), or a combination thereof.

6. The quantum dot of claim 1, wherein the core comprises Cu, indium (In), gallium (Ga), and sulfur(S).

7. The quantum dot of claim 6, wherein, based on a total of 100 parts by weight of the core, the core comprises:
an amount of Cu in a range of about 4 parts by weight to about 10 parts by weight;
an amount In in a range of about 10 parts by weight to about 20 parts by weight;
an amount Ga in a range of about 30 parts by weight to about 40 parts by weight; and
an amount S in a range of about 40 parts by weight to about 50 parts by weight.

8. The quantum dot of claim 1, wherein the first shell comprises a Group II-VI semiconductor compound, a Group III-VI semiconductor compound, a Group III-V semiconductor compound, or a combination thereof.

9. The quantum dot of claim 8, wherein the Group II-VI semiconductor compound is CdS, CdSe, CdTe, ZnS, ZnSe, ZnTe, ZnO, ZnMg, HgS, HgSe, HgTe, MgSe, MgS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, CdZnSeS, CdZnSeTe, CdZnSTe, CdHgSeS, CdHgSeTe, CdHgSTe, HgZnSeS, HgZnSeTe, HgZnSTe, or a combination thereof.

10. The quantum dot of claim 8, wherein the Group III-VI semiconductor compound is GaS, GaSe, Ga₂Se₃, GaTe, InS, InSe, In₂S₃, In₂Se₃, InTe, InGaSs, InGaSe₃, or a combination thereof.

11. The quantum dot of claim 8, wherein the Group III-V semiconductor compound is GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, GaAlNAs, GaAlNSb, GaAlPAs, GaAlPSb, GalnNP, GaInNAs, GalnNSb, GaInPAs, GaInPSb, InAlNP, InAlNAs, InAlNSb, InAlPAs, InAlPSb, or a combination thereof.

12. The quantum dot of claim 1, wherein the quantum dot emits red light having a maximum emission wavelength in a range of about 600 nm to about 700 nm.

13. The quantum dot of claim 1, wherein a quantum yield (QY) of the quantum dot is more than 70% but not more than about 98%.

14. An optical member comprising the quantum dot of claim 1.

15. An electronic apparatus comprising the quantum dot of claim 1.

16. The electronic apparatus of claim 15, further comprising:
a light source; and
a color conversion member arranged in an optical path of light emitted from the light source, wherein
the color conversion member comprises the quantum dot.

17. A method of manufacturing a quantum dot, the method comprising:
manufacturing a core comprising copper (Cu), a Group III element, and a Group VI element; and
manufacturing a first shell covering the core, wherein
a full width at half maximum (FWHM) of an emission wavelength spectrum of the core is equal to or less than about 55 nm.

18. The method of claim 17, wherein
the manufacturing of the core comprises:
manufacturing the core by using a composition for forming a core, and
the composition comprises a copper precursor, a Group III element-containing precursor, and a Group VI element-containing precursor.

19. The method of claim 17, wherein the manufacturing of the core comprises:
heat-treating the composition for forming a core at a temperature more than 240° C. but not more than about 320° C.

20. The method of claim 17, wherein
the manufacturing of the first shell comprises:
manufacturing the first shell by using a composition for forming a first shell, and
the composition comprises a Group Il element-containing precursor and a Group VI element-containing precursor.
